(19) United States
(12) Patent Application Publication
(10) Pub. No.: US 2009/0278595 A1
(43) Pub. Date: Nov. 12, 2009

(54) Braithwaite particle trap (THE BPT)

(76) Inventor: Sherman W. Braithwaite, Brooklyn, NY (US)

Correspondence Address: SHERMAN W. BRAITHWAITE, 1218 EAST 48 STREET, BROOKLYN, NY, 11234, US

(21) Appl. No.: 11/897,930

(22) Filed: Sep. 4, 2007

Related U.S. Application Data
(63) Continuation-in-part of application No. 11/181,048, filed on Jul. 14, 2005, now abandoned.

(51) Int. Cl. H03K 17/00

(52) U.S. Cl. 327/603

(57) ABSTRACT

THE BRAITHWAITE PARTICLE TRAP, a small device that is for or used to generate limitless electrical power. THE BPT CIRCUIT works simply by using Like-Forces (+ verses +) and (− verses −) or charges instead of Opposite-Forces (+ verses −) to produce power or to increase electrical power greatly. In general, great electrical power exists not only by having a great flow of energy or current. Electrical power can be made to increase because there is a great isolation of particles set aside to perform a function at a later time. When used, the isolation of particles helps to accumulate opposite charges with sometimes its greatest potential. In other words, as soon as one particular charge (protons or electrons) or while those charges accumulate—or in the sense of protons—and are isolated, the POTENTIAL ENERGY gains force to observe atomic particles of its opposite nature.

### CROSS REFERENCES AND RELATED SUBJECT MATTER

This application is a continuation of provisional patent application Ser. No. 60/587,683, filed in the United States Patent Office on Jul. 14, 2004, and of utility patent application Ser. No. 11/181,048, filed in the United States Patent Office on Jul. 14, 2005. This utility patent application is a correction and Ser. No. 11/897,930, filed on Sep. 4, 2007.

### BACKGROUND OF THE INVENTION

1. Field of the Invention

The present invention relates generally to current source devices and more specifically it relates to a device, my invention, THE BRAITHWAITE PARTICLE TRAP, a small device that is for or used to generate limitless electrical power. THE BPT CIRCUIT works simply by using Like-Forces (+ verses +) and (− verses −) or charges instead of Opposite-Forces (+ verses −) to produce power or to increase electrical power greatly. In general, great electrical power exists not only by having a great flow of energy or current. Electrical power can be made to increase because there is a great isolation of particles set aside to perform a function at a later time. When used, the isolation of particles helps to accumulate opposite charges with sometimes its greatest potential. In other words, as soon as one particular charge (protons or electrons) or while those charges accumulate—or in the sense of protons and are isolated, the POTENTIAL ENERGY gains force to observe atomic particles of its opposite nature. Using THE BPT CIRCUIT, in conjunction with battery power, to perform such a task so that when stored energy is manipulated to discharge, there is both great current and voltage not simply great voltage and small current or static electricity, there is enormous of a difference from the battery power connected to THE BPT CIRCUIT

2. Description of the Related Art

It can be appreciated that current source devices have been in use for years. Typically, current source devices vary, and may be comprised of, see PAGES 1 TO 23. (PATENT NO.: U.S. Pat. No. 7,042,204 B2)

The main problems with conventional current source devices are—see PATENT NO.: U.S. Pat. No. 7,042,204 B2 this is a typical device powered by an AC INPUT from a generator. A device that is powered by a generator might simply be defined as being powered by a Rectifier (a small device) with the need of a great outside force of energy as power which usually comes from a device that is usually large and bulky in size. Another problem with current source devices is—see PAGES 1 TO 15. (PATENT NO.: US 2003/0071465 A1)—Generators are typically bulky. (PATENT NO.: US 2003/0071465 A1) this is an engine generator.

While these devices may be suitable for the particular purpose to which they address, they are not as suitably a small device that is for or used to generate limitless electrical power. THE BPT CIRCUIT works simply by using Like-Forces (+ verses +) and (− verses −) or charges instead of Opposite-Forces (+ verses −) to produce power or to increase electrical power greatly. In general, great electrical power exists not only by having a great flow of energy or current. Electrical power can be made to increase because there is a great isolation of particles set aside to perform a function at a later time. When used, the isolation of particles helps to accumulate opposite charges with sometimes its greatest potential. In other words, as soon as one particular charge (protons or electrons) or while those charges accumulate—or in the sense of protons—and are isolated, the POTENTIAL ENERGY gains force to observe atomic particles of its opposite nature. Using THE BPT CIRCUIT, in conjunction with battery power, to perform such a task so that when stored energy is manipulated to discharge, there is both great current and voltage not simply great voltage and small current or static electricity, there is enormous of a difference from the battery power connected to THE BPT CIRCUIT.

In these respects, THE BRAITHWAITE PARTICLE TRAP, according to the present inventions substantially departs from the conventional concepts and designs of the prior art, and in so doing provide an apparatus primarily developed as a small device that is for or used to generate limitless electrical power. THE BPT CIRCUIT works simply by using Like-Forces (+ verses +) and (− verses −) or charges instead of Opposite-Forces (+ verses −) to produce power or to increase electrical power greatly. In general, great electrical power exists not only by having a great flow of energy or current. Electrical power can be made to increase because there is a great isolation of particles set aside to perform a function at a later time. When used, the isolation of particles helps to accumulate opposite charges with sometimes its greatest potential. In other words, as soon as one particular charge (protons or electrons) or while those charges accumulate—or in the sense of protons—and are isolated, the POTENTIAL ENERGY gains force to observe atomic particles of its opposite nature. Using THE BPT CIRCUIT, in conjunction with battery power, to perform such a task so that when stored energy is manipulated to discharge, there is both great current and voltage not simply great voltage and small current or static electricity, there is enormous of a difference from the battery power connected to THE BPT CIRCUIT.

### SUMMARY OF THE INVENTION

In view of the foregoing disadvantages inherent in the known types of current source devices now present in the prior art, the present invention provides a better, device, THE BRAITHWAITE PARTICLE TRAP, construction wherein is different and can be utilized as a small device that is for or used to generate limitless electrical power. THE BPT CIRCUIT works simply by using Like-Forces (+ verses +) and (− verses −) or charges instead of Opposite-Forces (+ verses −) to produce power or to increase electrical power greatly. In general, great electrical power exists not only by having a great flow of energy or current. Electrical power can be made to increase because there is a great isolation of particles set aside to perform a function at a later time. When used, the isolation of particles helps to accumulate opposite charges with sometimes its greatest potential. In other words, as soon as one particular charge (protons or electrons) or while those charges accumulate—or in the sense of protons—and are isolated, the POTENTIAL ENERGY gains force to observe atomic particles of its opposite nature. Using THE BPT CIRCUIT, in conjunction with battery power, to perform such a task so that when stored energy is manipulated to discharge, there is both great current and voltage not simply great voltage and small current or static electricity, there is enormous of a difference from the battery power connected to THE BPT CIRCUIT. The general purpose of the present invention, which will be described subsequently in greater detail, is to provide a new device. THE BRAITHWAITE PARTICLE TRAP has many of the advantages of the current source devices mentioned heretofore and many novel features that result in a new device, THE BRAITHWAITE PARTICLE TRAP which is not anticipated, rendered obvious, suggested, or even implied by any of the prior art current source devices, either alone or in any combination thereof

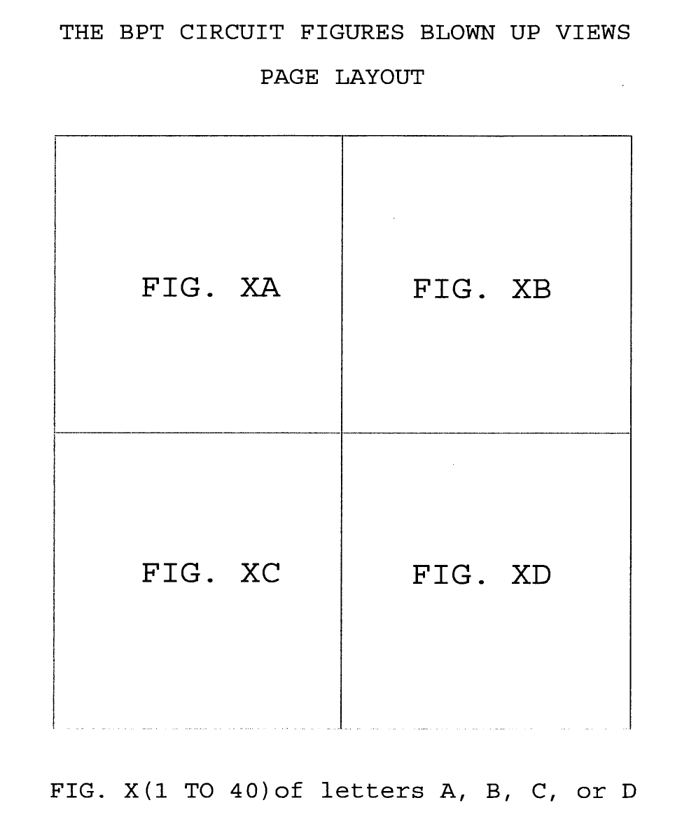

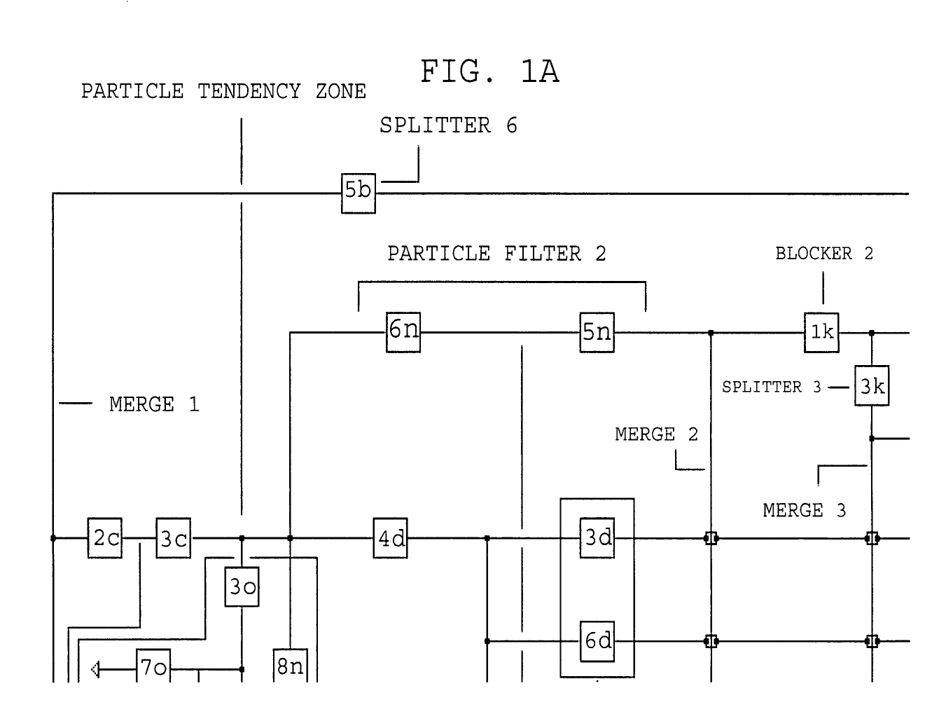

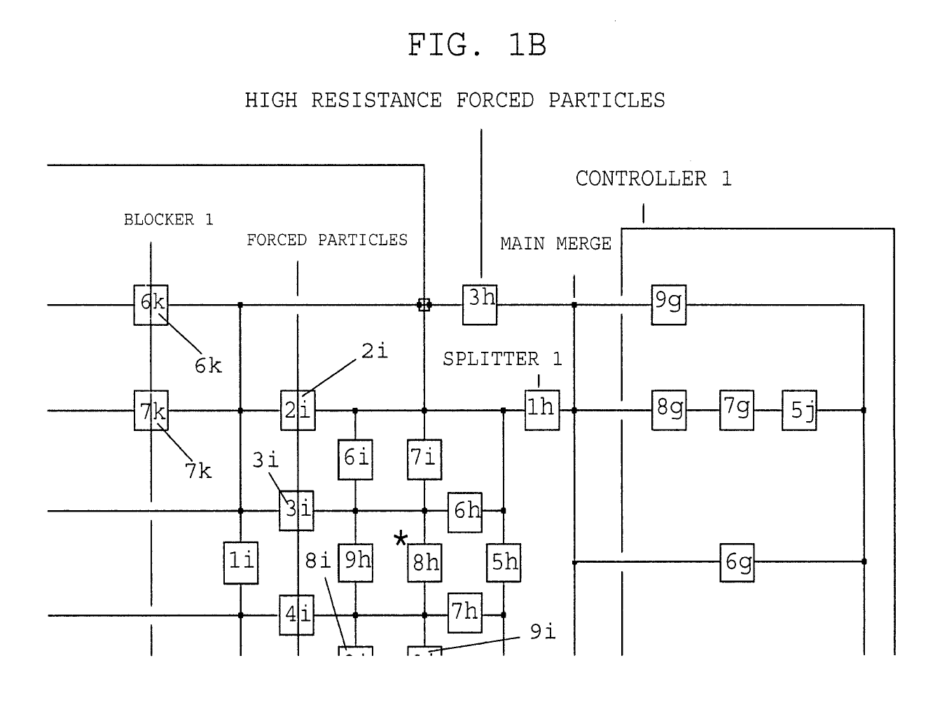

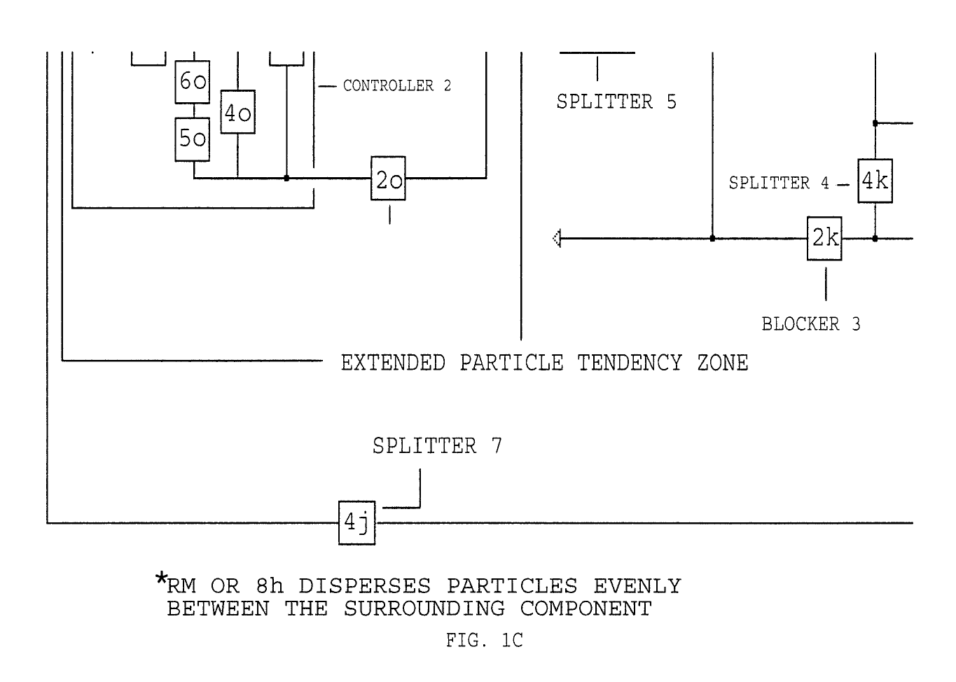

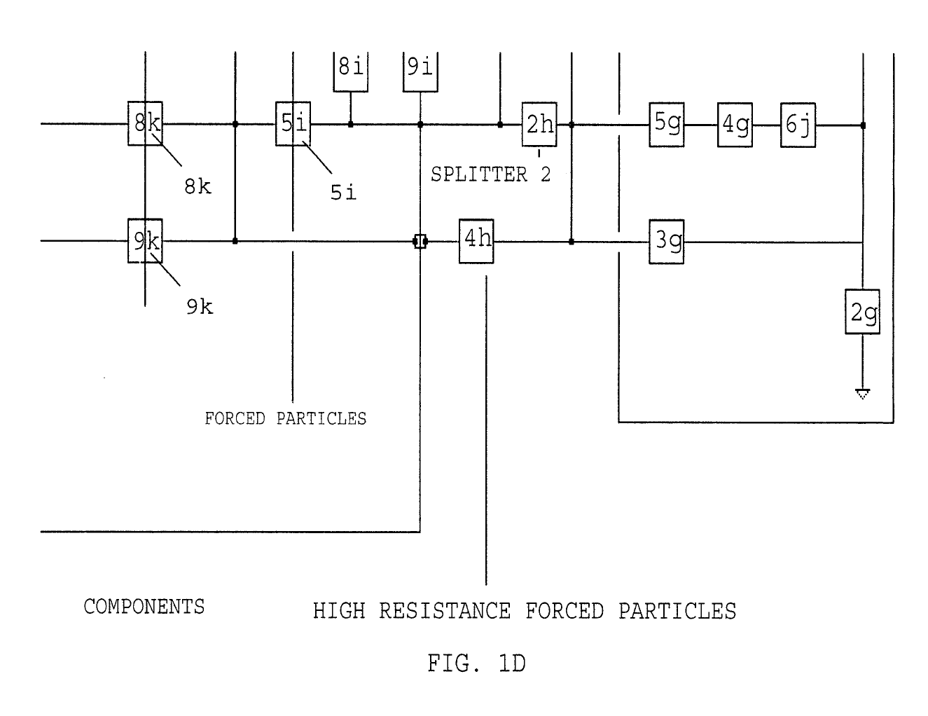

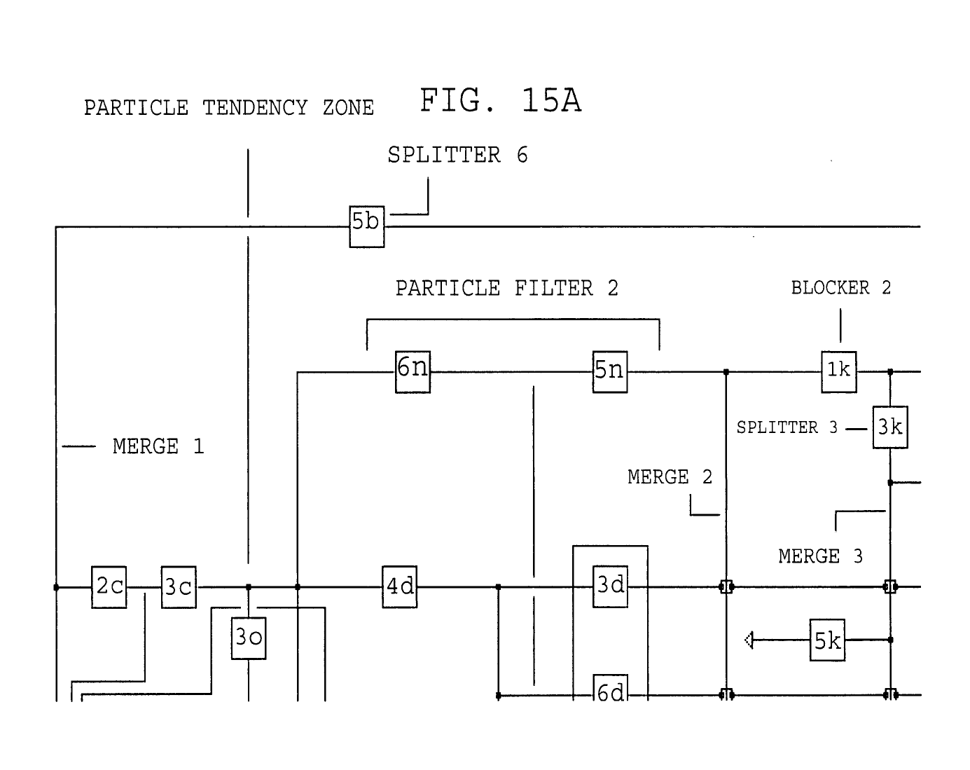

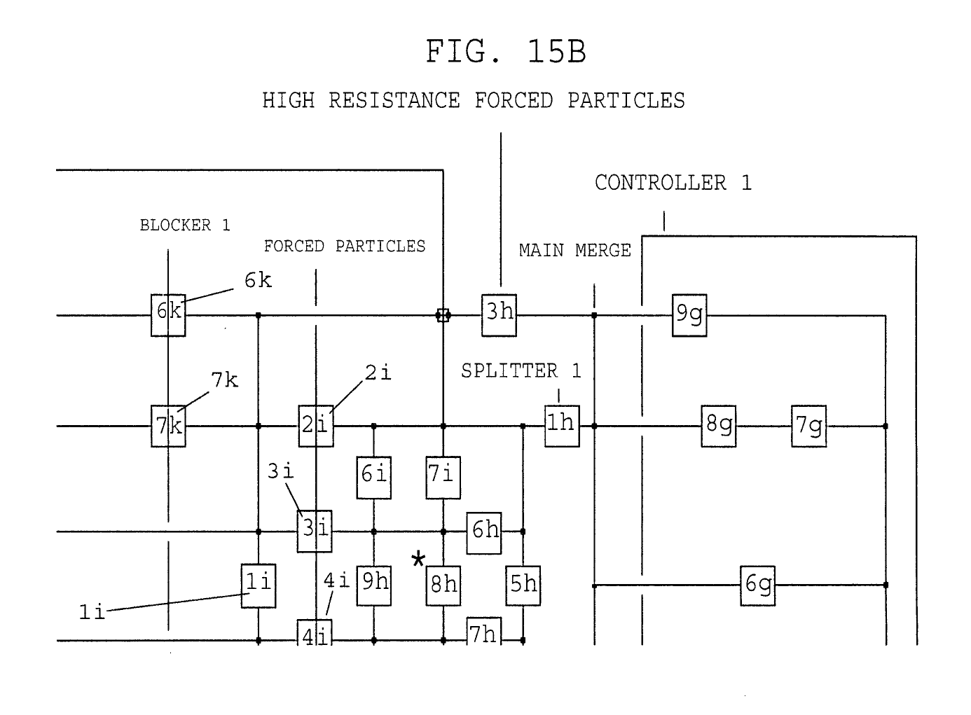

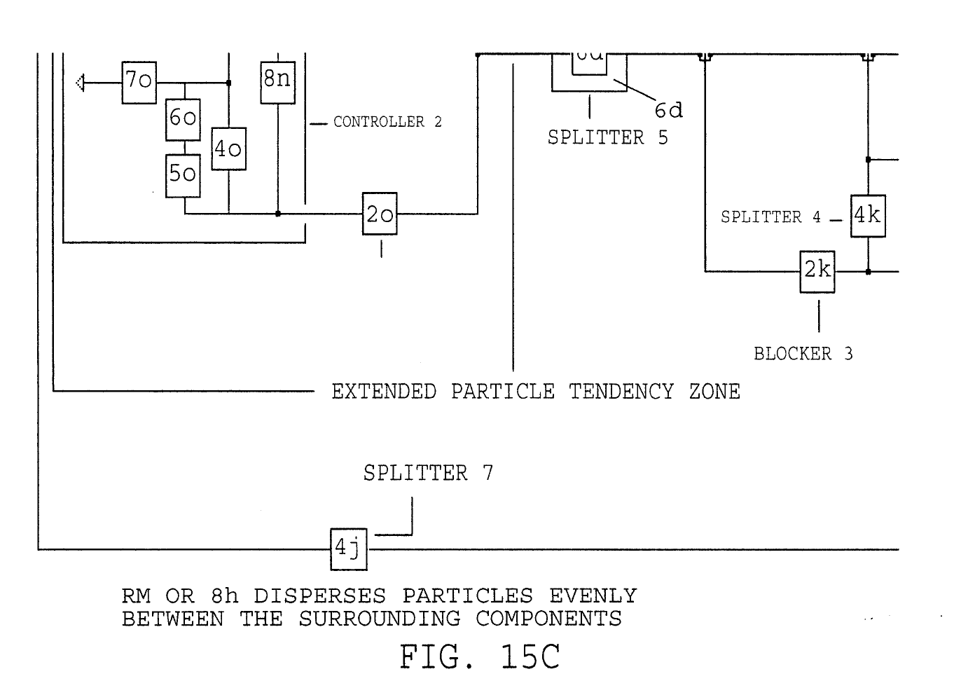

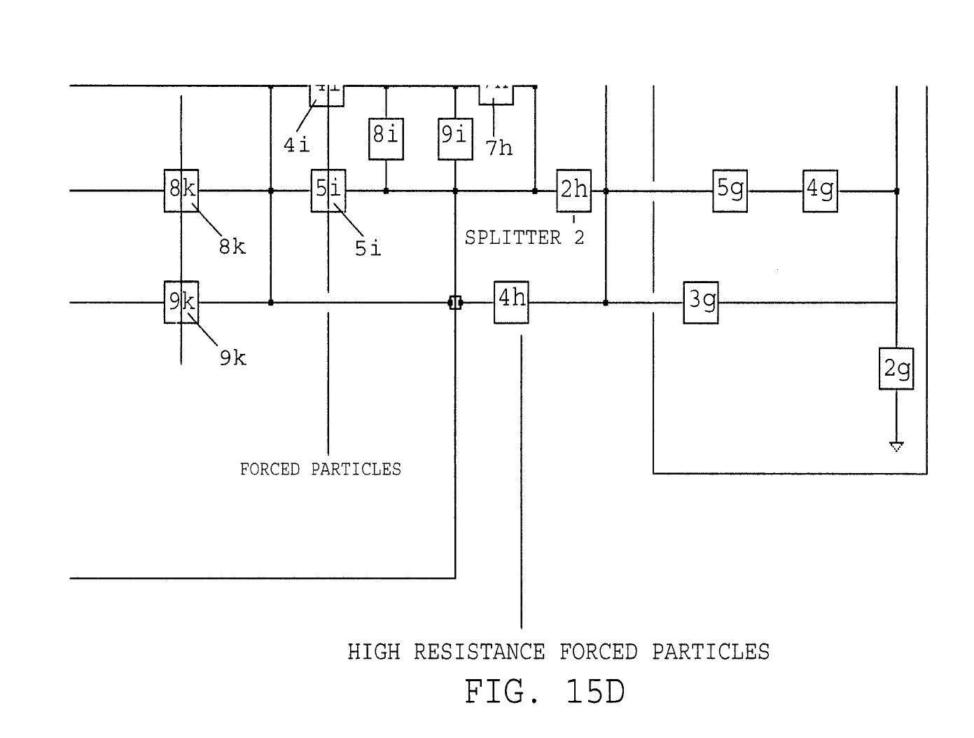

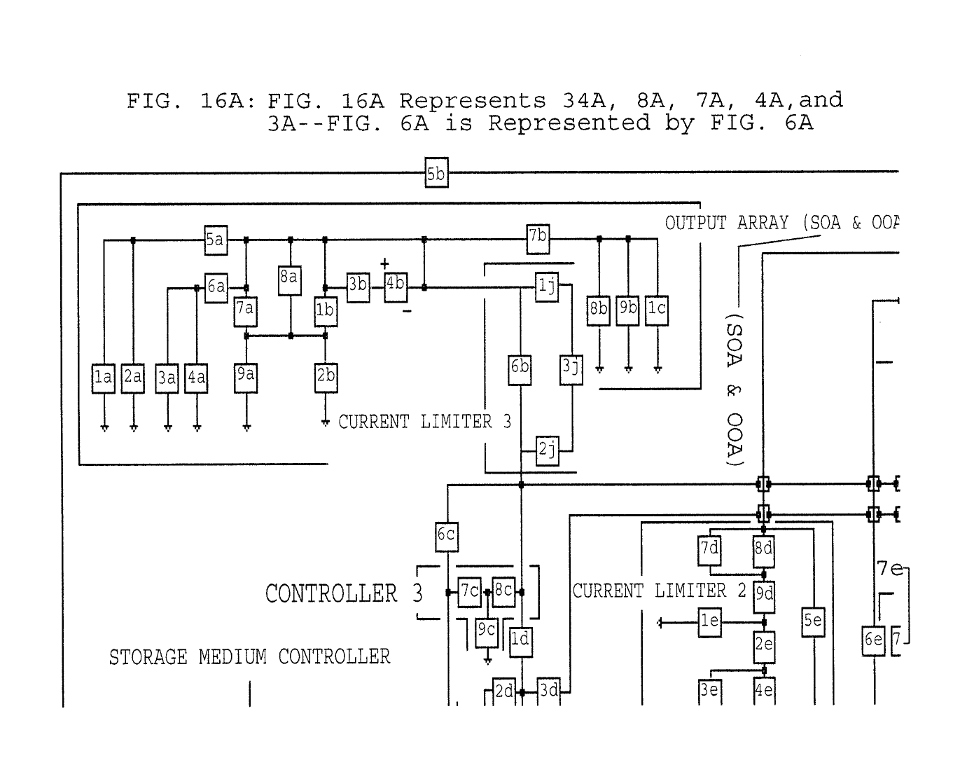

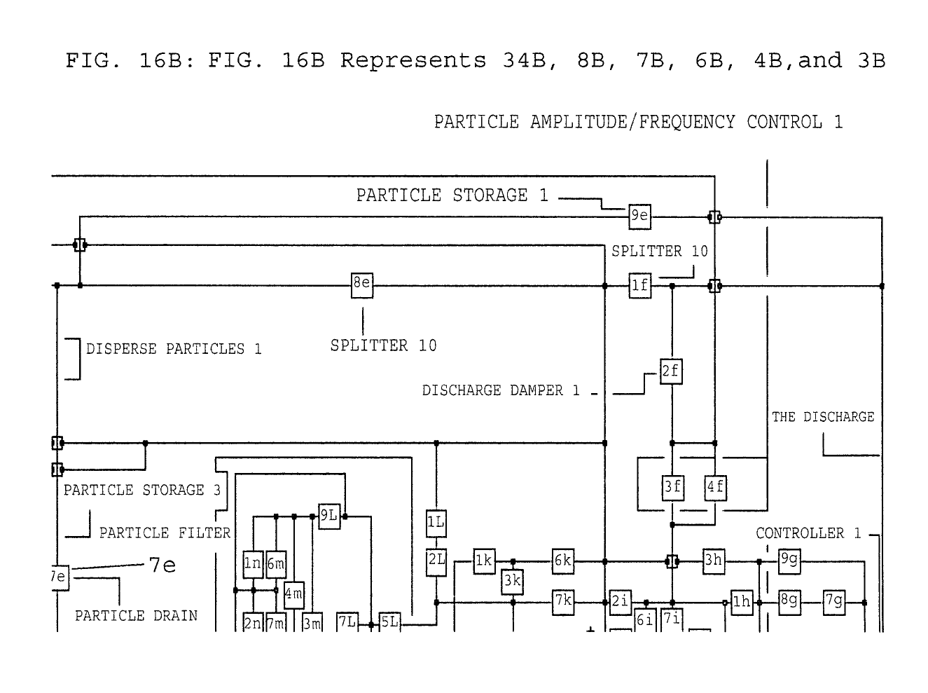

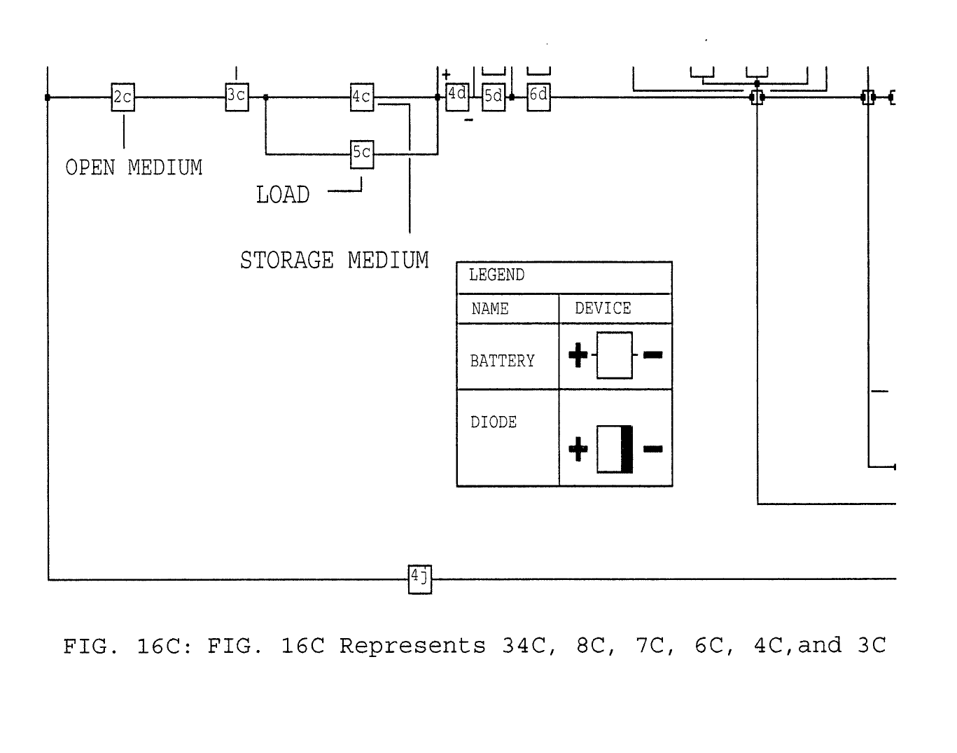

To attain this, the present invention generally comprises Batteries, Capacitors, Resistors and Diodes (Optional i.e. the device can be made of simply Batteries, Capacitors, Resistors as Diodes—Working resistors I have tested are about 0.1 Million Ohms for FIG. 1, FIG. 15, and 0.02 Million Ohms for FIG. 8—, Wires and a Bread Board or PCB), Wires and a Prototype Board or a PCB (PRINTED CIRCUIT BOARD).

Batteries are a 2 pin device. Capacitors are a 2 pin device. Resistors are a 2 pin device. Diodes are a 2 pin device. Prototype Boards are drilled Copper Clad Breadboards for use with many pin type components at the same time. PCBs are printed circuit boards—used in place of a Drilled Copper Clad Breadboard and wires—.

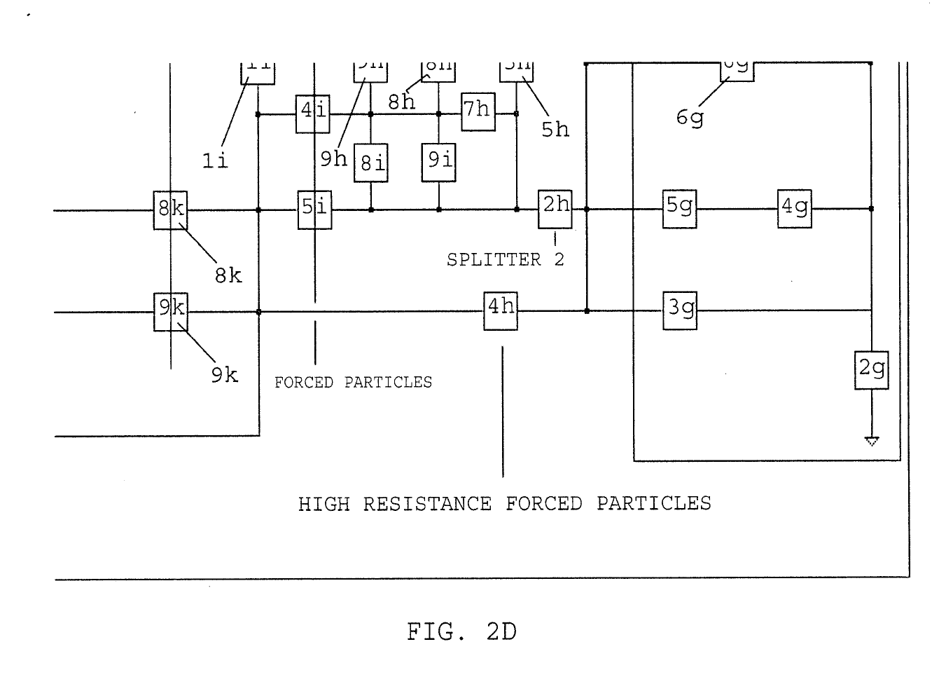

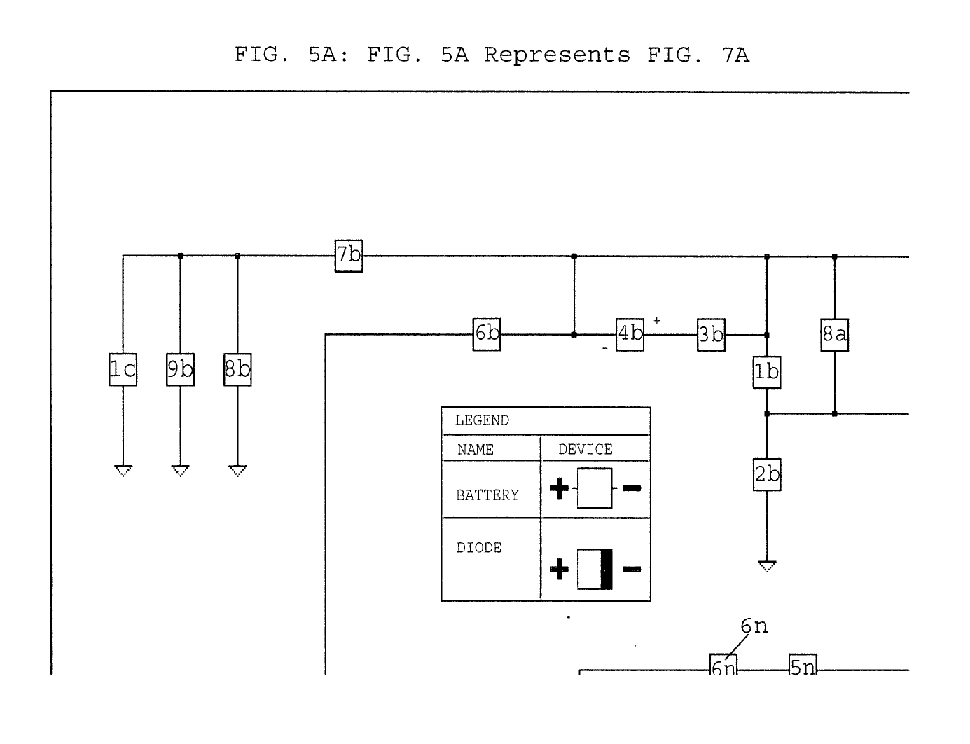

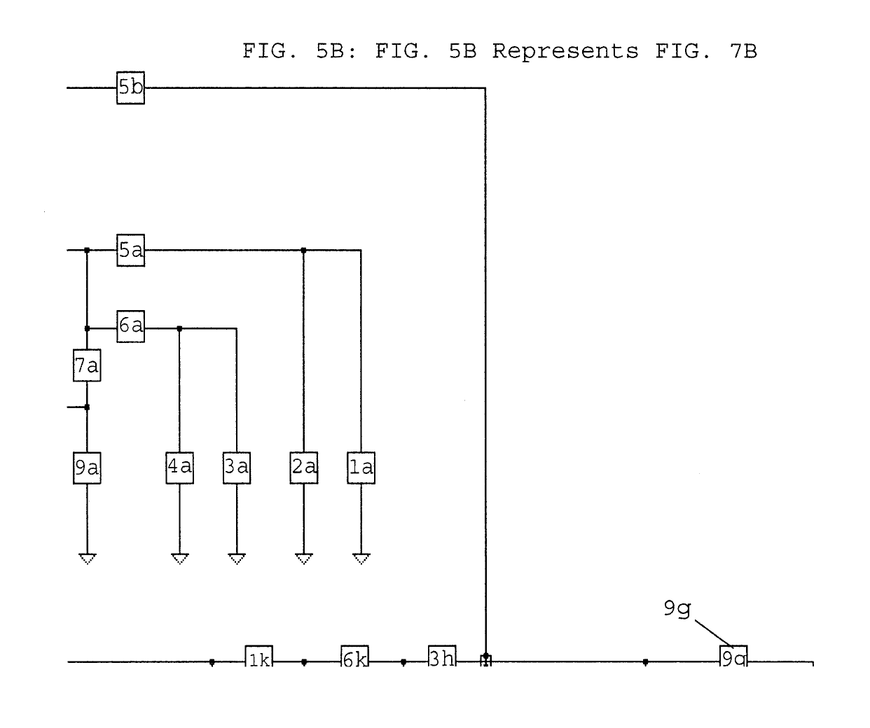

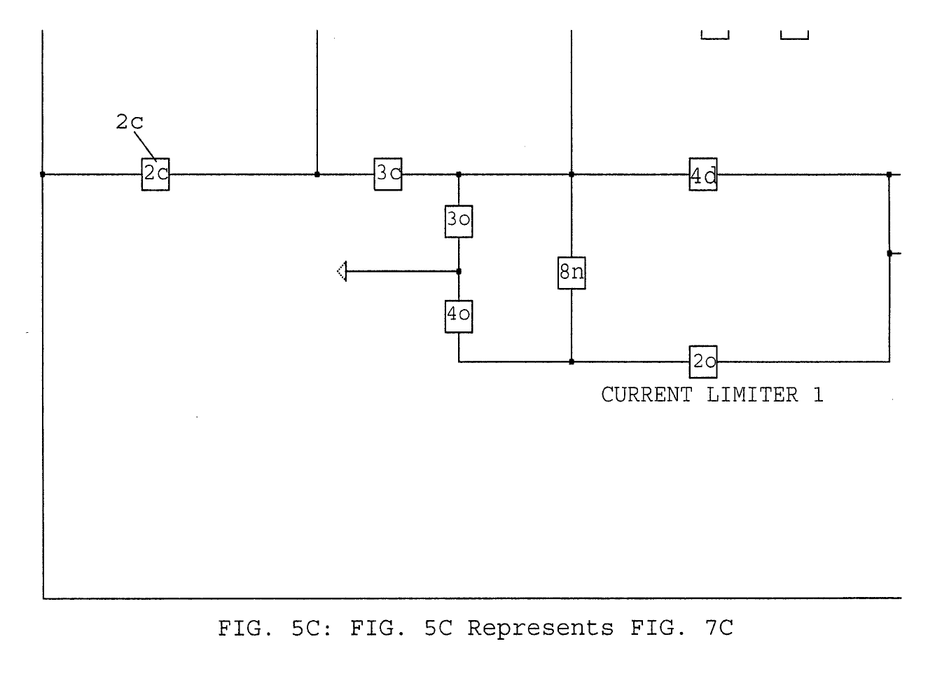

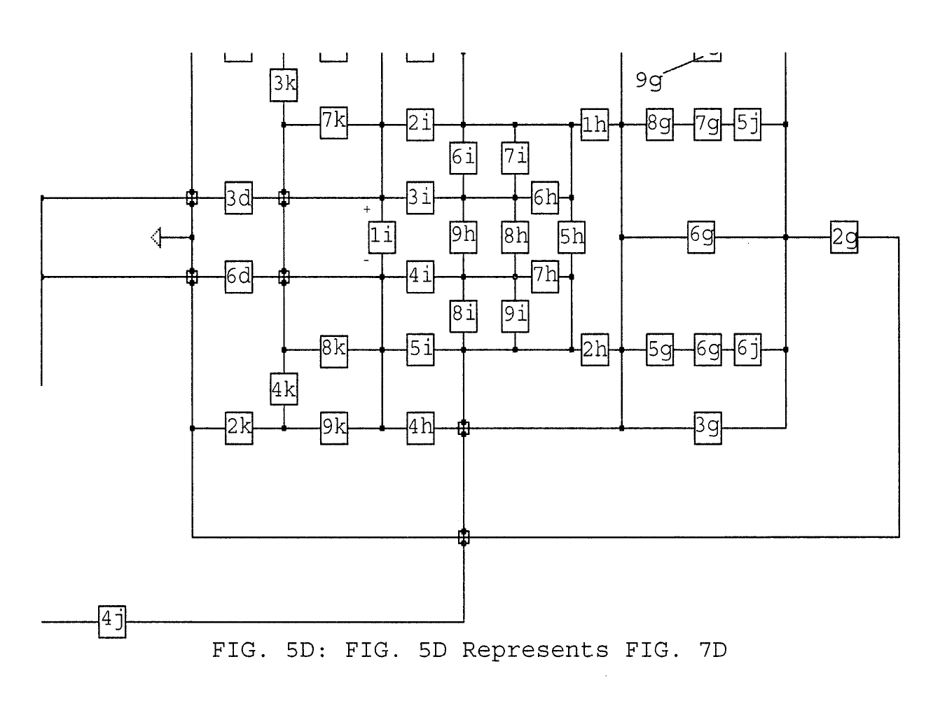

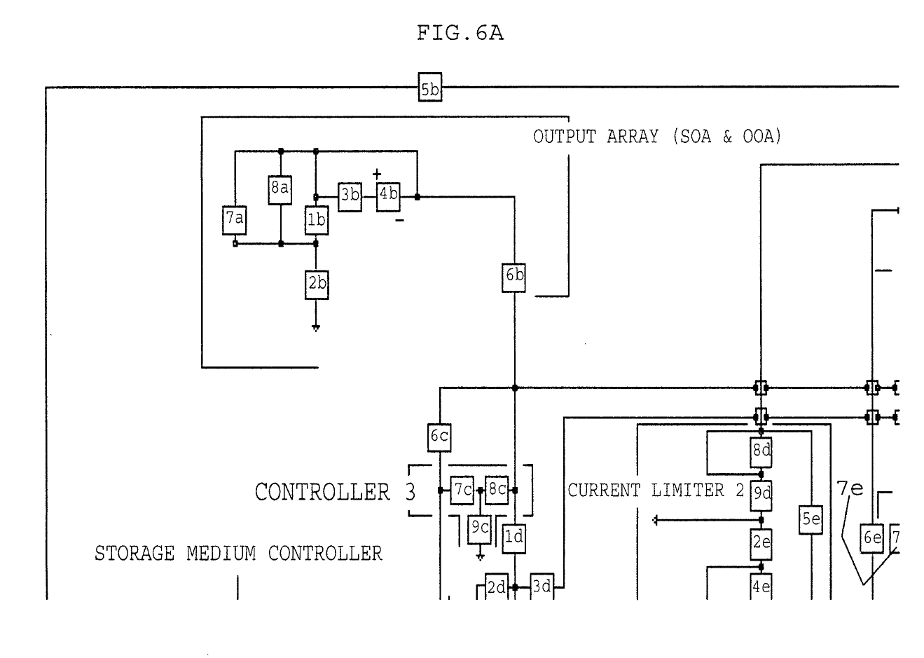

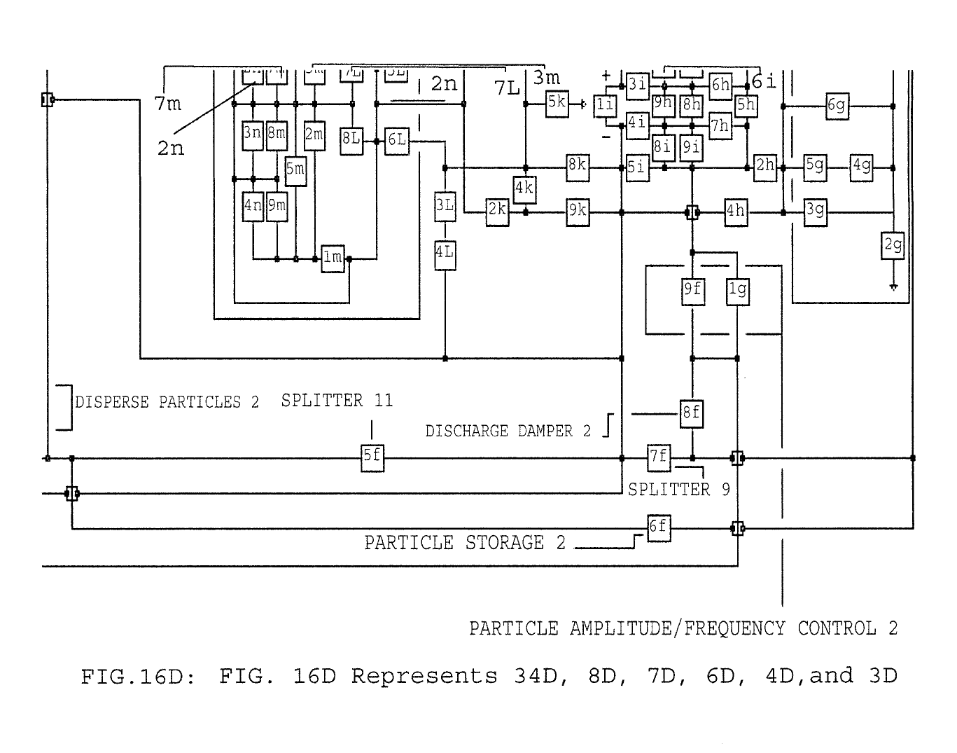

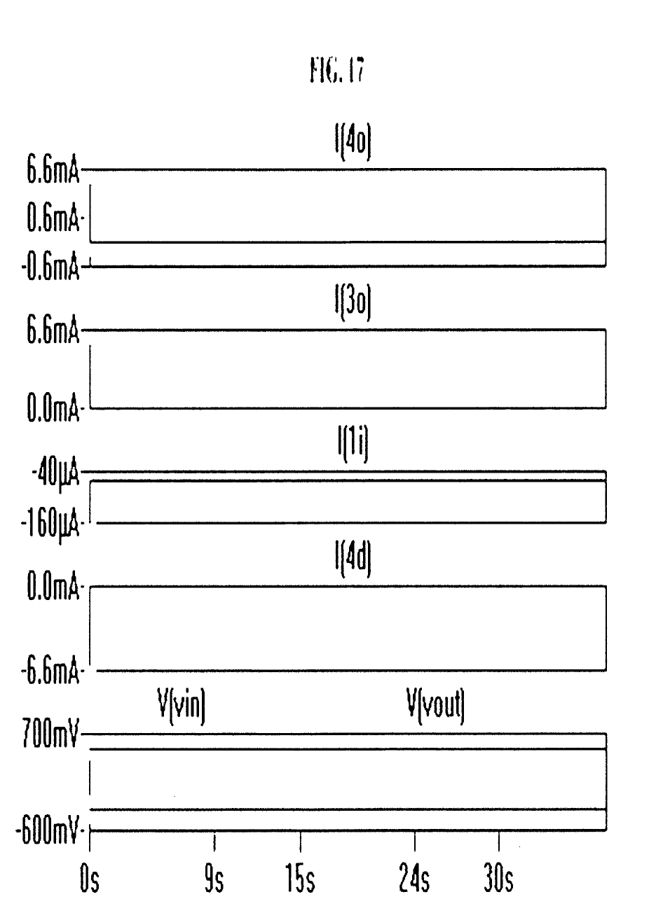

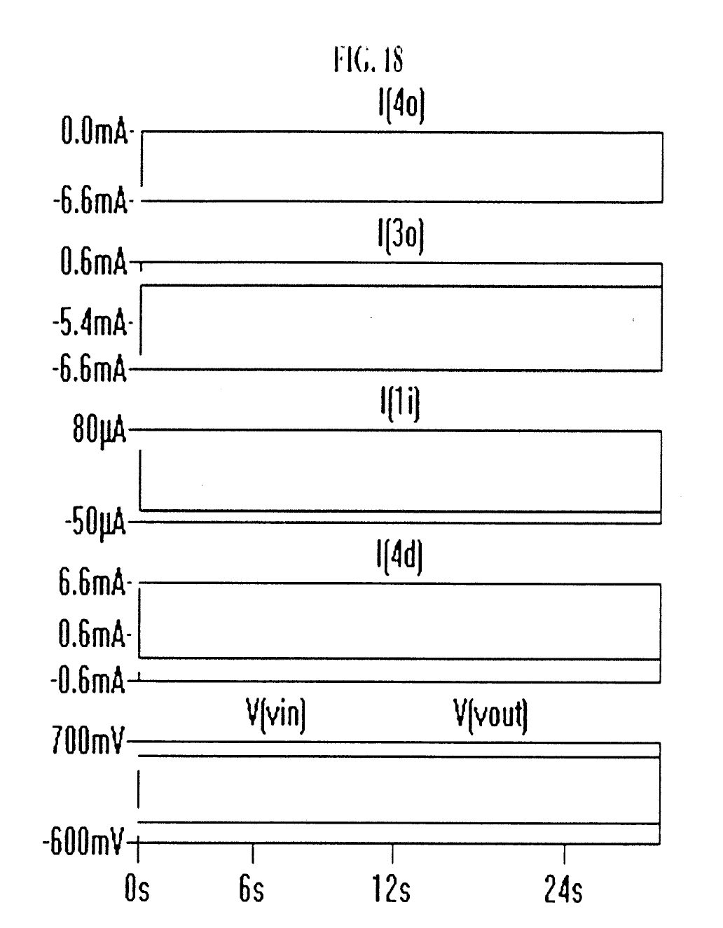

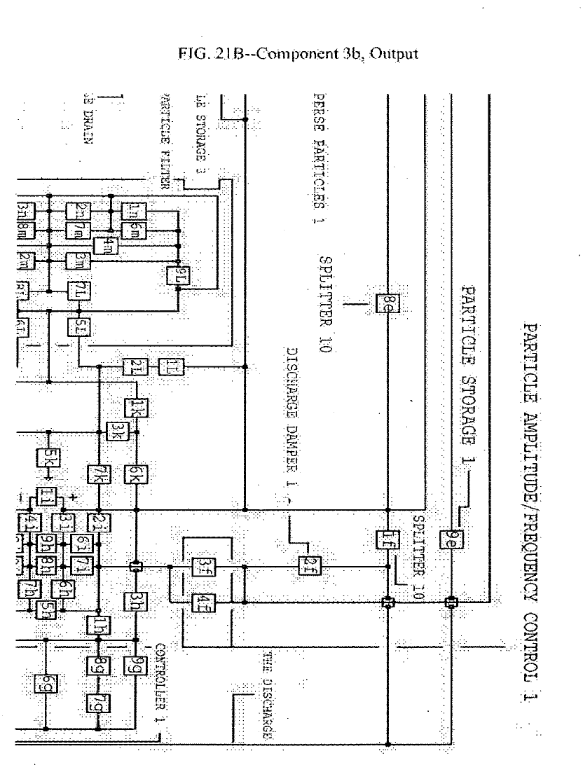

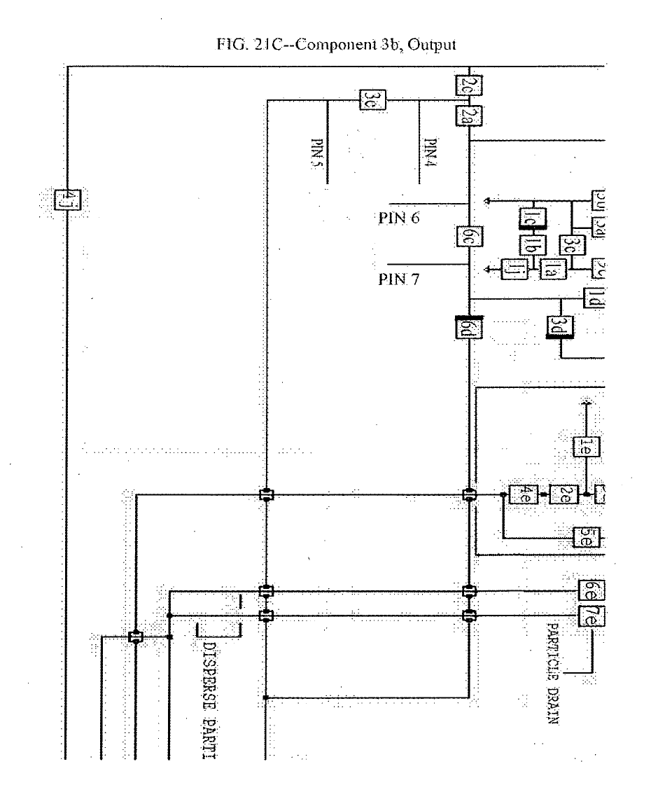

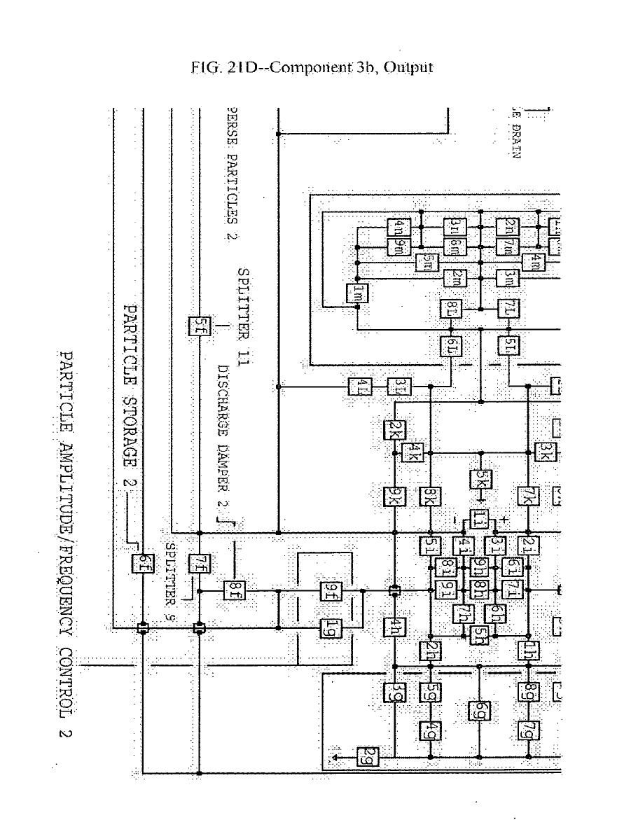

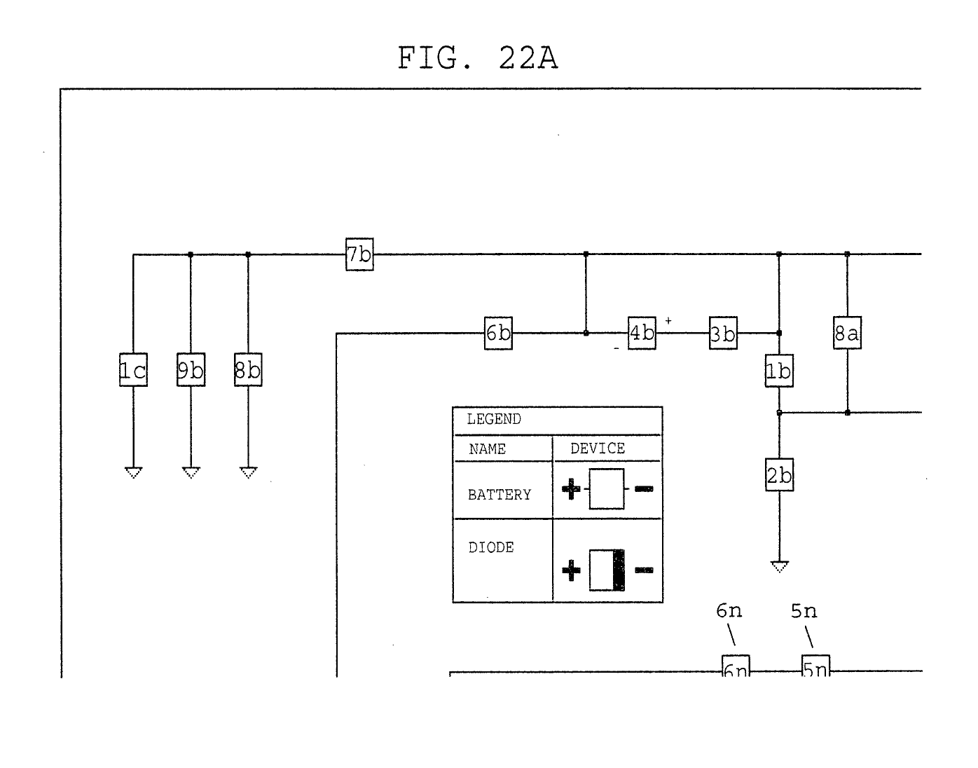

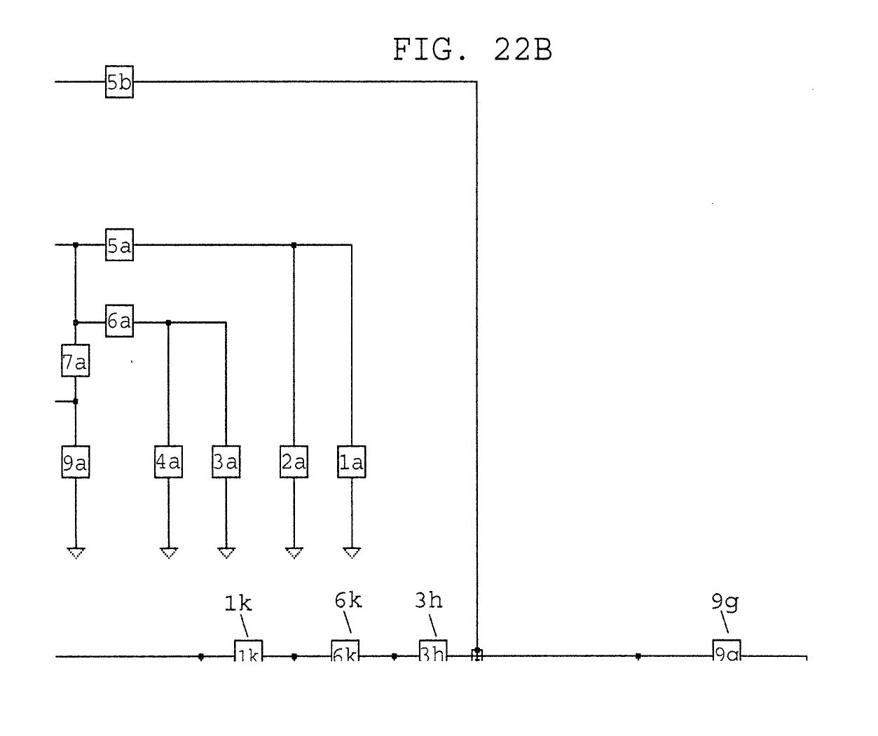

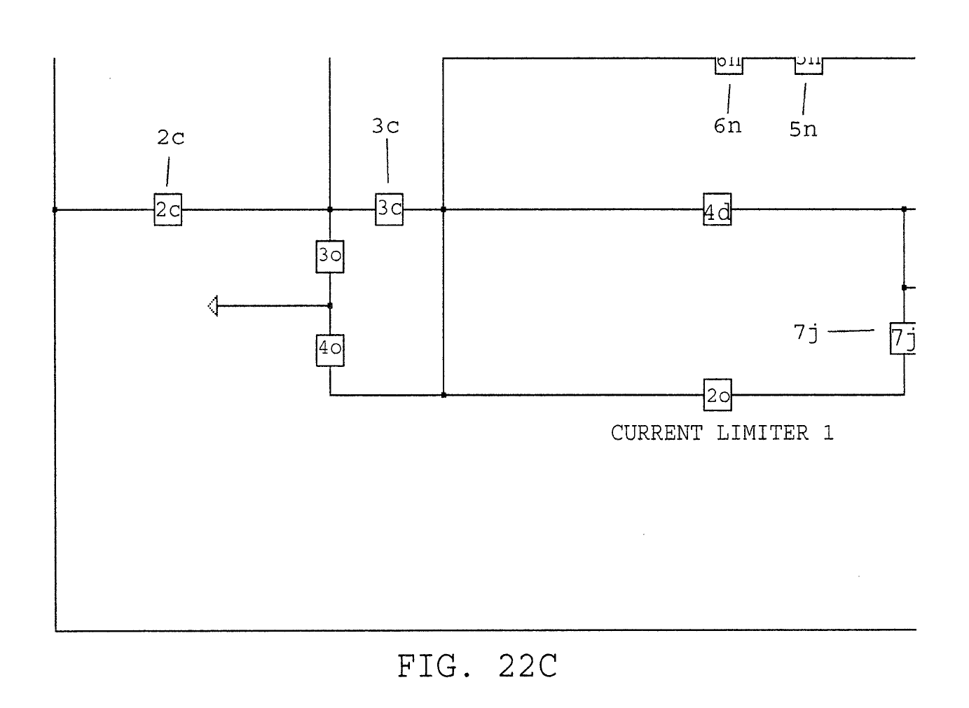

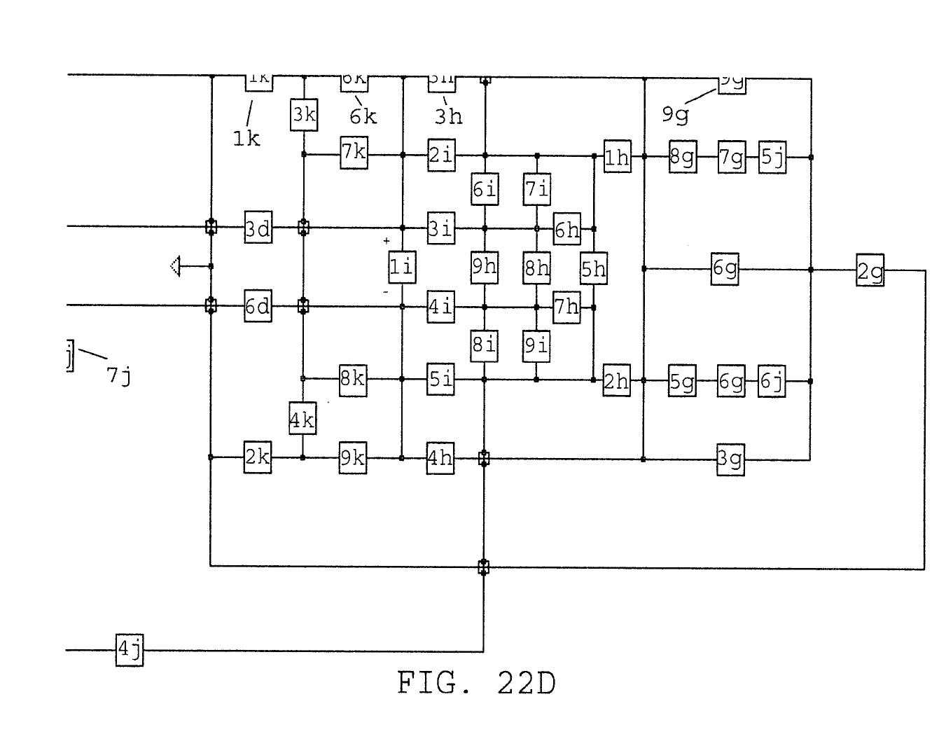

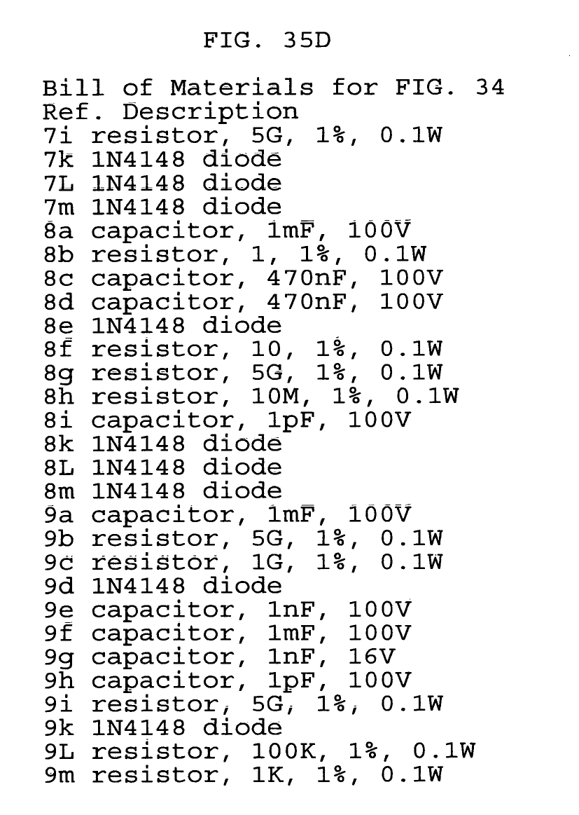

The wire to use is a string of conducting material, copper or other metals which usually come in circumference units of gage. BATTERY POWER, ALLOWS TIMED-PARTICLES (moving atomic particles that have a frequency) TO EXIST AT ZONES OF THE BPT CIRCUIT see FIG. 16 (THE PARTICLE TENDENCY ZONE and EXTENDED PARTICLE TENDENCY ZONE)

Where the particles end up in THE BPT CIRCUIT is an interesting matter. The particles can exist at any zone of the circuit. They mostly run to the parts of the circuit with the most resistance or highest resistor. The following are examples of enhanced concepts of where the particles run to, called (THE PARTICLE TENDENCY ZONE and EXTENDED PARTICLE TENDENCY ZONE), and this (see FIG. 16) part of THE BPT CIRCUIT MAINTAINS THE DIRECTION OF PARTICLES, and EXIST IN THESE BPT CIRCUIT(S) FIG. 1, FIG. 3, FIG. 4, FIG. 5, FIG. 6, FIG. 7, FIG. 8, FIG. 13, FIG. 14, FIG. 15, FIG. 21, FIG. 22, and FIG. 34.

THE PARTICLE TENDENCY ZONE and EXTENDED PARTICLE TENDENCY ZONE: POTENTIAL ENERGY OR STORAGE OF PARTICLES OCCURS at these zones. Tapping into these ] zones of THE BPT CIRCUIT and using a CURRENT ARRAY allows current increase in some components in the CURRENT ARRAY (see FIG. 16). ONLY A FEW NODES IN THE BPT CIRCUIT HAS THE POTENTIAL FOR CURRENT INCREASE IN THE OUTPUT ARRAY. FIG. 3, FIG. 4, FIG. 5, FIG. 6, FIG. 7, FIG. 8, FIG. 14, FIG. 15, FIG. 22 and FIG. 34 have THE PARTICLE TENDENCY ZONE and EXTENDED PARTICLE TENDENCY ZONE where POTENTIAL ENERGY exists that causes current increase in an OUTPUT ARRAY.

Current can be a burden at times; in the case of THE BPT CIRCUIT, current can be dangerous; therefore, I decided to work with current limiter zones in THE BPT CIRCUIT (see FIG. 16). The CURRENT LIMITER (CURRENT LIMITER 2) is made up of LOWERED RESISTANCE OR POTENTIOMETERS (POTS), ALLOWING HIGHER CURRENT FLOW IN THE OUTPUT ARRAY. For CURRENT LIMITER 2, either component 7d or component 3e CAN BE OPEN CIRCUITED. FIG. 3, FIG. 4, FIG. 6 (components 8d and 4e are shorted and THERE IS NO RESISTOR OR INDUCTOR AT THE GROUND between components 9d and 2e; making, THE OUTPUT ARRAY CURRENT AT ITS MAXIMUM AMP.), FIG. 8 and FIG. 34. Also, for the figures mentioned; not both components 7d and 3e CAN BE OPEN-CIRCUITED, that uses current in THE BPT CIRCUIT(s) TO DROP down to zero.

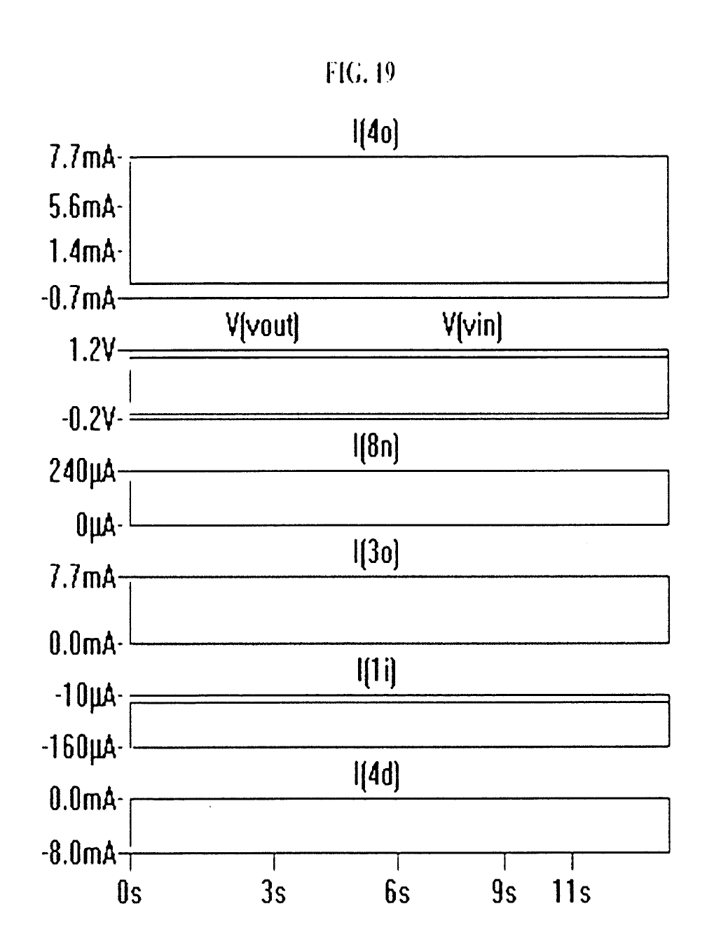

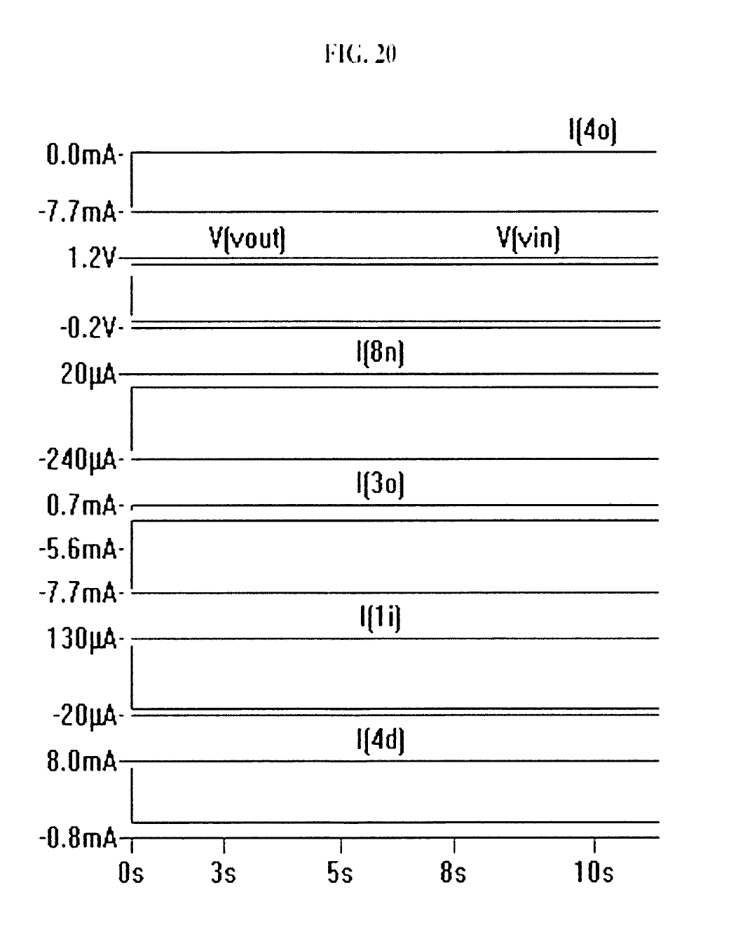

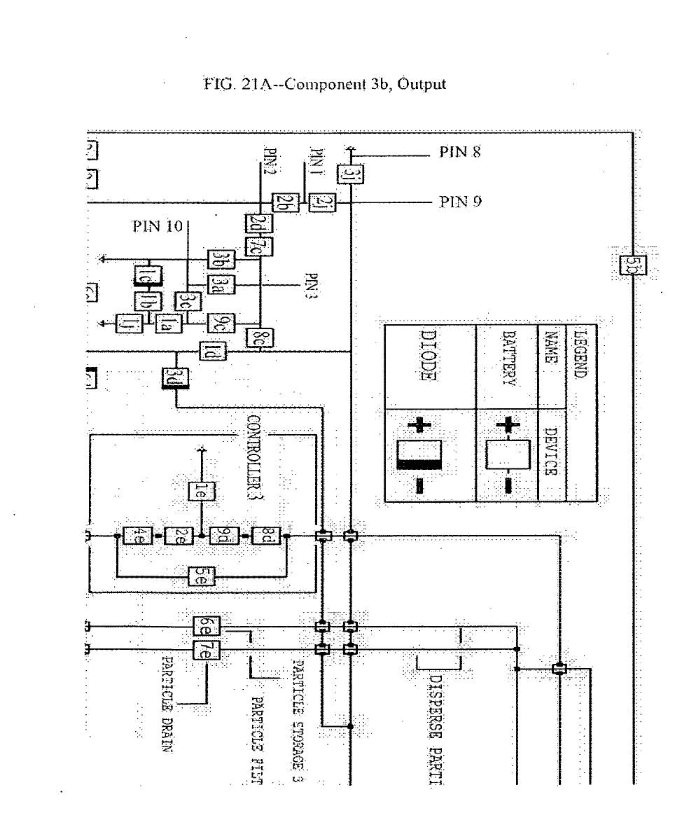

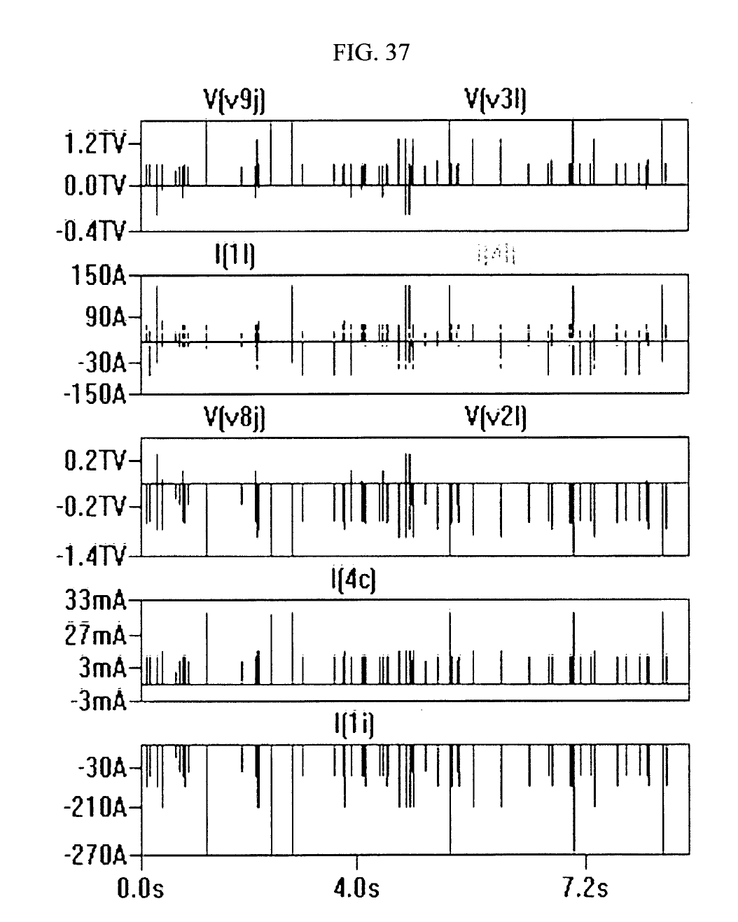

Open components like capacitors can be used to have a desired output such as that of FIG. 1 (see FIG. 17 and FIG. 18); FIG. 15 (see FIG. 19 and FIG. 20) and FIG. 21 (see FIG. 16, CURRENT LIMITER 2 and FIG. 37 The output of some components of FIG. 21).

FIG. 21 is a circuit that oscillates for 10 seconds giving high voltage and current output for a limited time of only 10 seconds.

Another current limiter (CURRENT LIMITER 3) is a RESISTOR CAPACITOR (RC) CURRENT LIMITER. MADE UP OF 2 SMALL 1P FARAD) PARALLEL CAPACITORS SEPARATED BY 2 SMALL (1 OHM) PARALLEL RESISTORS. In this CURRENT LIMITER, HIGHER RESISTORS=LESS CURRENT and LOWER RESISTORS=MORE CURRENT see FIG. 4.

Also, for the OUTPUT ARRAY(s) for example component 8b, this component allows a SAFE MODE for any higher resistors as component 9b see FIG. 3, FIG. 4, FIG. 5, FIG. 6, FIG. 7, FIG. 8, FIG. 13, FIG. 22 and FIG. 34.

The OUTPUT ARRAY functions because of POTENTIAL ENERGY (PARTICLE TENDENCY ZONE and EXTENDED PARTICLE TENDENCY ZONE) from storage of particles; there are two types of OUTPUT ARRAY(s) among the above mentioned OUTPUT ARRAY(s). One is an OPEN OUTPUT ARRAY (component 2b—is a capacitor—of FIG. 6, FIG. 7 and FIG. 34), and the other is a SWITCHING OUTPUT ARRAY (component 2b—is a voltage controlled switch—of FIG. 3, FIG. 4, FIG. 5, FIG. 8, FIG. 22, also FIG. 13 and FIG. 14, which have OUTPUT ARRAY ZONE(s) between components 2o and 2b.

The odd figure FIG. 3 is simply a demonstration of a particle filter used in the initial process of the more complex figures of THE BPT CIRCUIT.

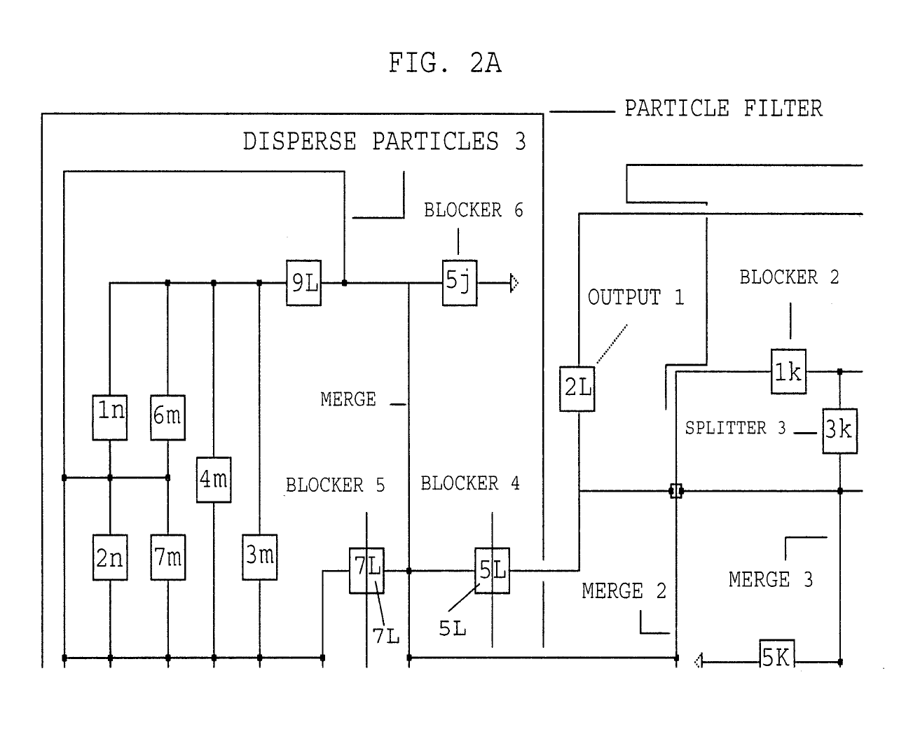

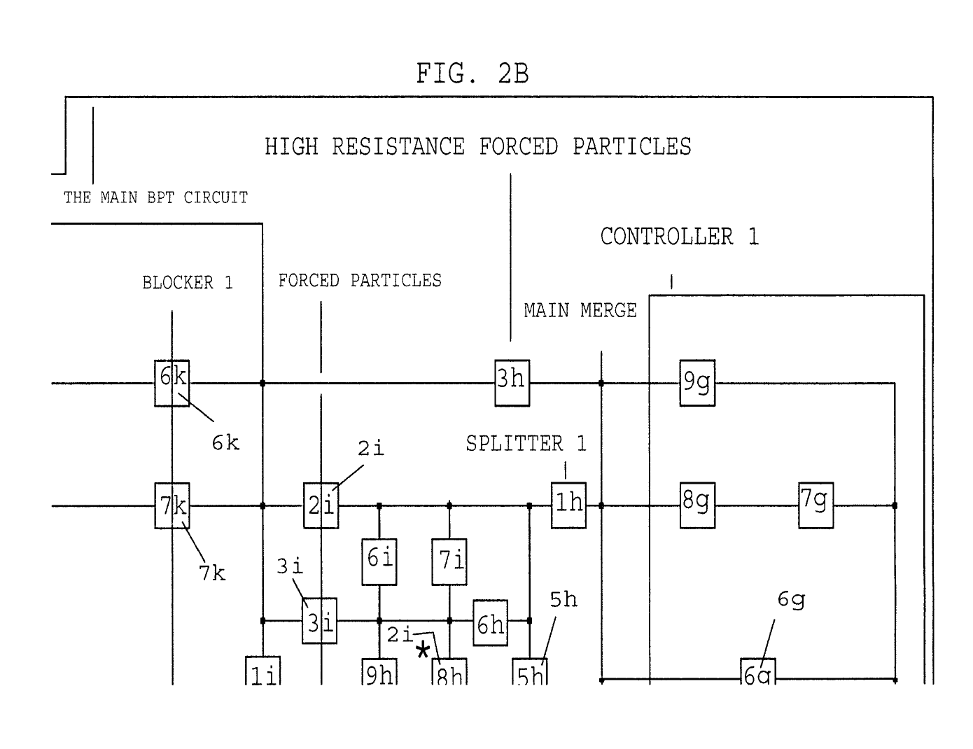

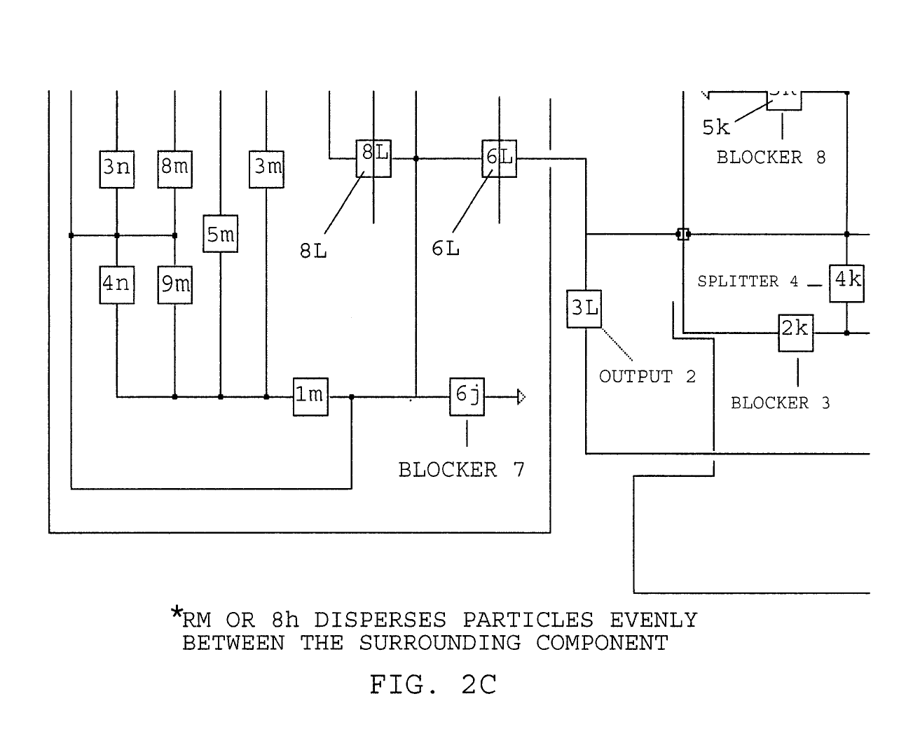

The remaining figures FIG. 1 and FIG. 15 are figures of a slightly more complex version of THE BPT CIRCUIT in comparison to FIG. 2. FIG. 1 and FIG. 15 are simply the first steps in realizing THE PARTICLE TENDENCY ZONE and EXTENDED PARTICLE TENDENCY ZONE.

There has thus been outlined, rather broadly, the more important features of the invention in order that the detailed description thereof may be better understood, and in order that the present contribution to the art may be better appreciated. There are additional features of the invention that will be described hereinafter.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

A primary object of the present invention is to provide a device, my invention, THE BRAITHWAITE PARTICLE TRAP, a small device that is for or used to generate limitless electrical power that will overcome the shortcomings of the prior art devices.

An object of the present invention is to provide a device, my invention, THE BRAITHWAITE PARTICLE TRAP, a small device that is for or used to generate limitless electrical power. THE BPT CIRCUIT works simply by using Like-Forces (+ verses +) and (− verses −) or charges instead of Opposite-Forces (+ verses −) to produce power or to increase electrical power greatly. In general, great electrical power exists not only by having a great flow of energy or current. Electrical power can be made to increase because there is a great isolation of particles set aside to perform a function at a later time. When used, the isolation of particles helps to accumulate opposite charges with sometimes its greatest potential. In other words, as soon as one particular charge (protons or electrons) or while those charges accumulate—or in the sense of protons—and are isolated, the POTENTIAL ENERGY gains force to observe atomic particles of its opposite nature. Using THE BPT CIRCUIT, in conjunction with battery power, to perform such a task so that when stored energy is manipulated to discharge, there is both great current and voltage not simply great voltage and small current or static electricity, there is enormous of a difference from the battery power connected to THE BPT CIRCUIT.

Another object is to provide a device, my invention, THE BRAITHWAITE PARTICLE TRAP, a small device that is for or used to generate limitless electrical power that Provides electrical power from a simple and small source.

Another object is to provide a device, my invention, THE BRAITHWAITE PARTICLE TRAP, a small device that is for or used to generate limitless electrical power, that doesn't create much heat as a byproduct.

Another object is to provide a device, my invention, THE BRAITHWAITE PARTICLE TRAP, a small device that is for or used to generate limitless electrical power that uses only one to three batteries as an initial power source.

Another object is to provide a device, my invention, THE BRAITHWAITE PARTICLE TRAP, a small device that is for or used to generate limitless electrical power, that is safe to touch the anode and cathode of a connected component as long as the current is grounded by a parallel component of about 1 Ohm—SAFE MODE due to component 8b see FIG. 3, FIG. 4, FIG. 5, FIG. 6, FIG. 7, FIG. 8, FIG. 22 and FIG. 34—.

Another object is to provide a device, my invention, THE BRAITHWAITE PARTICLE TRAP, a small device that is for or used to generate limitless electrical power that uses only a small amount of components to make it work.

Another object is to provide a device, my invention, THE BRAITHWAITE PARTICLE TRAP, a small device that is for or used to generate limitless electrical power where most of the component values of the circuit are high in resistant value to provide a circuit that uses less power from batteries, while there is a great gain in electrical power.

Another object is to provide a device, my invention, THE BRAITHWAITE PARTICLE TRAP, a small device that is for or used to generate limitless electrical power, that can be made into microchip form and can exist as a very powerful electrical power source being able to power about 100 devices giving about 10 Million Amps to each device at the same time See FIG. 3, FIG. 4, FIG. 5, FIG. 6, FIG. 7, FIG. 8, FIG. 13, FIG. 14, FIG. 22 and FIG. 34, all of these circuits have OUTPUT ARRAY(s) or a ZONE for an OUTPUT ARRAY. The OUTPUT ARRAY(s) for the figures except FIG. 13 and FIG. 14 (limited to 8 components) are limited to using only 9 components (1a, 2a, 3a, 4a, 9a, 2b, 8b, 9b, and 1c) at Ground, just for demonstrative purposes. With more experimentation, more devices or components than 9 can be used in a BPT CIRCUITS OUTPUT ARRAY.

Other objects and advantages of the present invention will become obvious to the reader and it is intended that these objects and advantages are within the scope of the present invention.

To the accomplishment of the above and related objects, this invention may be embodied in the form illustrated in the accompanying drawings, attention being called to the fact, however, that the drawings are illustrative only, and that changes may be made in the specific construction illustrated.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

This is a view of the simplest BPT CIRCUIT form, with an output technique

### FIG. 1—Represented by FIGS. 1A, 1B, 1C, and 1D

This is THE BPT MAIN CIRCUIT, THIS COMPLETED CIRCUIT MAINTAINS THE DIRECTION OF THE PARTICLES and it does not HAVE AN OUTPUT ARRAY. THIS IS A SMALL-RESISTOR-TYPE-BPT-CIRCUIT

BLOWN UP VIEWS OF FIG. 1:

### FIG. 1A, FIG. 1B, FIG. 1C and FIG. 1D

BILL OF MATERIALS (BOM) of FIG. 1:

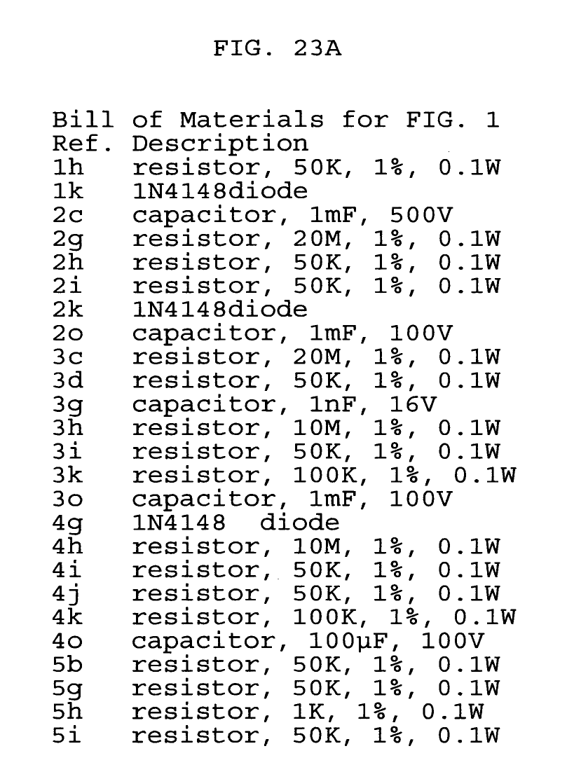

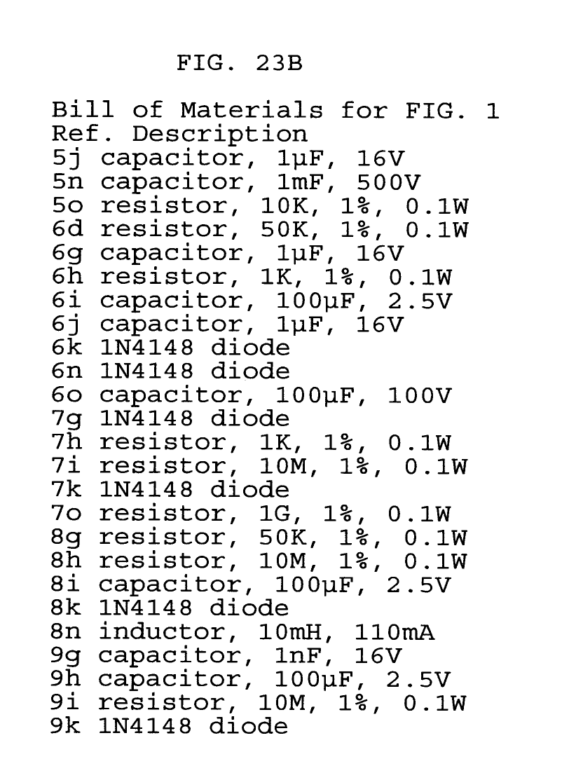

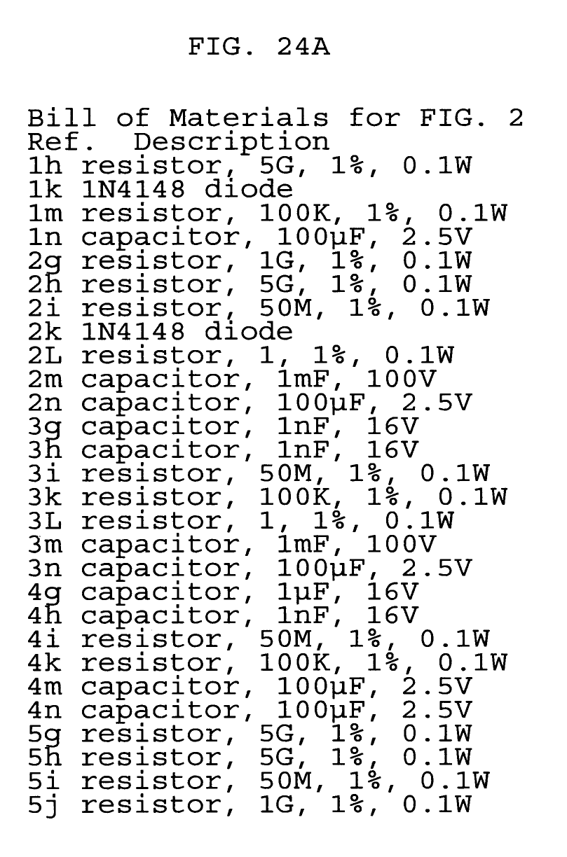

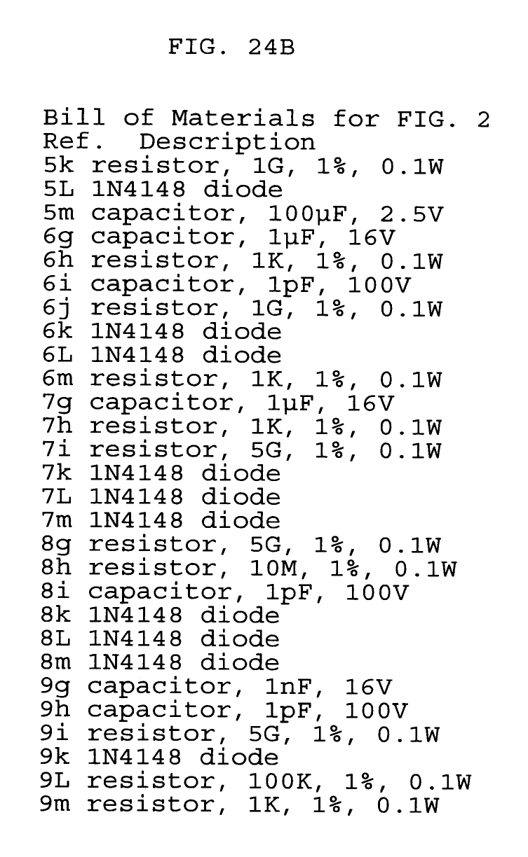

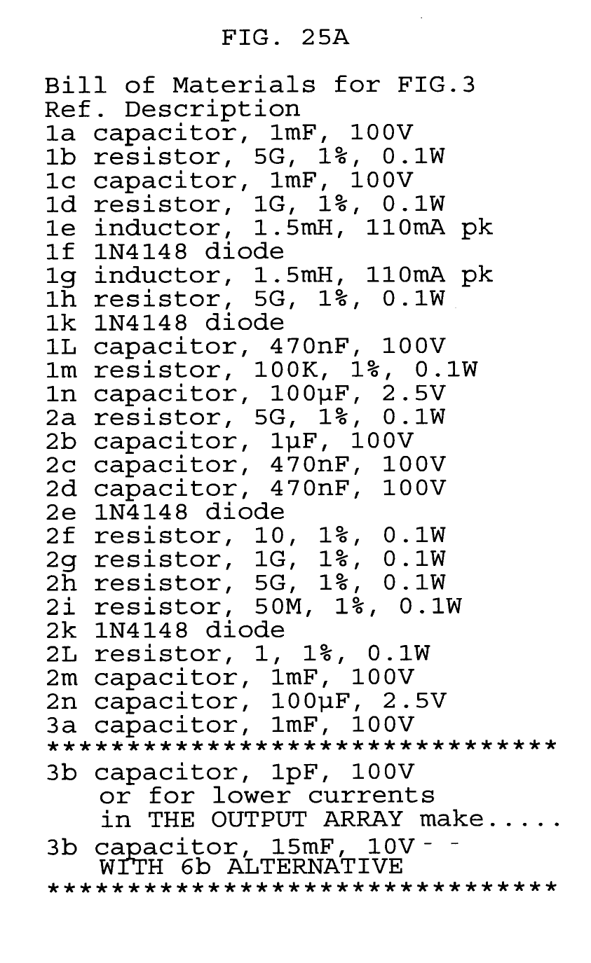

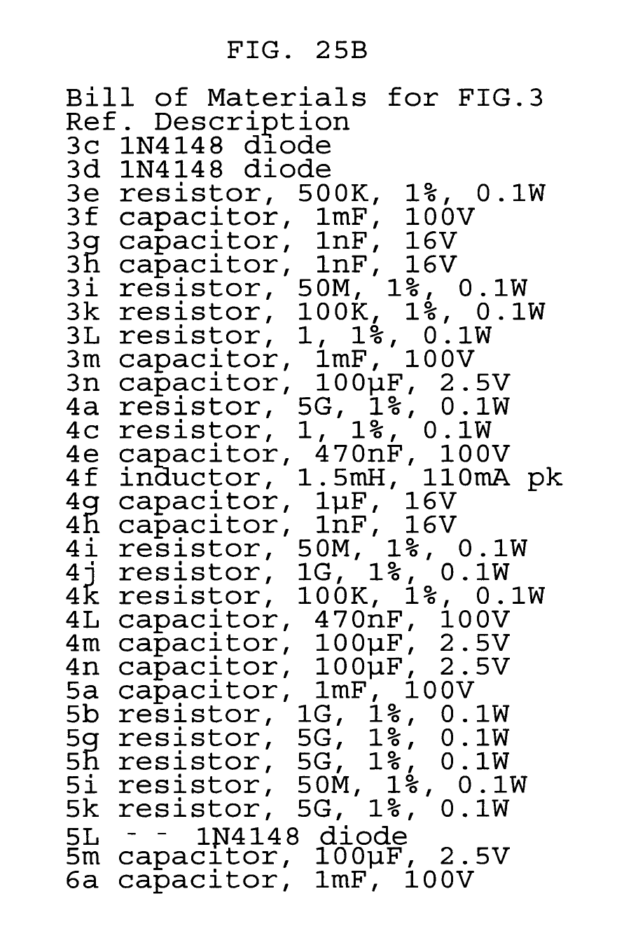

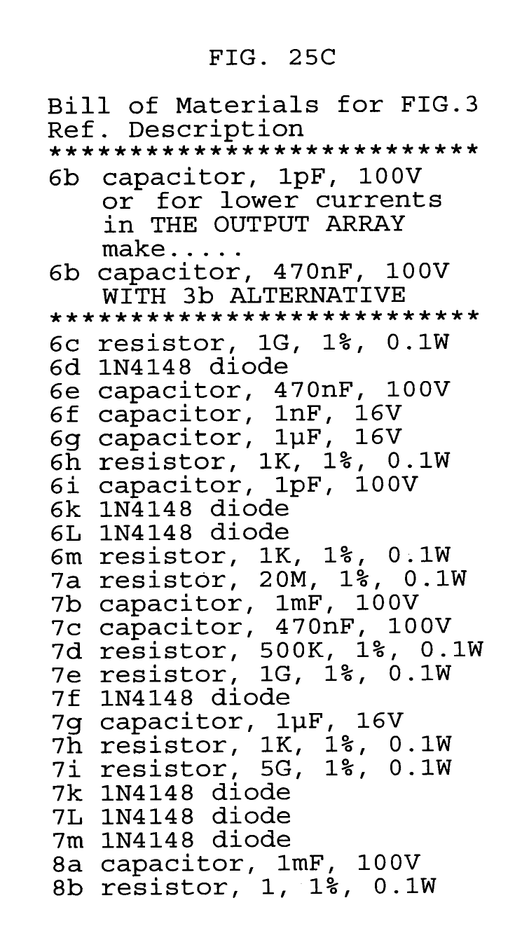

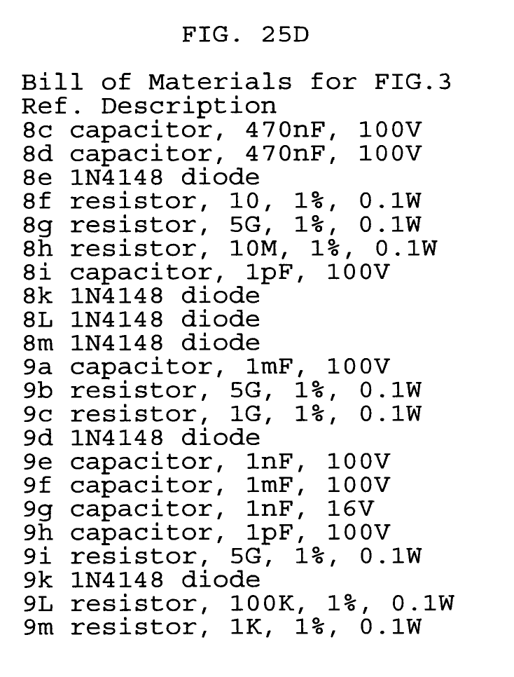

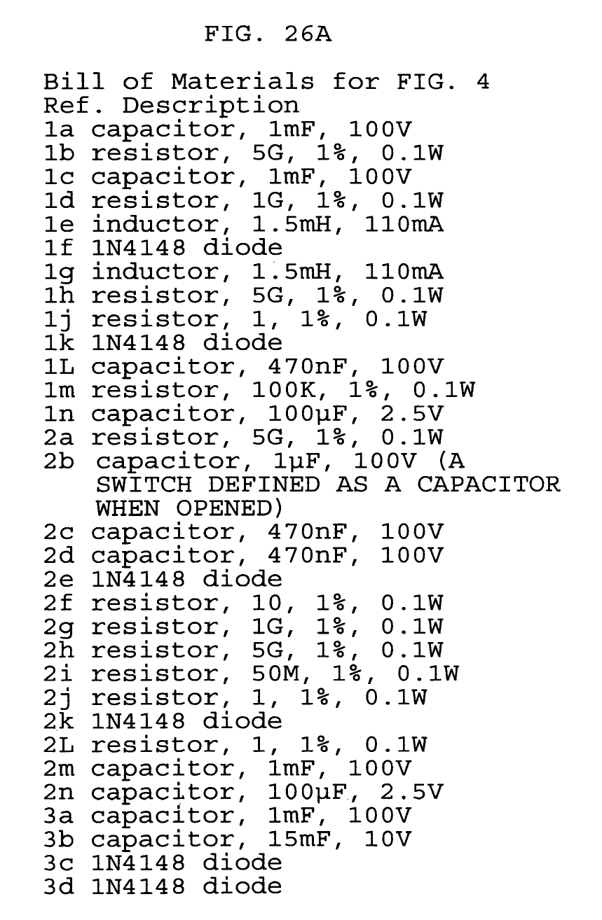

### FIG. 23A, and FIG. 23B

This is a view of the simplest BPT CIRCUIT form, with an output technique

### FIG. 2—Represented by FIGS. 2A, 2B, 2C, and 2D

THE PARTICLE FILTER AND THE MAIN BPT CIRCUIT, OUTPUT AT SOME FREQUENCIES (TIMED-PARTICLES) FROM THE BPT MAIN CIRCUIT, allows the PARTICLE FILTER CIRCUIT of this version of THE BPT CIRCUIT to give the entire BPT CIRCUIT less harmonics. THE PARTICLE FILTER basically is a part of THE BPT CIRCUIT of FIG. 2. The filter is a FILTER for PARTICLES THAT HAVE A FREQUENCY (TIMED-PARTICLES). THE PARTICLE FILTER is useful only at the initial stage of making THE BPT CIRCUIT. As the circuit becomes more complex and power increases, the need for a PARTICLE FILTER CIRCUIT decreases.

BLOWN UP VIEWS OF FIG. 2:

### FIG. 2A, FIG. 2B, FIG. 2C, FIG. 2D

BOM of FIG. 2:

### FIG. 24A, and FIG. 24B

This is a view of a more complex BPT CIRCUIT form, with an output technique

### FIG. 3—Represented by FIGS. 16A, 16B, 16C, and 16D

### THIS COMPLETED CIRCUIT MAINTAINS THE DIRECTION OF THE PARTICLES AND ALSO USES AN OUTPUT ARRAY.

BLOWN UP VIEWS OF FIG. 3:

### FIG. 16A, FIG. 16B, FIG. 16C, and FIG. 16D

BOM of FIG. 3:

### FIG. 25A, FIG. 25B, FIG. 25C, and FIG. 25D

This is a view of a more complex BPT CIRCUIT form, with an output technique

### FIG. 4—Represented by FIGS. 16A, 16B, 16C, and 16D

### THIS COMPLETED CIRCUIT MAINTAINS THE DIRECTION OF THE PARTICLES AND ALSO USES AN OUTPUT ARRAY.

BLOWN UP VIEWS OF FIG. 4:

### FIG. 16A, FIG. 16B, FIG. 16C, and FIG. 16D

BOM of FIG. 4:

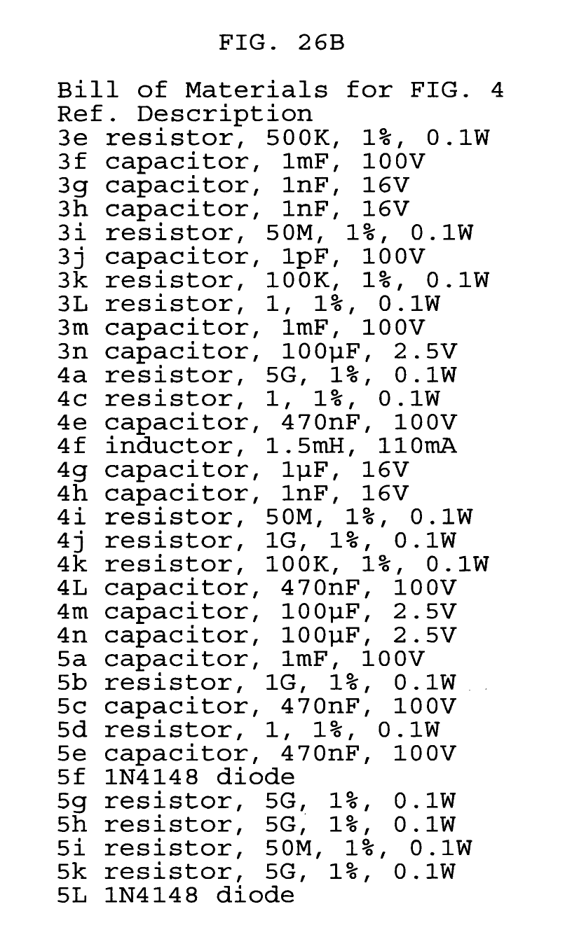

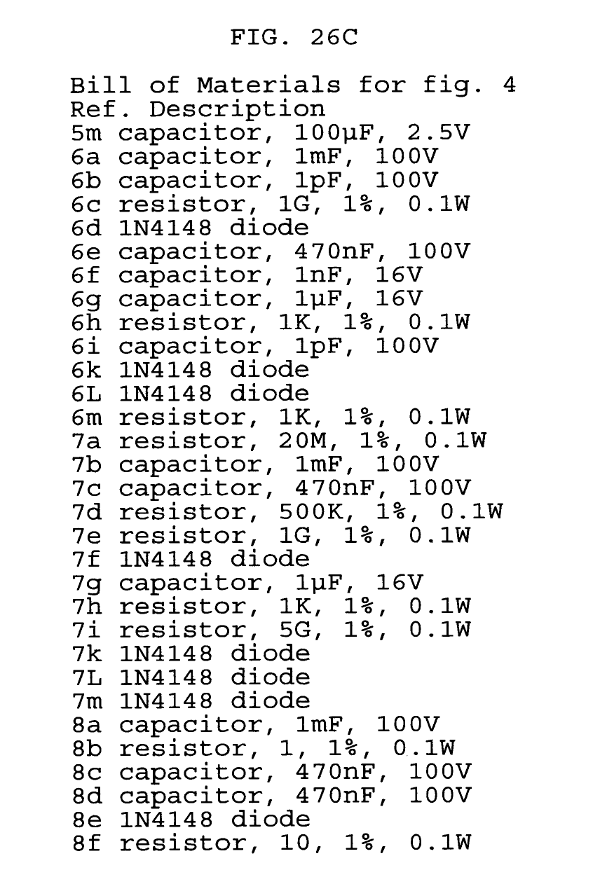

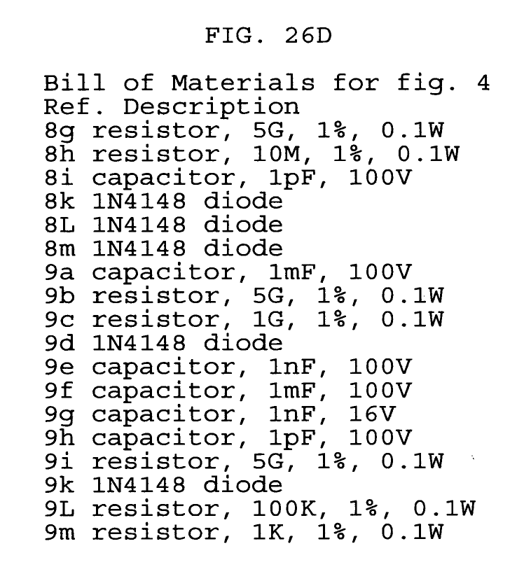

### FIG. 26A, FIG. 26B, FIG. 26C, and FIG. 26D

This is a view of the simplest BPT CIRCUIT form, with an output technique

### FIG. 5—Represented by FIGS. 5A, 5B, 5C, and 5D

### THIS COMPLETED CIRCUIT MAINTAINS THE DIRECTION OF THE PARTICLES AND ALSO USES AN OUTPUT ARRAY.

BLOWN UP VIEWS OF FIG. 5:

### FIG. 5A, FIG. 5B, FIG. 5C, and FIG. 5D

BOM of FIG. 5

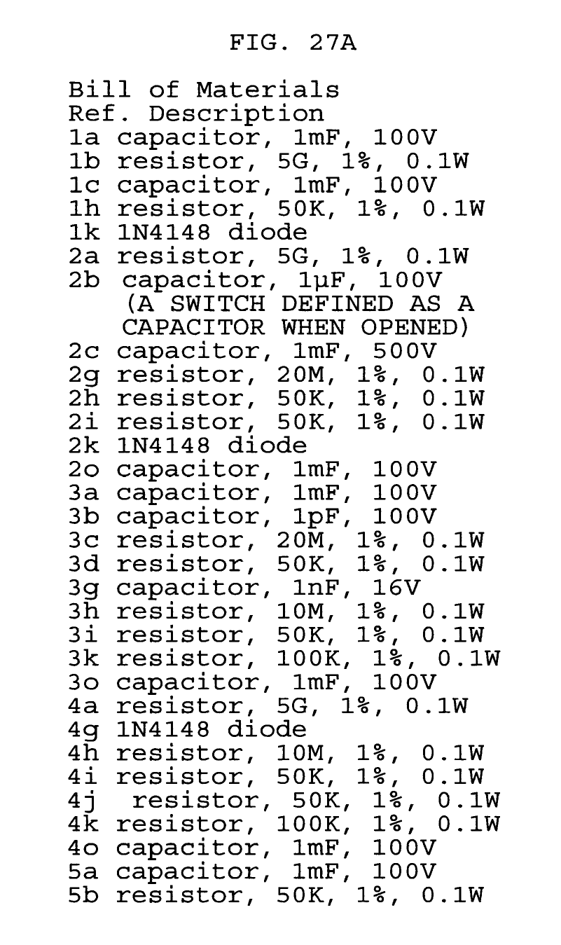

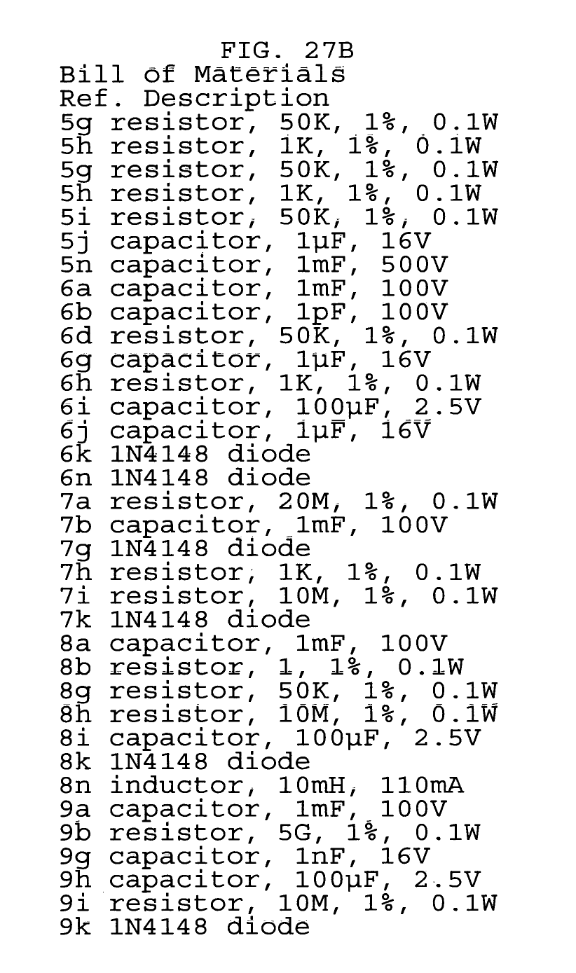

### FIG. 27A, and FIG. 27B

This is a view of a more complex BPT CIRCUIT form, with an output technique

### FIG. 6—Represented by FIGS. 6A, 16B, 16C, and 16D

### THIS COMPLETED CIRCUIT MAINTAINS THE DIRECTION OF THE PARTICLES AND ALSO USES AN OUTPUT ARRAY.

BLOWN UP VIEWS OF FIG. 6:

### FIG. 6A, FIG. 16B, FIG. 16C, and FIG. 16D

BOM of FIG. 6

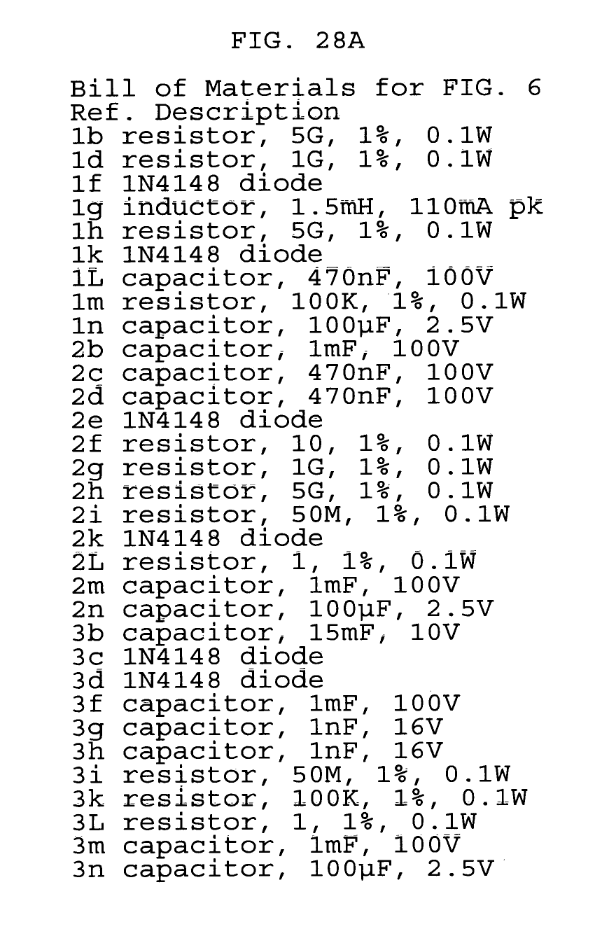

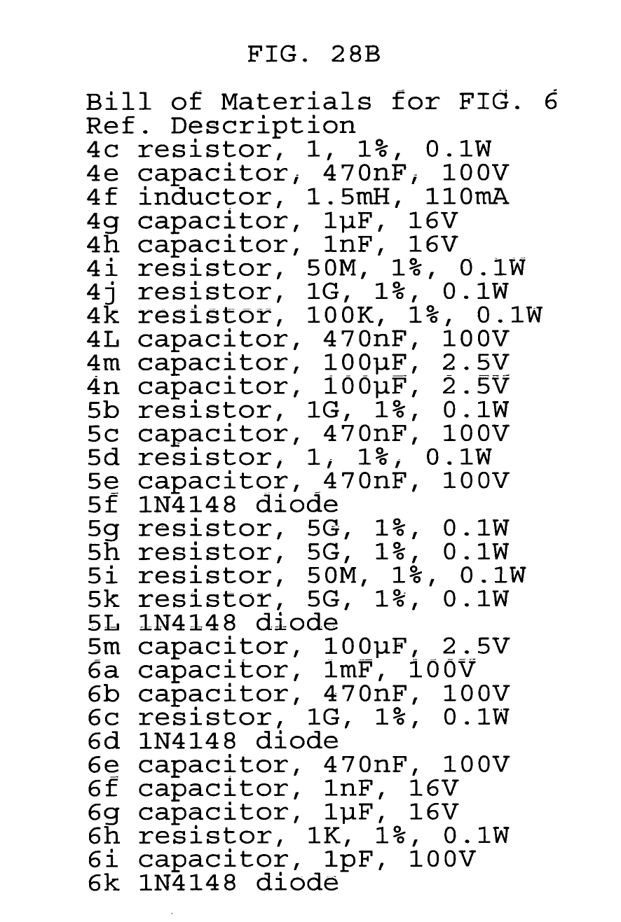

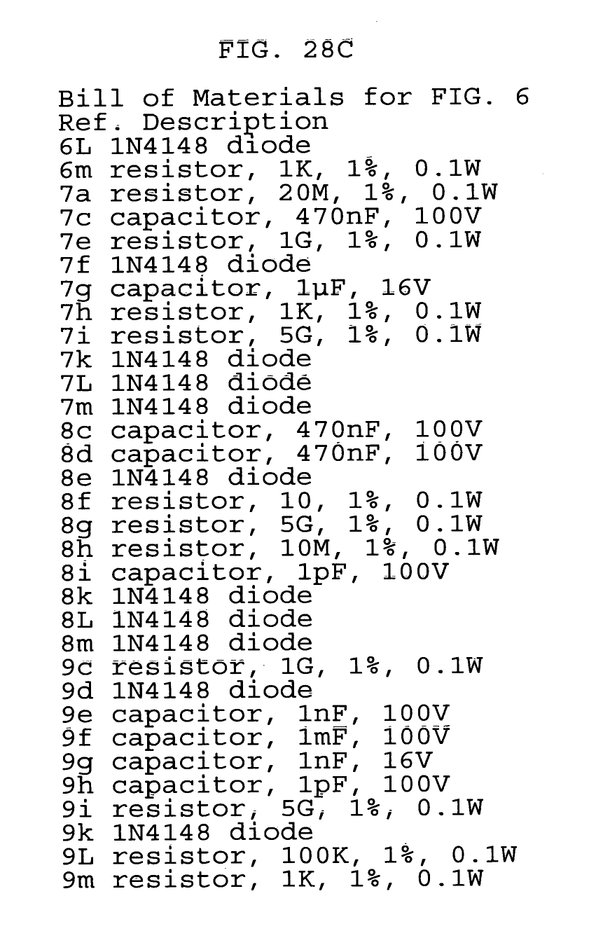

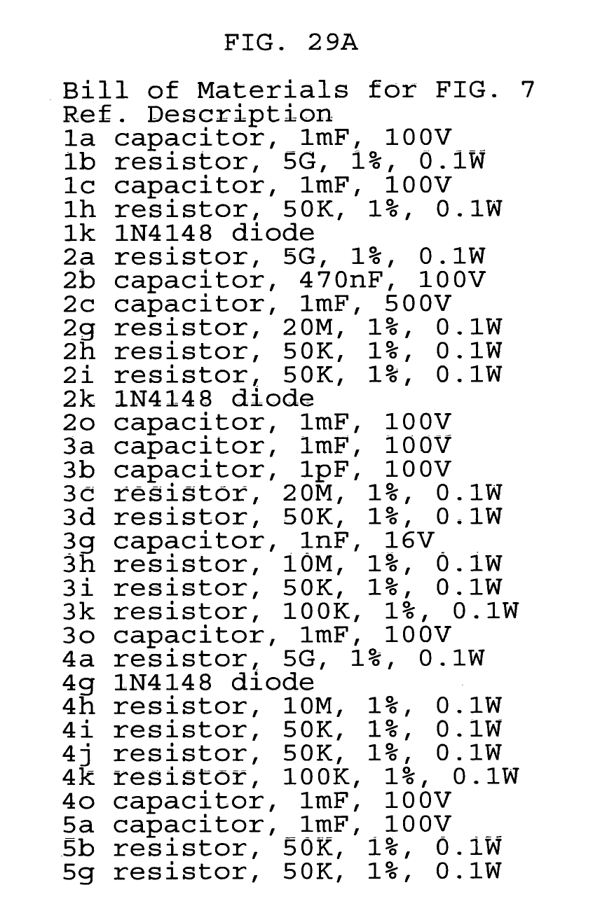

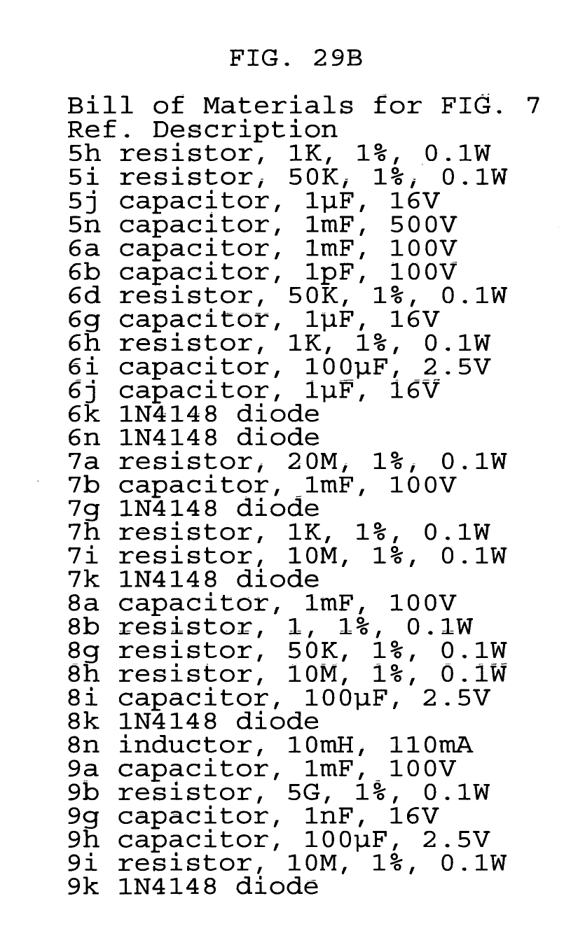

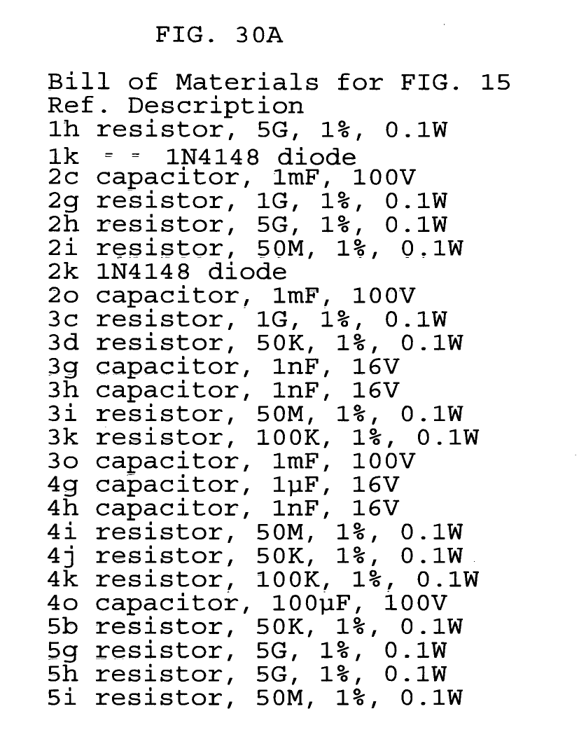

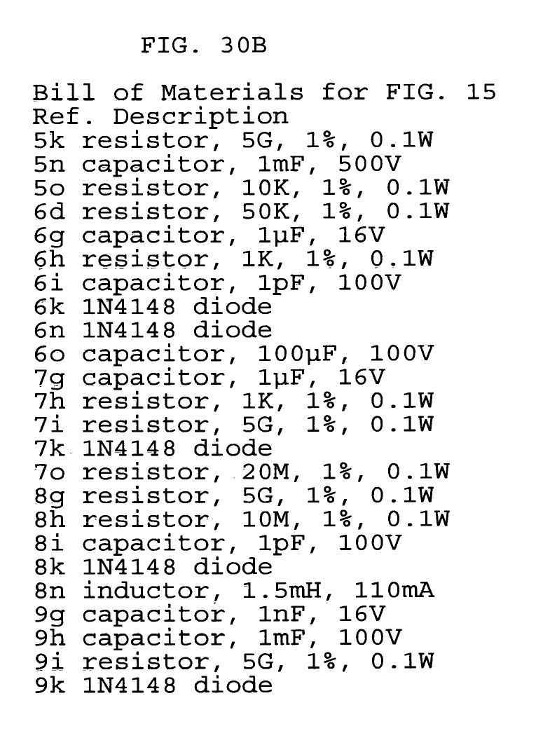

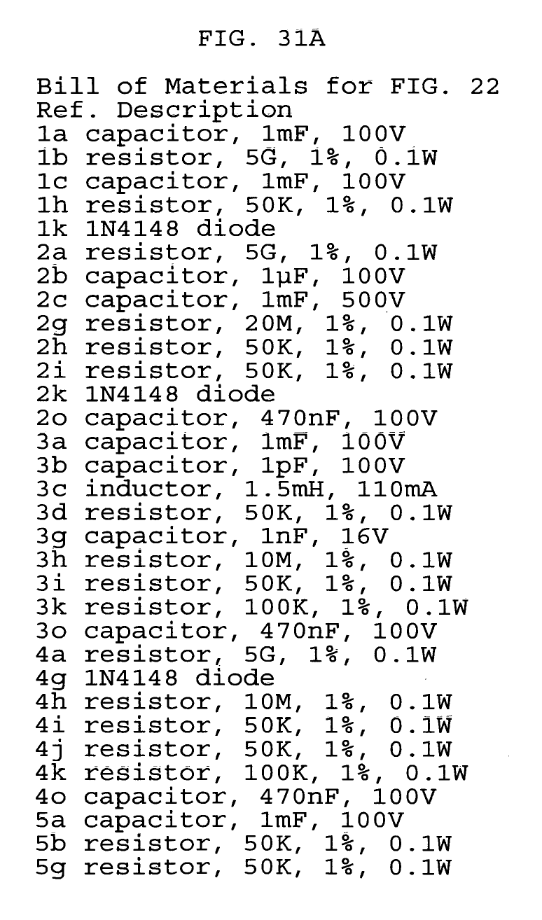

### FIG. 28A, FIG. 28B, and FIG. 28C

This is a view of the simplest BPT CIRCUIT form, with an output technique

### FIG. 7—Represented by FIG. 16A, 16B, 16C, and 16D

### THIS COMPLETED CIRCUIT MAINTAINS THE DIRECTION OF THE PARTICLES AND ALSO USES AN OUTPUT ARRAY.

BLOWN UP VIEWS OF FIG. 7:

### FIG. 16A, FIG. 16B, FIG. 16C, and FIG. 16D

BOM of FIG. 7

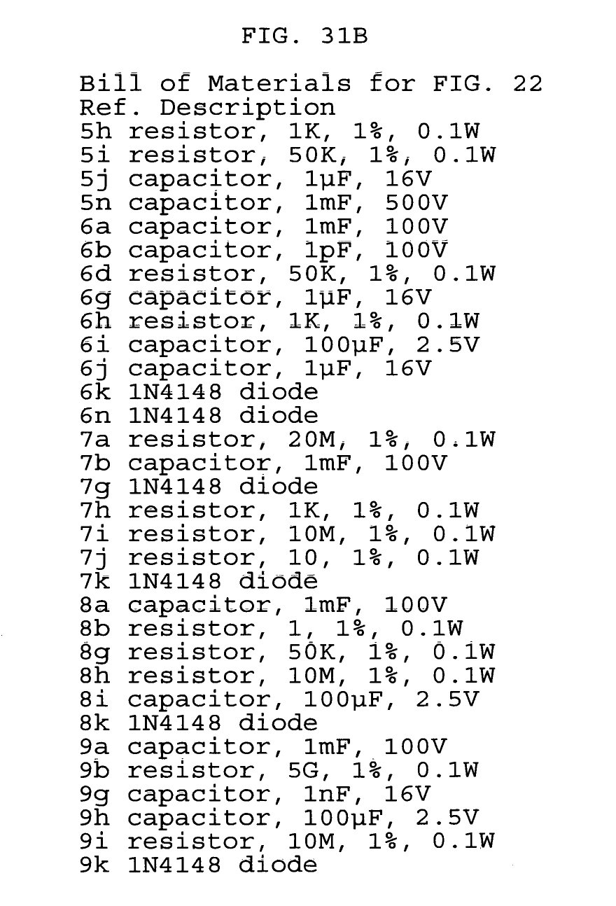

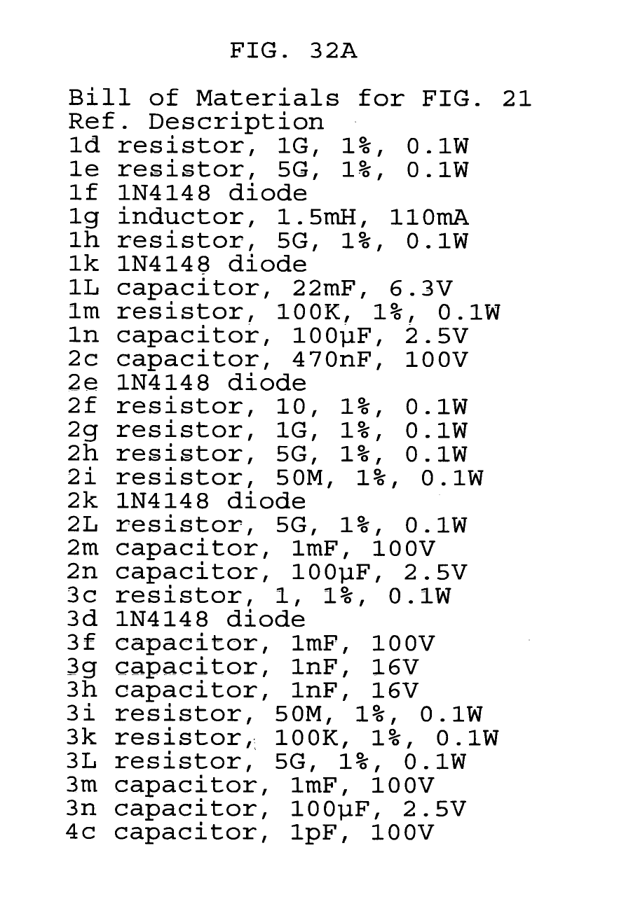

### FIG. 29A, and FIG. 29B

This is a view of a more complex BPT CIRCUIT form, with an output technique

### FIG. 8—Represented by FIGS. 16A, 16B, 16C, and 16D

### THIS COMPLETED CIRCUIT MAINTAINS THE DIRECTION OF THE PARTICLES AND ALSO USES AN OUTPUT ARRAY. IN THIS CIRCUIT THE DIODES ARE REPLACED BY RESISTORS.

BLOWN UP VIEWS OF FIG. 8:

### FIG. 16A, FIG. 16B, FIG. 16C, and FIG. 16D

BOM of FIG. 8

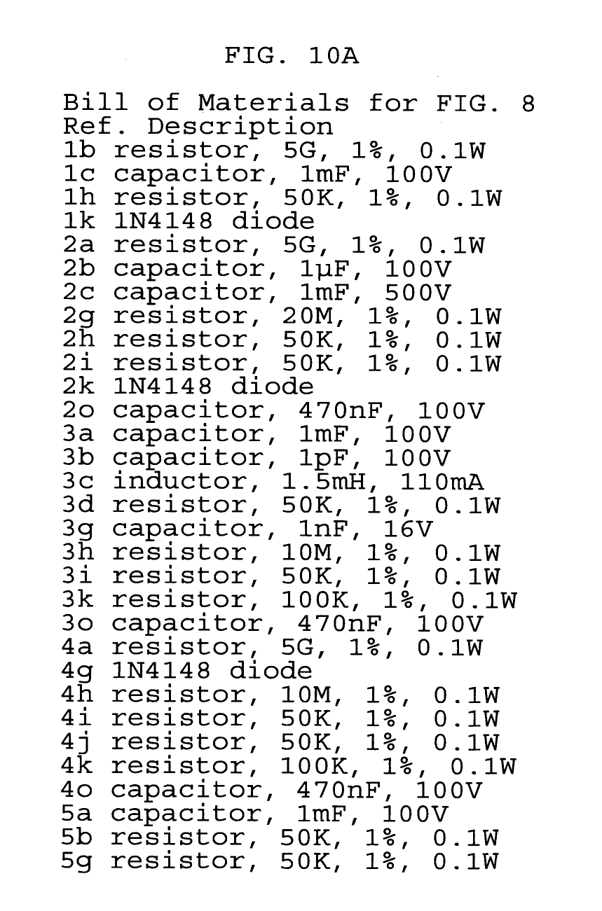

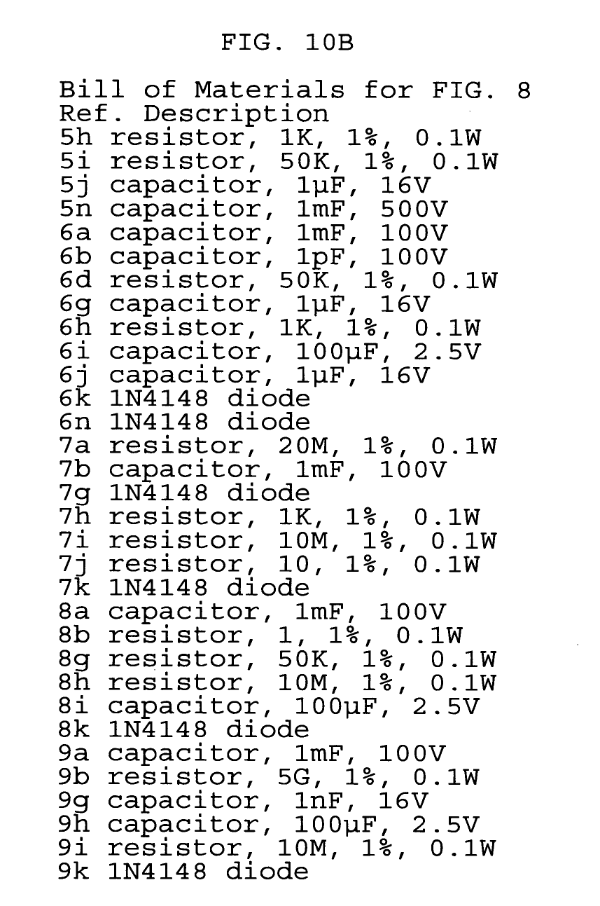

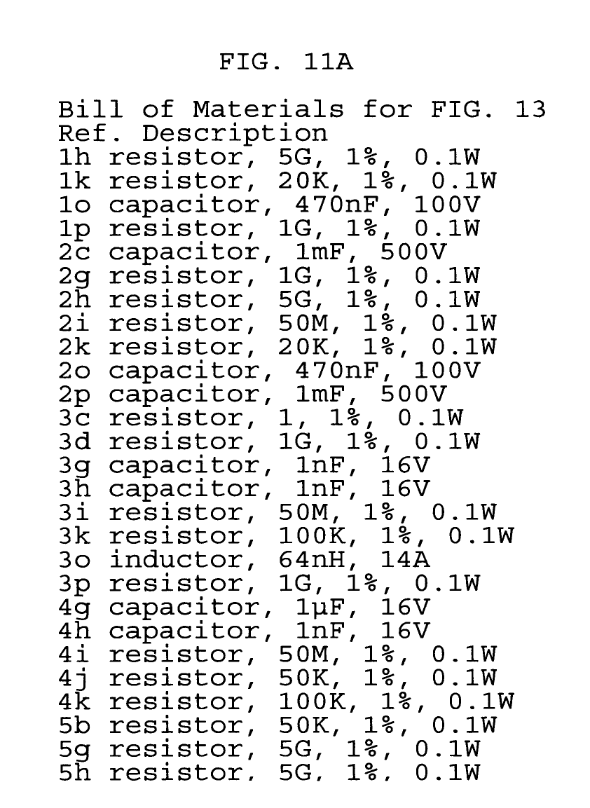

### FIG. 10A, and FIG. 10B

This is a voltage output view

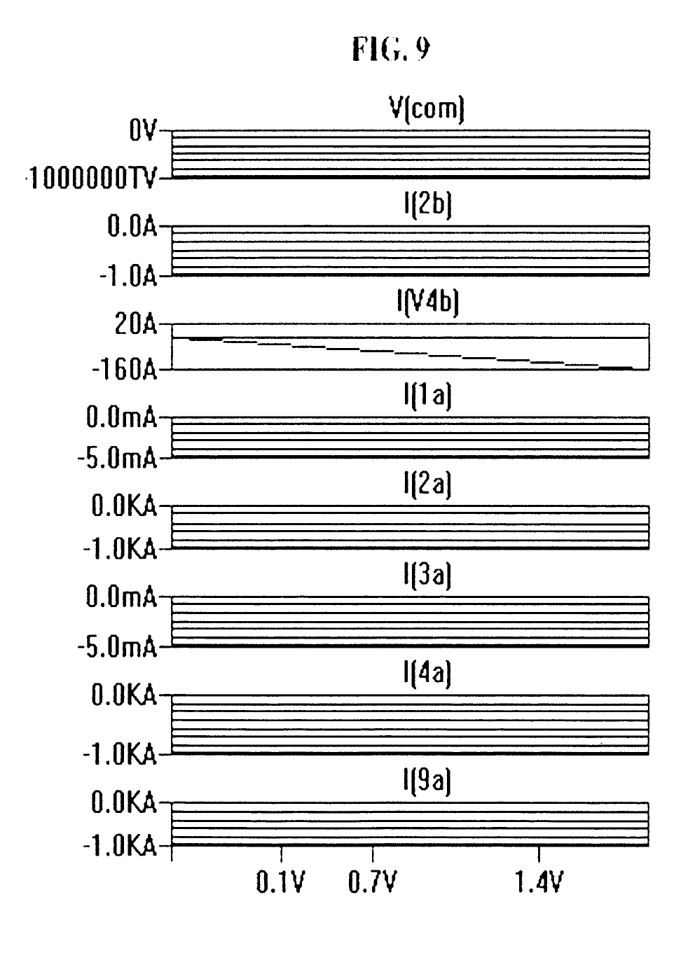

### FIG. 9

### A WAVEFORM OUTPUT OF FIG. 8

This is a view of the simplest BPT CIRCUIT form, with an output technique

### FIG. 13—Represented by FIGS. 13A, 13B, 13C, and 13D

### THE BPT MAIN CIRCUIT, THIS COMPLETED CIRCUIT MAINTAINS THE DIRECTION OF THE PARTICLES AND IT HAS AN OUTPUT ARRAY ZONE CONTROLLED BY A SWITCH. THIS IS A LARGE RESISTOR TYPE BPT CIRCUIT, WITH RESISTORS USED TO REPLACE DIODES.

BLOWN UP VIEWS OF FIG. 13:

### FIG. 13A, FIG. 13B, FIG. 13C, and FIG. 13D

BOM of FIG. 13:

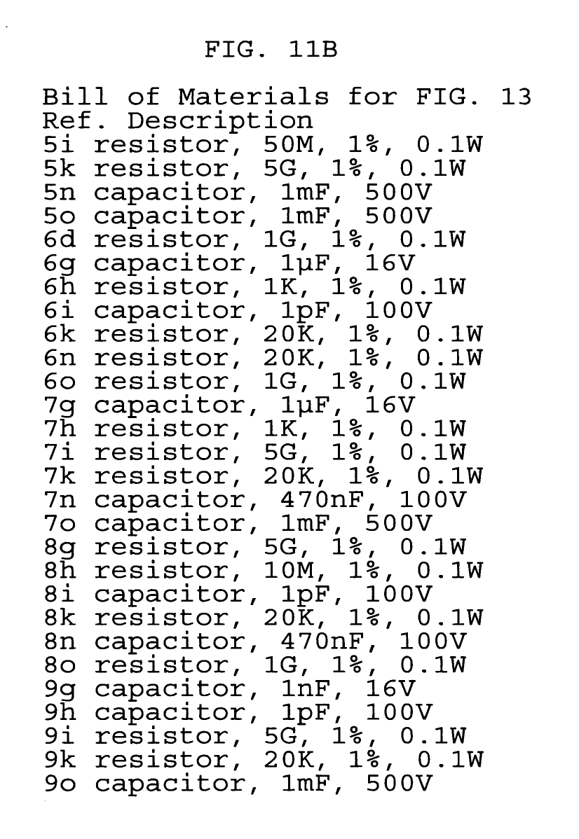

### FIG. 11A, and FIG. 11B

This is a view of the simplest BPT CIRCUIT form, with an output technique

### FIG. 14—Represented by FIGS. 13A, 13B, 13C, and 13D

### THE BPT MAIN CIRCUIT, THIS COMPLETED CIRCUIT MAINTAINS THE DIRECTION OF THE PARTICLES AND IT HAS AN OUTPUT ARRAY ZONE CONTROLLED BY A SWITCH. THIS IS A SMALL RESISTOR TYPE BPT CIRCUIT.

BLOWN UP VIEWS OF FIG. 14:

### FIGS. 13A, FIG, 13B, FIG. 13C, and FIG. 13D

BOM of FIG. 14:

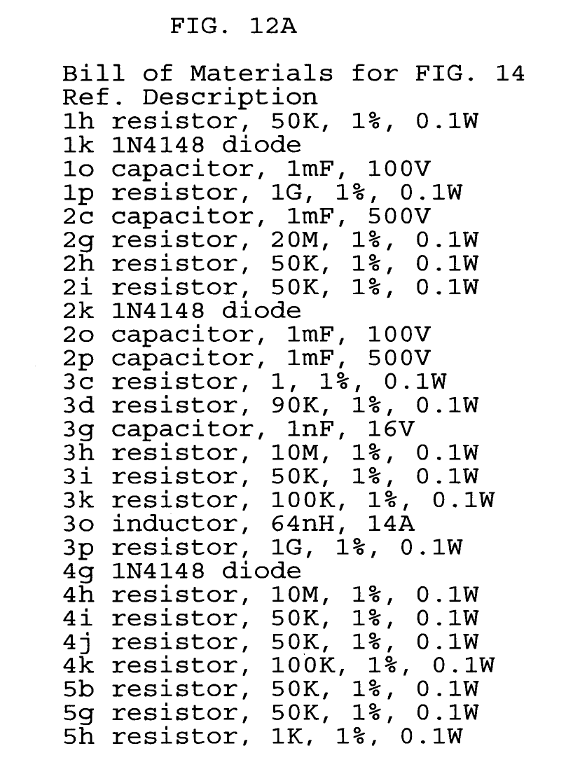

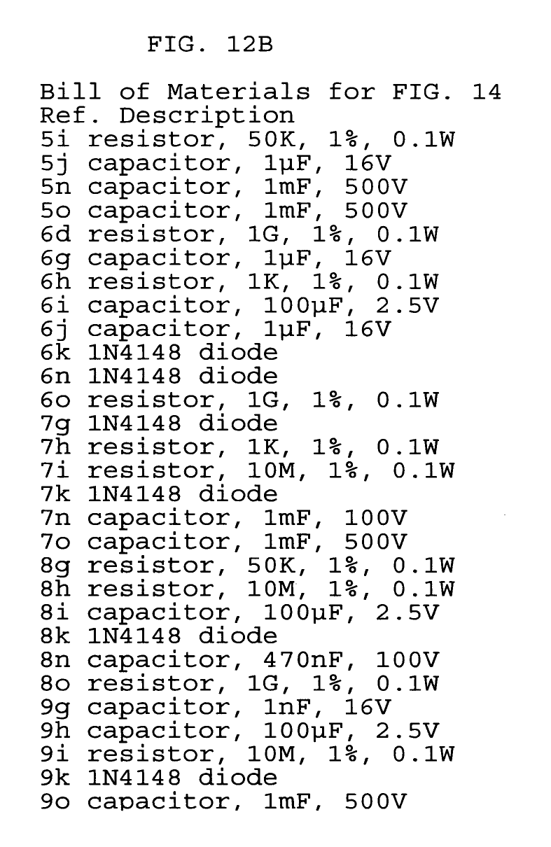

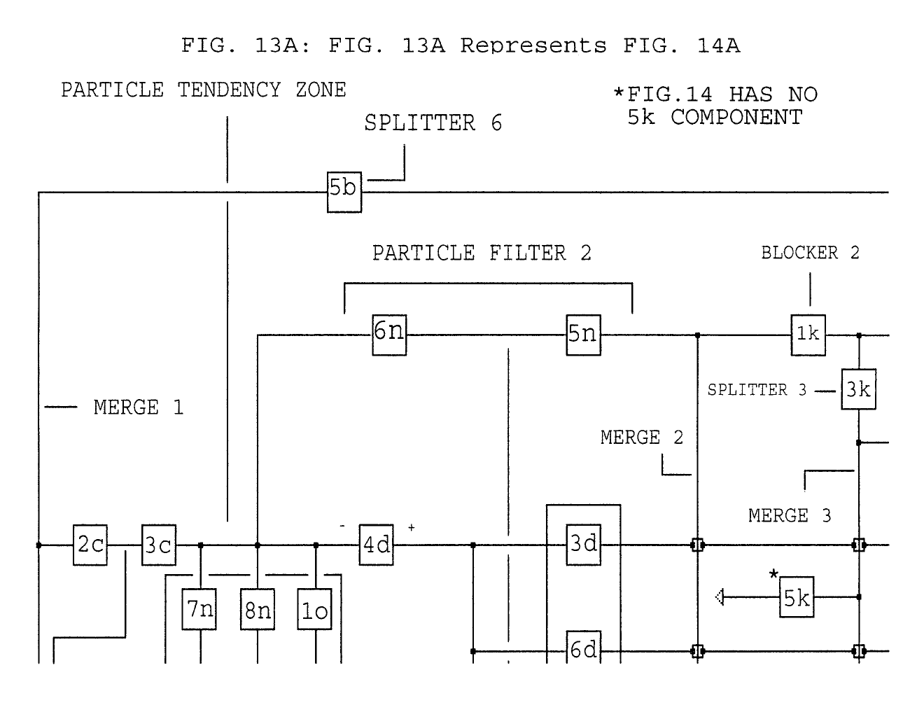

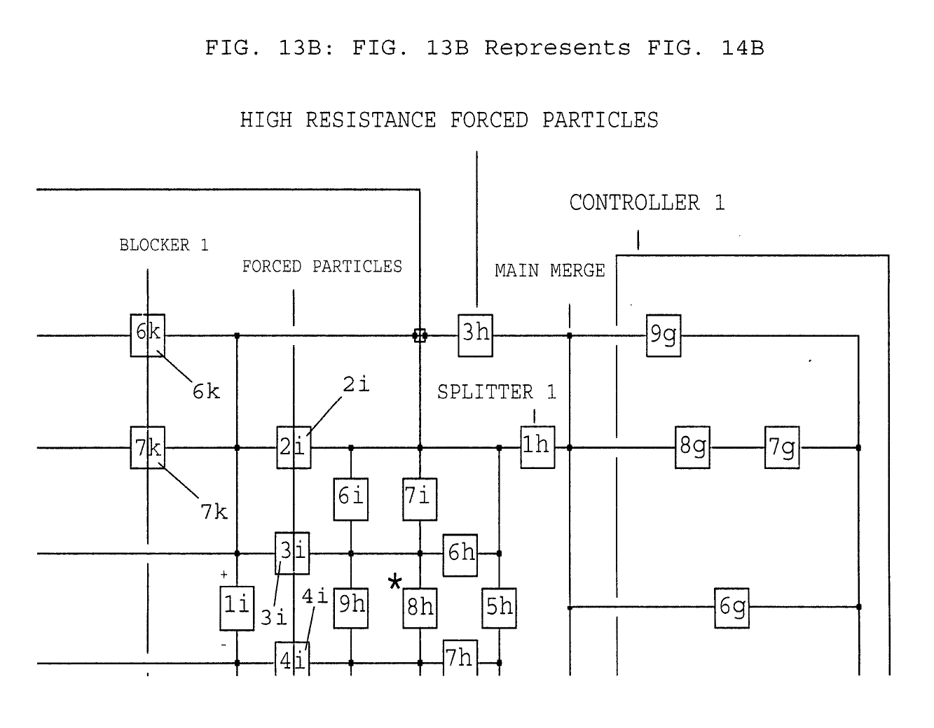

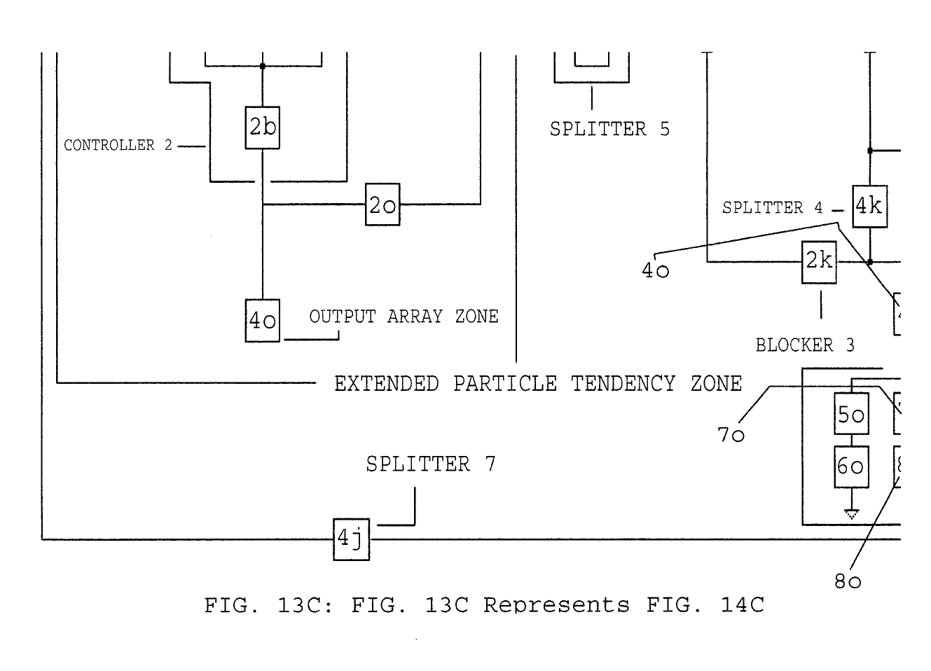

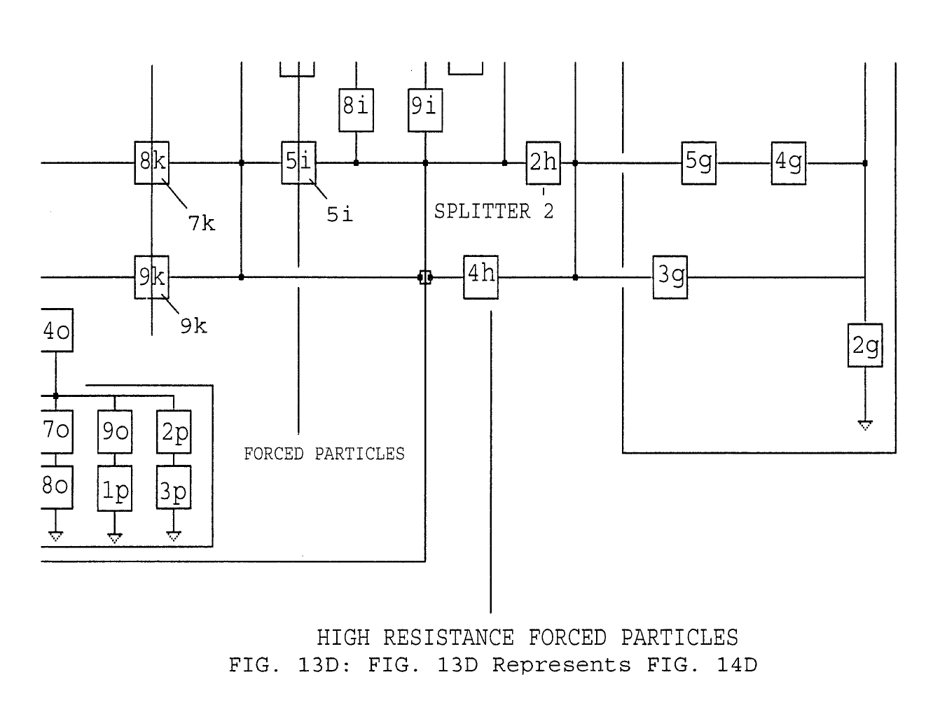

### FIG. 12A, and FIG. 12B

This is a view of the simplest BPT CIRCUIT form, with an output technique

### FIG. 15—Represented by FIGS. 15A, 15B, 15C, and 15D

### THE BPT MAIN CIRCUIT, THIS COMPLETED CIRCUIT MAINTAINS THE DIRECTION OF THE PARTICLES AND IT DOES NOT HAVE AN OUTPUT ARRAY. THIS IS A LARGE RESISTOR TYPE BPT CIRCUIT.

BLOWN UP VIEWS OF FIG. 15:

### FIG. 15A, FIG. 15B, FIG. 15C, and FIG. 15D

BOM of FIG. 15:

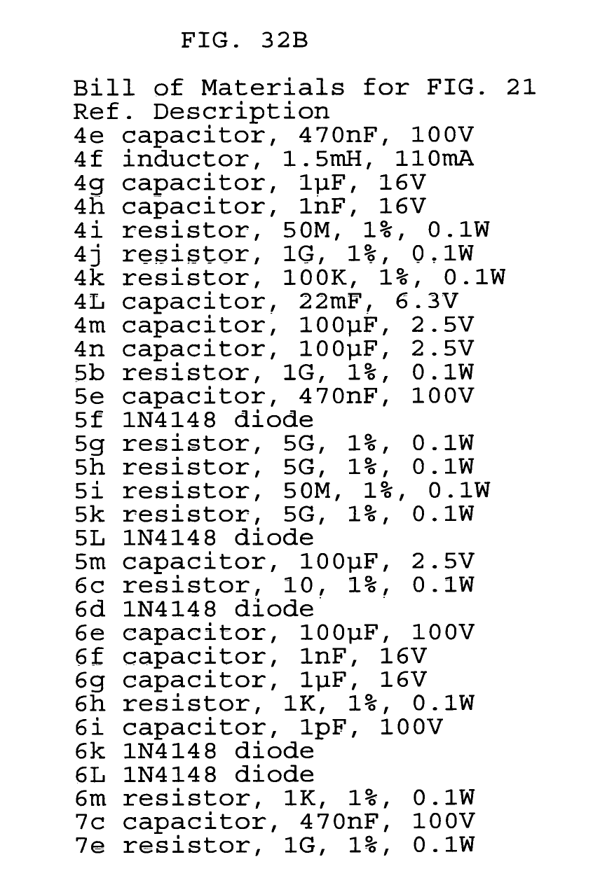

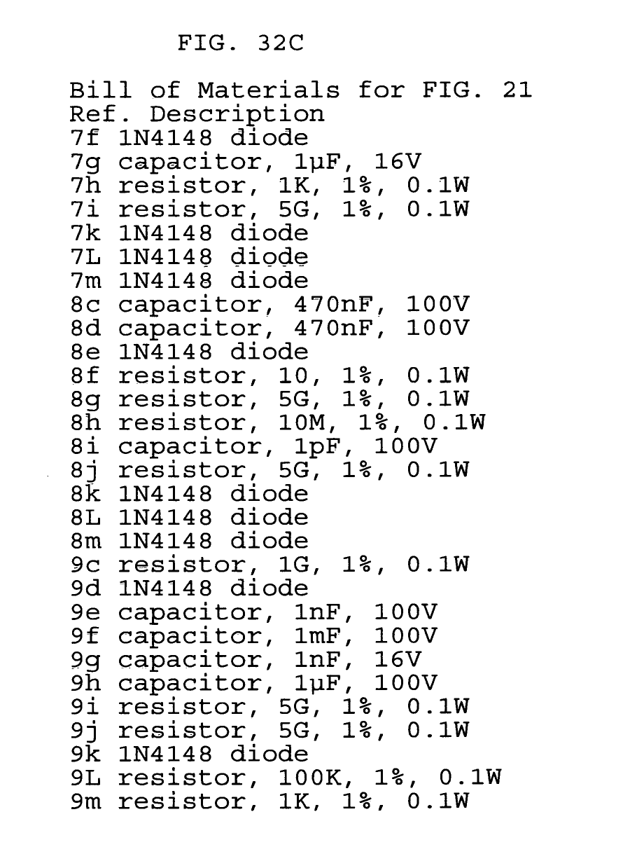

### FIG. 30A, and FIG. 30B

This is a view of a more complex BPT CIRCUIT form, with an output technique

### FIG. 16—Represented by FIGS. 16A, 16B, 16C, and 16D

SHOWS INTERCONNECTIONS OF COMPONENTS AND COMPONENT NAMES, THIS FIGURE DEFINES INTERCONNECTIONS AND NAMES OF SOME OF THE FUNCTIONS OF ZONES IN FIG. 1, FIG. 2, FIG, 3, FIG. 4, FIG. 5, FIG. 6, FIG. 7, FIG. 8, FIG. 13, FIG. 14, FIG. 15, FIG. 21, FIG. 22 and FIG. 34. For full details of all zones in all of the figures see FIG. 2, FIG. 6, FIG. 7, FIG. 13, FIG. 15, FIG. 16 FIG. 21, and FIG. 22.

This is a voltage output view

### FIG. 17

### OUTPUT OF 3 DIMENSIONALLY PROJECTED PARTICLES IN ONE INSTANCE OF FIG. 1

This is a voltage output view

### FIG. 18

### OUTPUT OF 3 DIMENSIONALLY PROJECTED PARTICLES IN ANOTHER INSTANCE OF FIG. 1

This is a voltage output view

### FIG. 19

### OUTPUT OF 3 DIMENSIONALLY PROJECTED PARTICLES IN ONE INSTANCE OF FIG. 15

This is a voltage output view

### FIG. 20

### OUTPUT OF 3 DIMENSIONALLY PROJECTED PARTICLES IN ANOTHER INSTANCE OF FIG. 15

This is a view of a more complex BPT CIRCUIT form, with an output technique

### FIG. 21—Represented by FIGS. 21A, 21B, 21C, 21D

This BPT CIRCUIT has a 10 second high voltage and current output (see FIG. 37)

BLOWN UP VIEWS OF FIG. 21:

### FIG. 21A, FIG. 21B, FIG. 21C, and FIG. 21D

BOM OF FIG. 21

### FIG. 32A, FIG. 32B, and FIG. 32C

This is a view of the simplest BPT CIRCUIT form, with an output technique

FIG. 22—Represented by FIGS. 22A, 22B, 22C, 22D —is FIG. 5 with a different CONTROLLER 2 element where component 3c is a part of CONTROLLER 2 and component 8n isn't included. Components 3b, 2o and 2c are different than in FIG. 5 and component 7j is added as an extra component.

BLOWN UP VIEWS OF FIG. 21:

### FIG. 22A, FIG. 22B, FIG. 22C, and FIG. 22D

BOM of FIG. 22:

### FIG. 31A, and FIG. 31B

This is a voltage output view

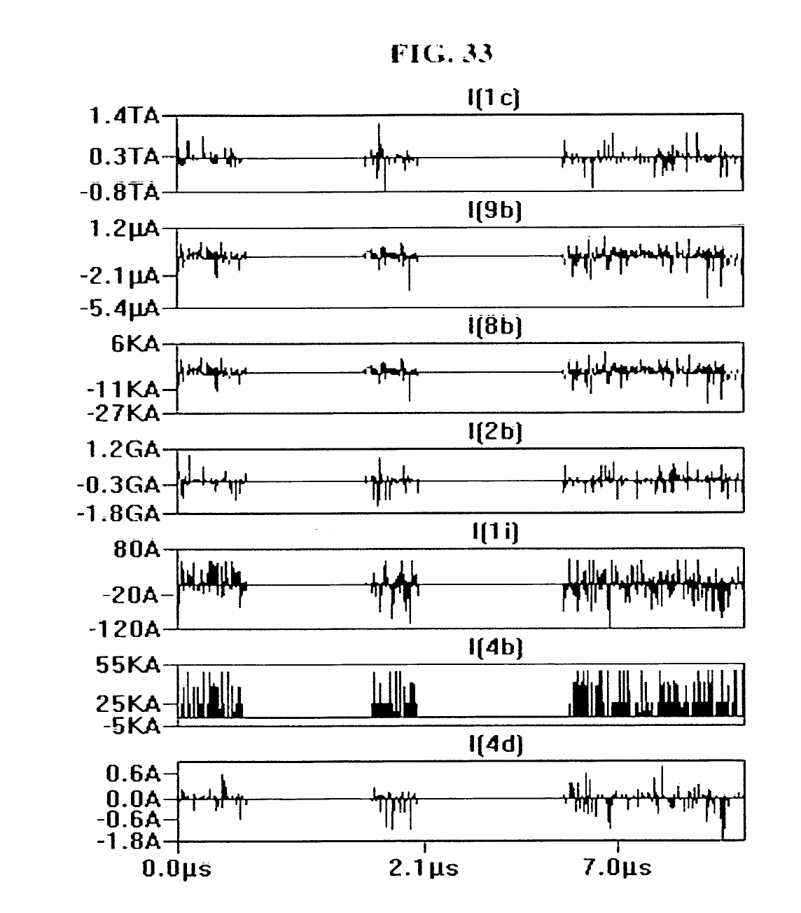

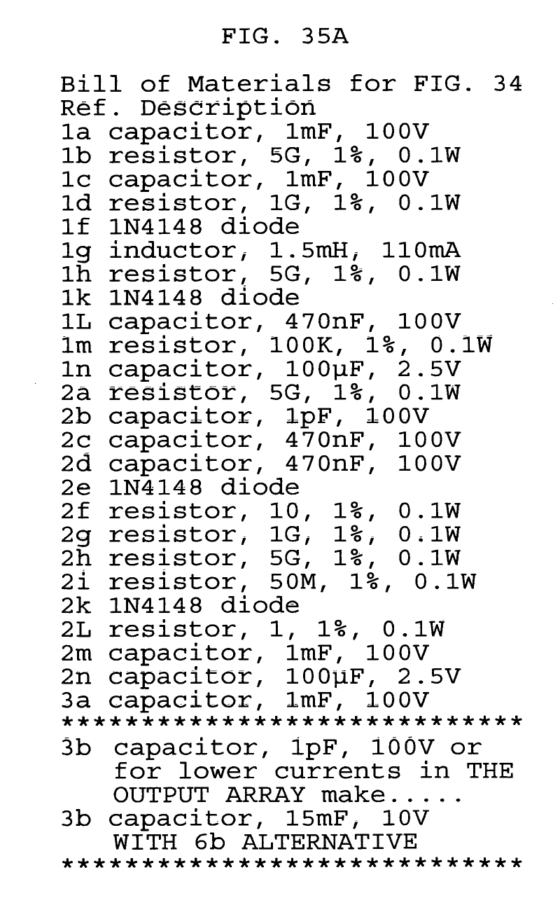

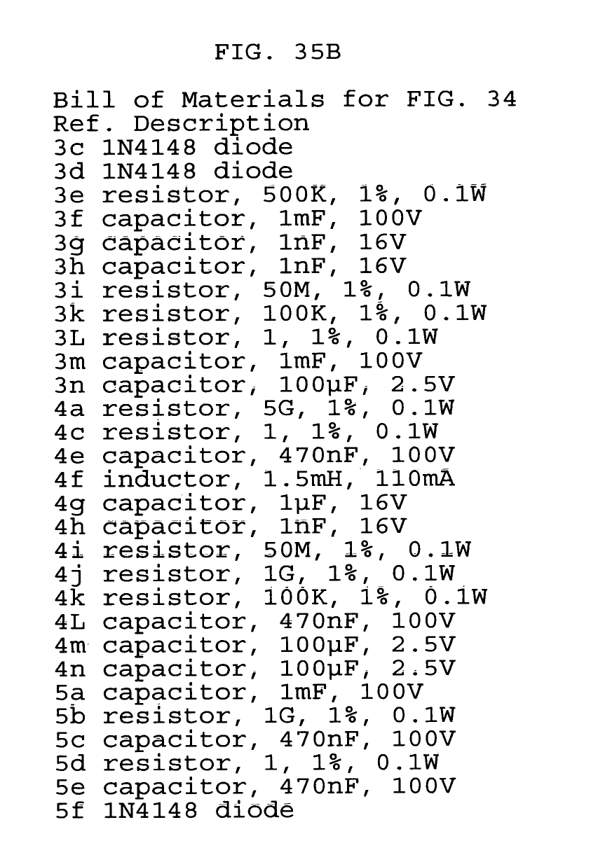

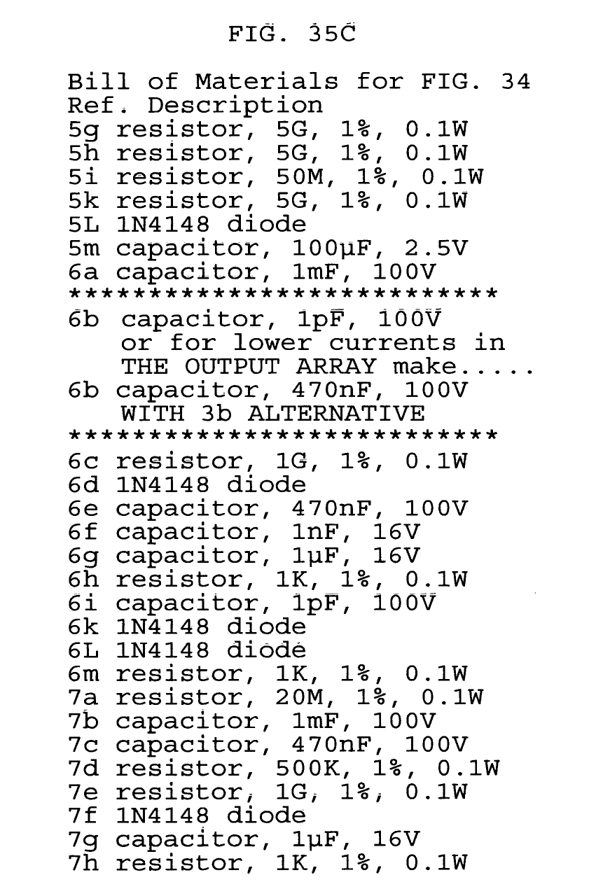

### FIG. 33

This is an output from some components of THE BPT SWITCHING OUTPUT ARRAY (SOA output) of FIG. 3

This is a view of a more complex BPT CIRCUIT form, with an output technique

### FIG. 34—Represented by FIGS. 16A, 16B, 16C, and 16D

### THIS COMPLETED CIRCUIT MAINTAINS THE DIRECTION OF THE PARTICLES AND ALSO USES AN OUTPUT ARRAY

BLOWN UP VIEWS OF FIG. 34:

### FIG. 16A, FIG. 16B, FIG. 16C, and FIG. 16D

BOM of FIG. 34:

### FIG. 35A, FIG. 35B, FIG. 35C, and FIG. 35D

This is a voltage output view

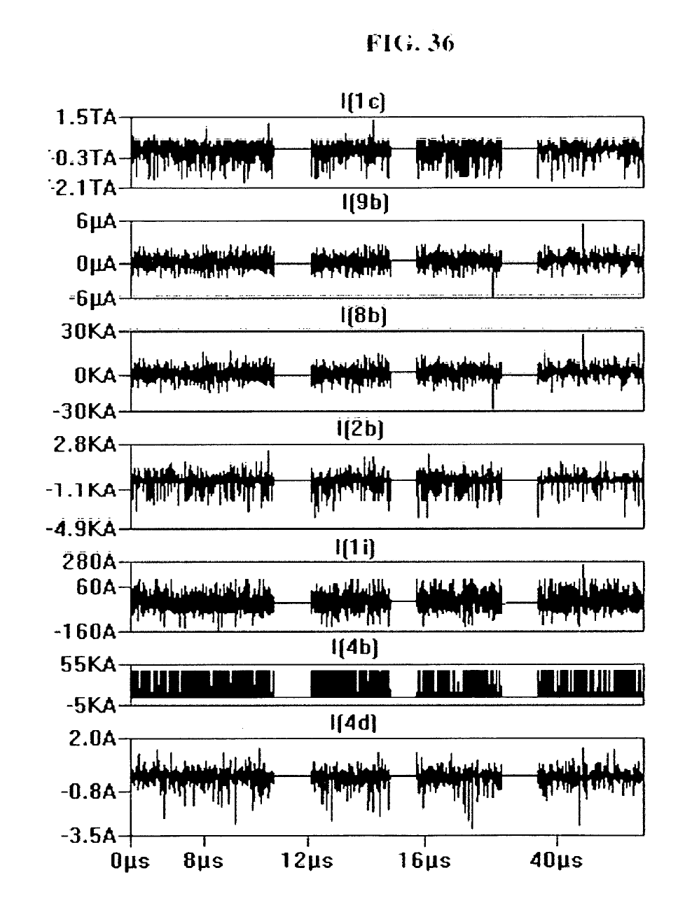

### FIG. 36

This is an output from some components of THE OPEN OUTPUT ARRAY (OOA output) output of FIG. 34

This is a voltage output view

### FIG. 37

This is the output of some components of FIG. 21

### THESE ARE THE DIODE CHARTS FOR ALL OF THE FIGURES

This is a view of the direction (anode or cathode) of the diodes in some BPT CIRCUITS

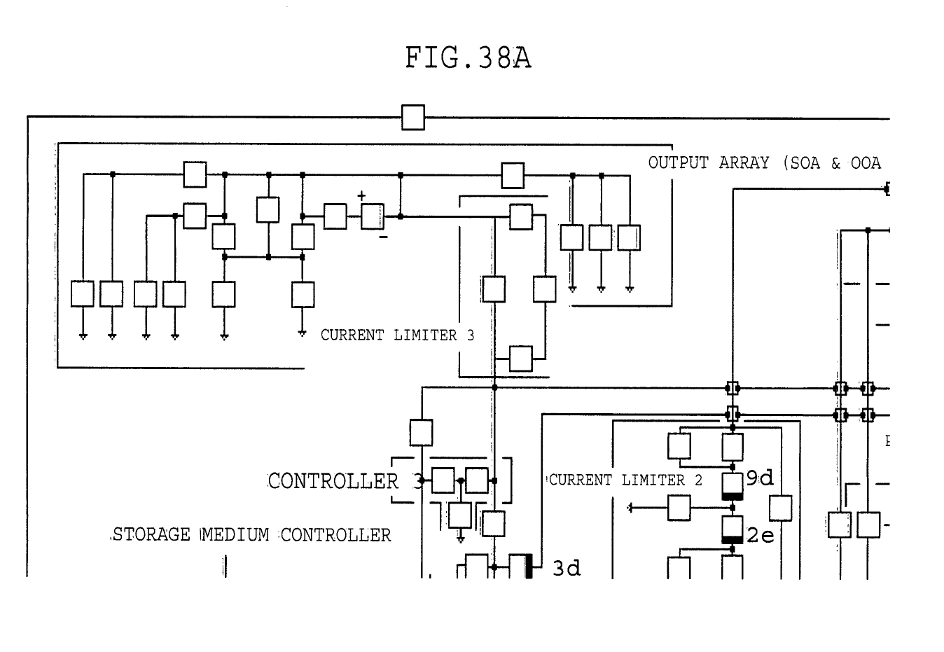

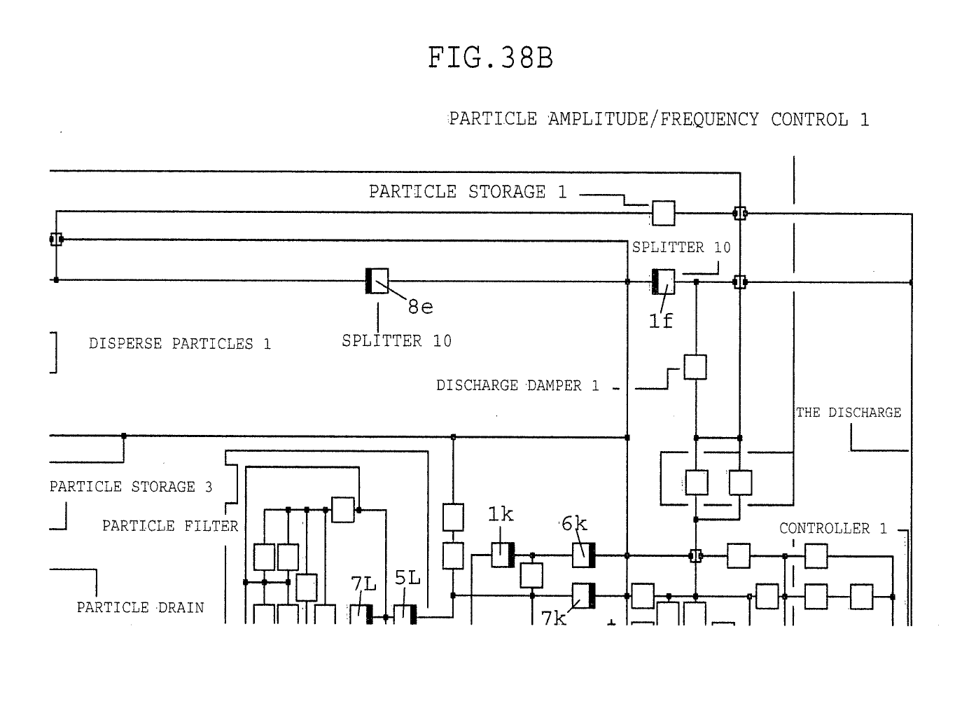

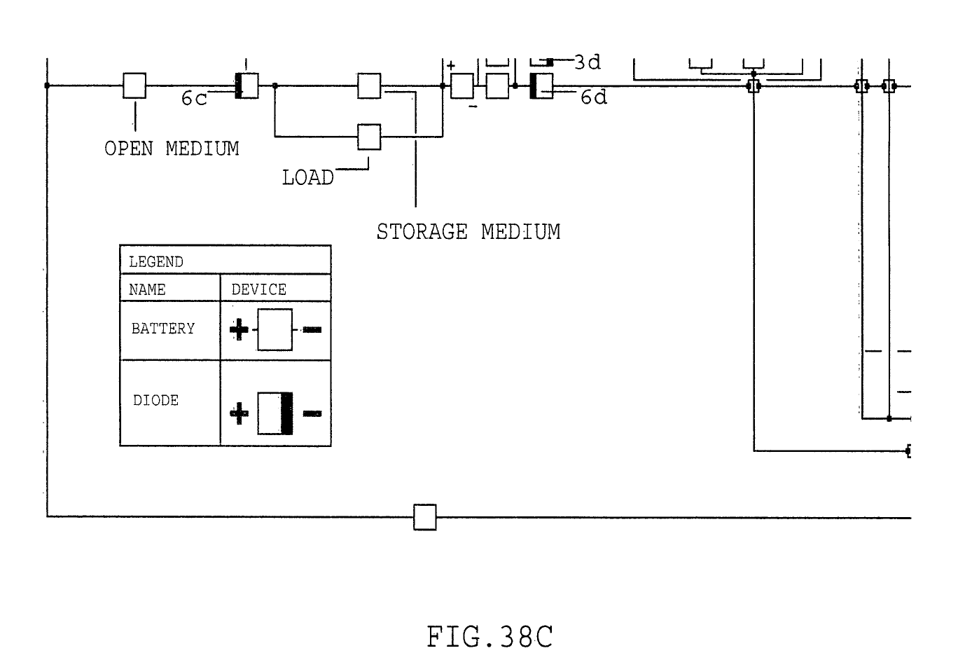

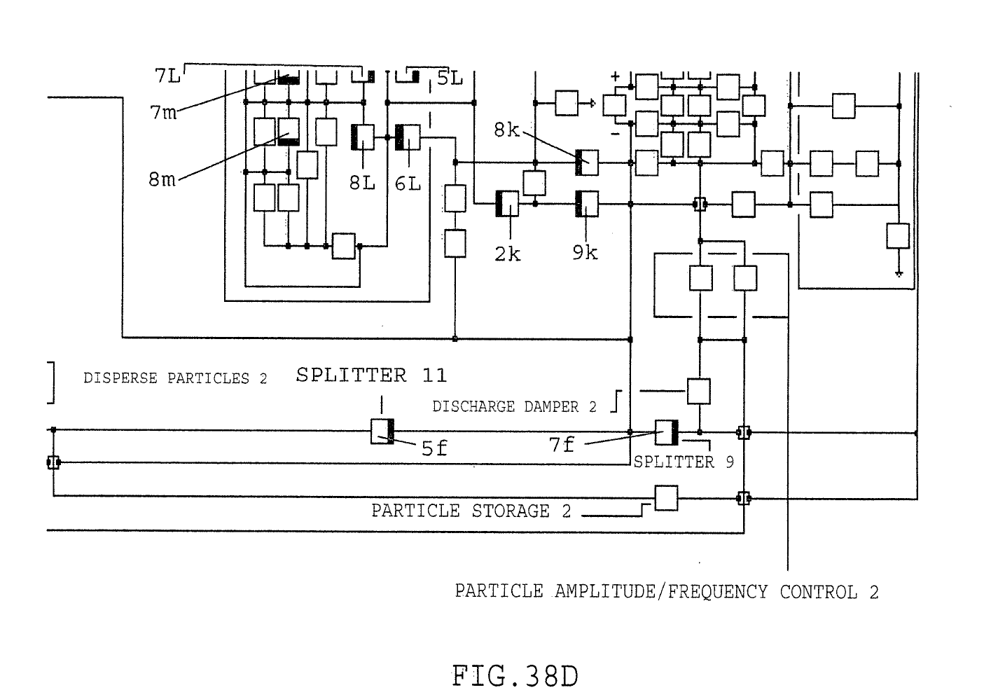

FIG. 38—Represented by the blown up views FIGS. 38A, 38B, 38C, and 38D—
This figure is a diode chart of some components in FIG. 3, FIG. 4, FIG. 6, FIG. 16 and FIG. 34.

This is a view of the simplest BPT CIRCUIT form, with an output technique

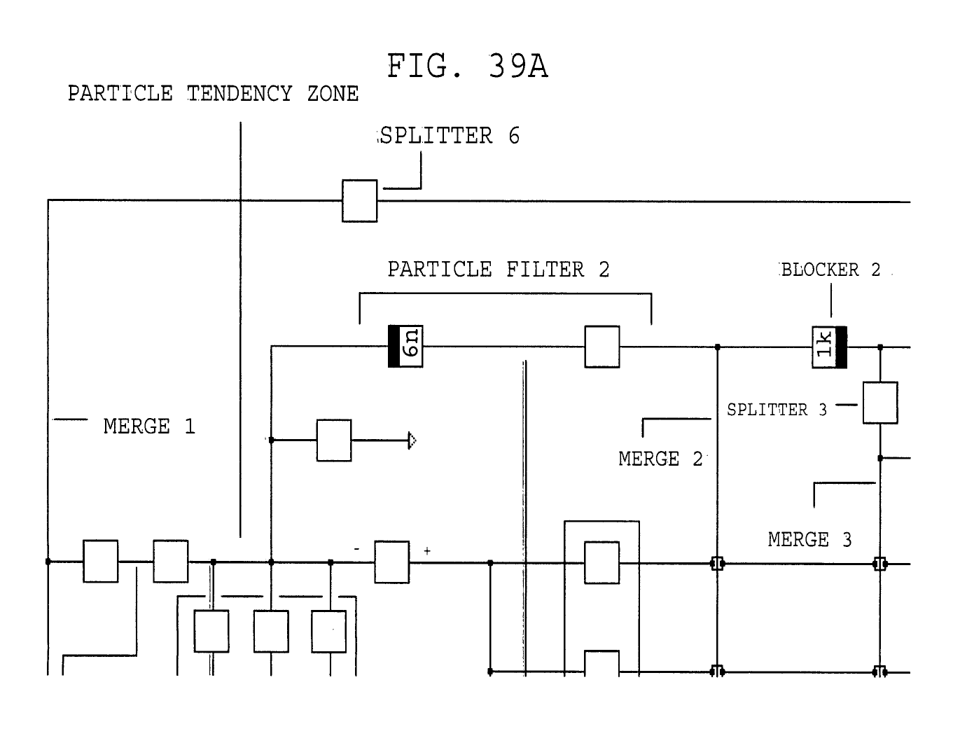

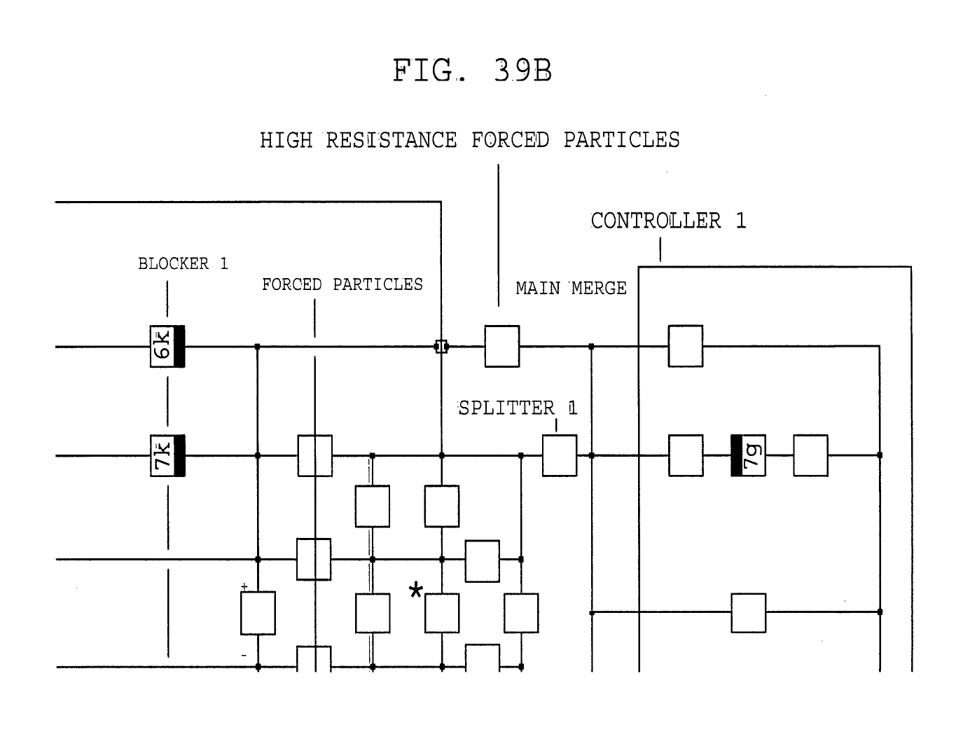

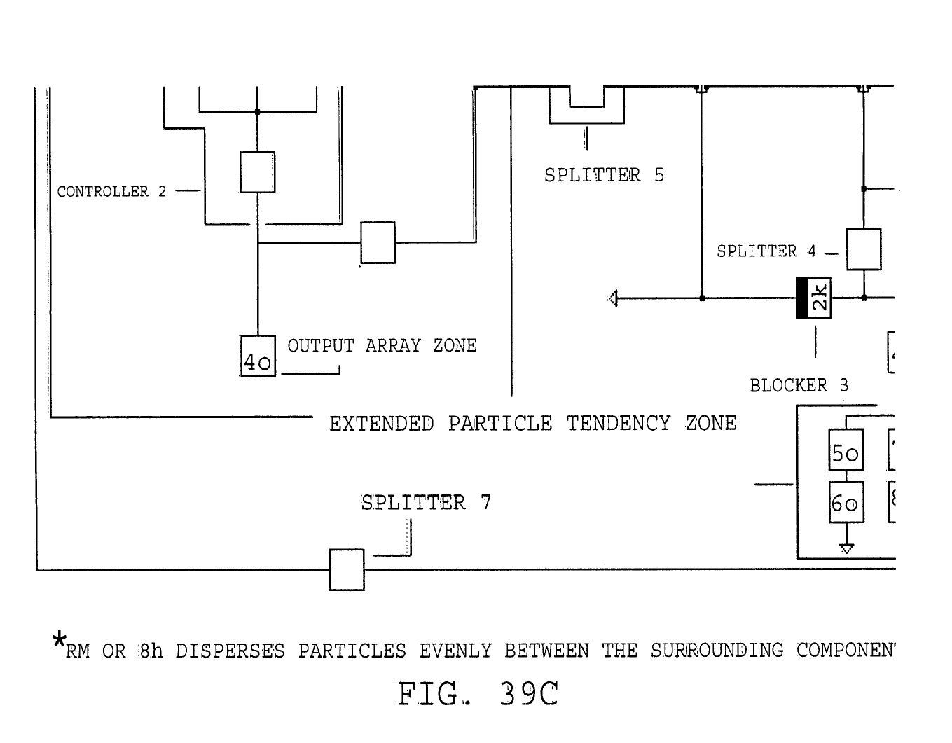

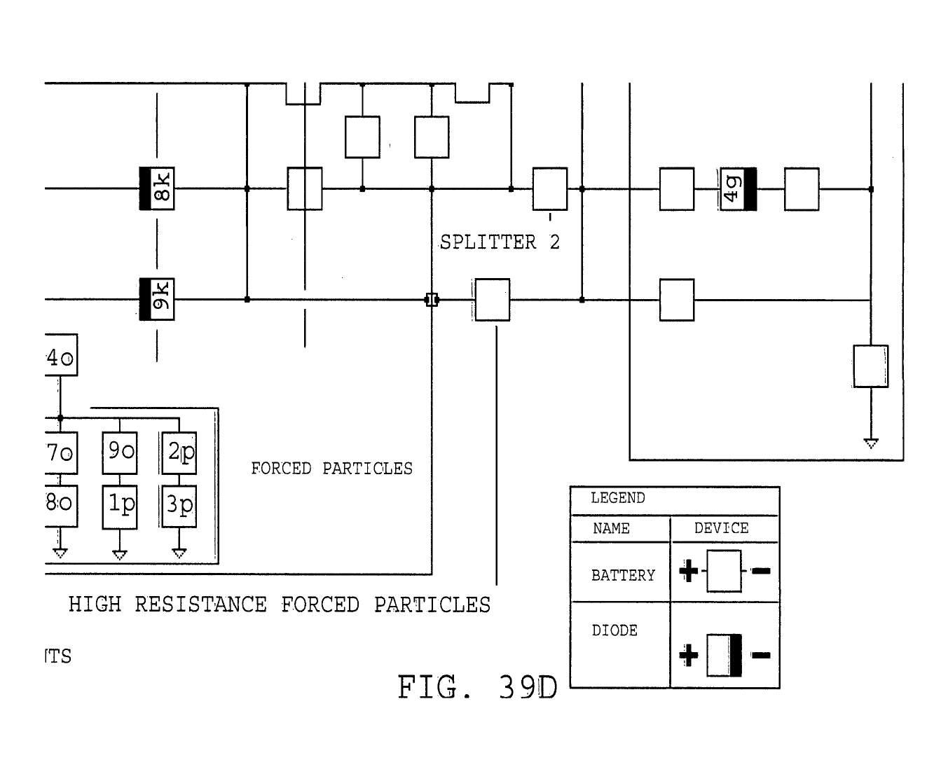

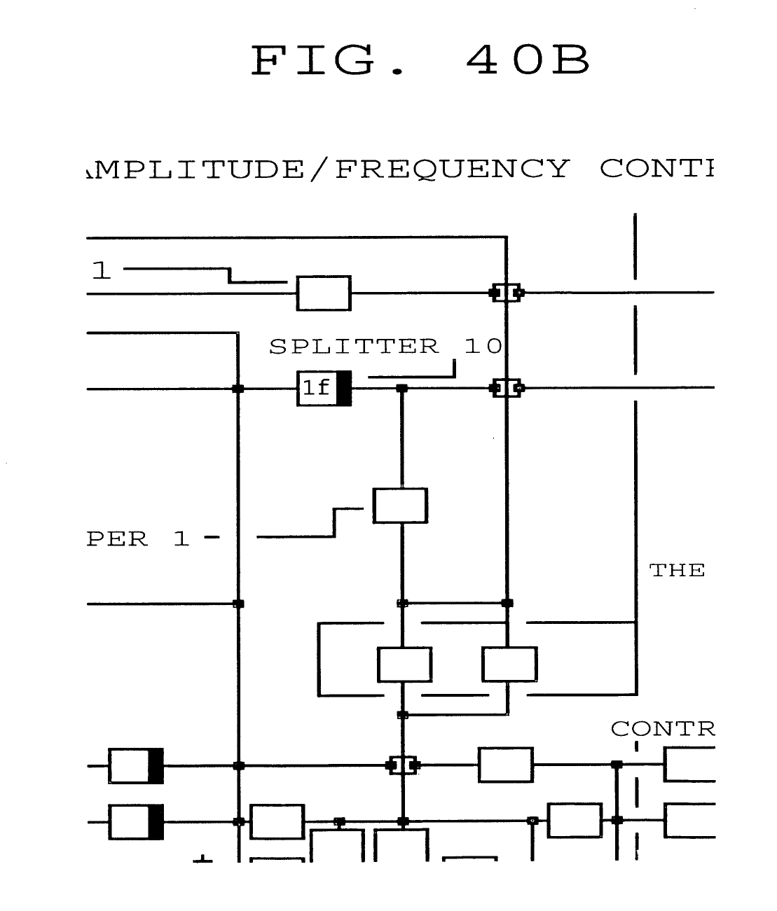

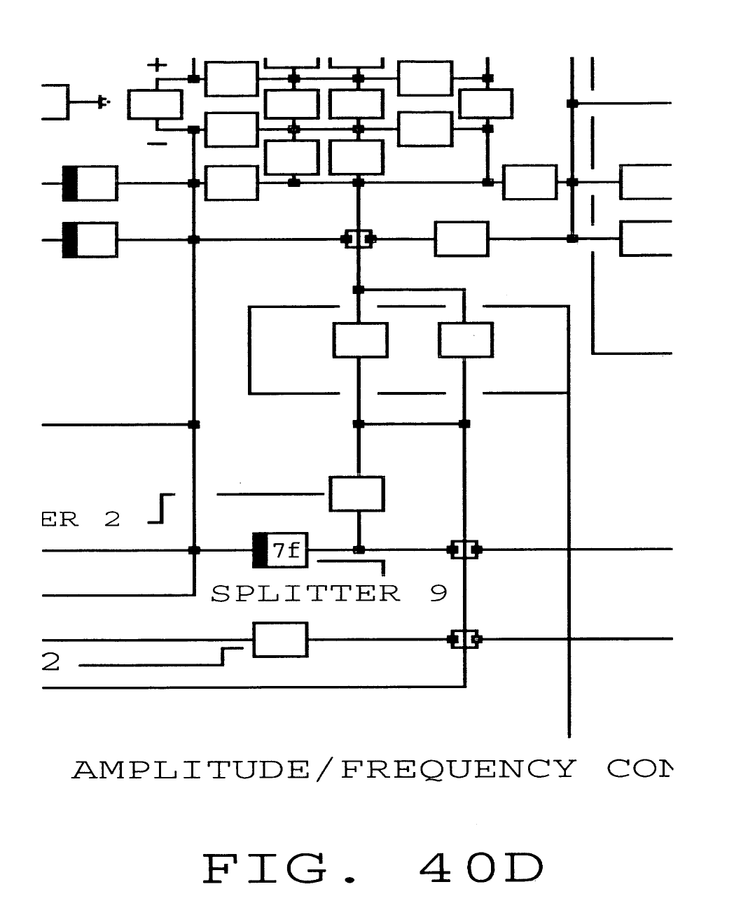

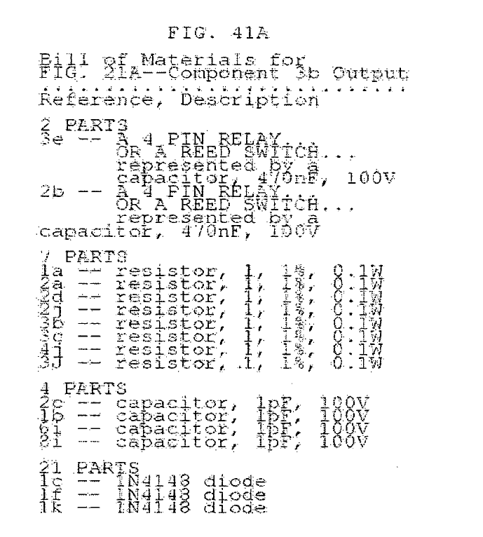

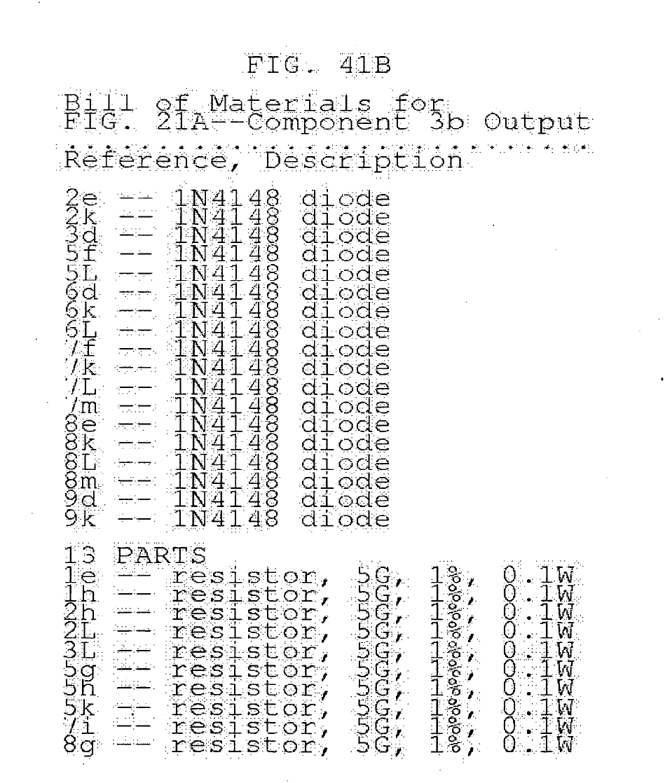

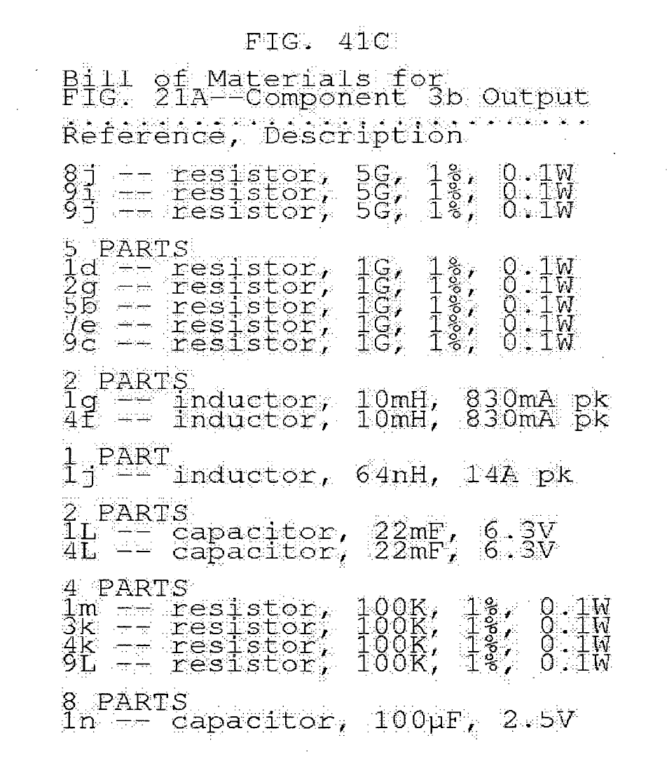

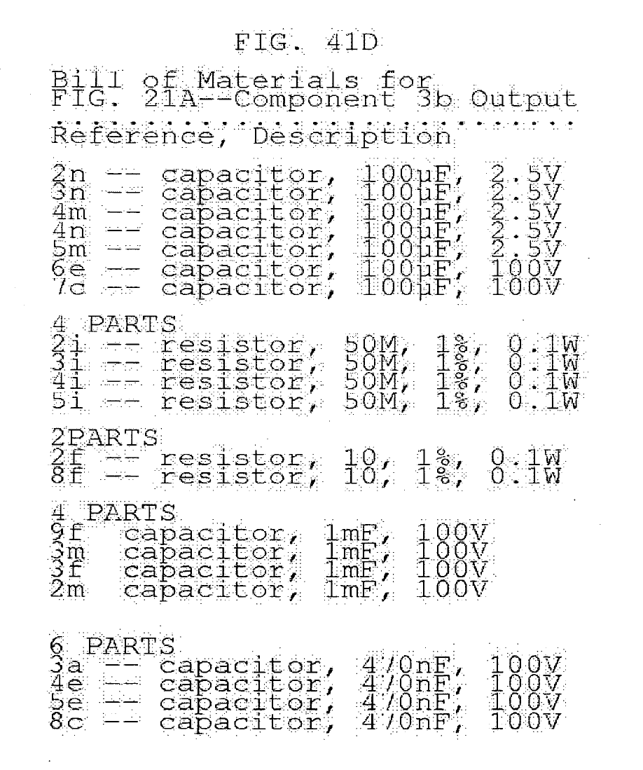

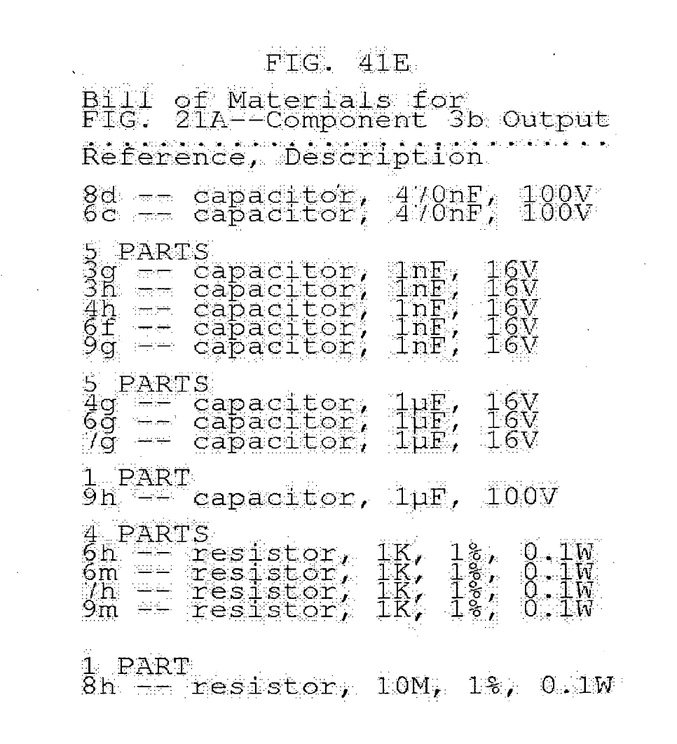

FIG. 39—Represented by the blown up views FIGS. 39A, 39B, 39C, and 39D—
This figure is a diode chart of some components in FIG. 1, FIG. 2, FIG. 5, FIG. 7, FIG. 14, FIG. 15 and FIG. 22.

This is a view of a more complex BPT CIRCUIT form, with an output technique

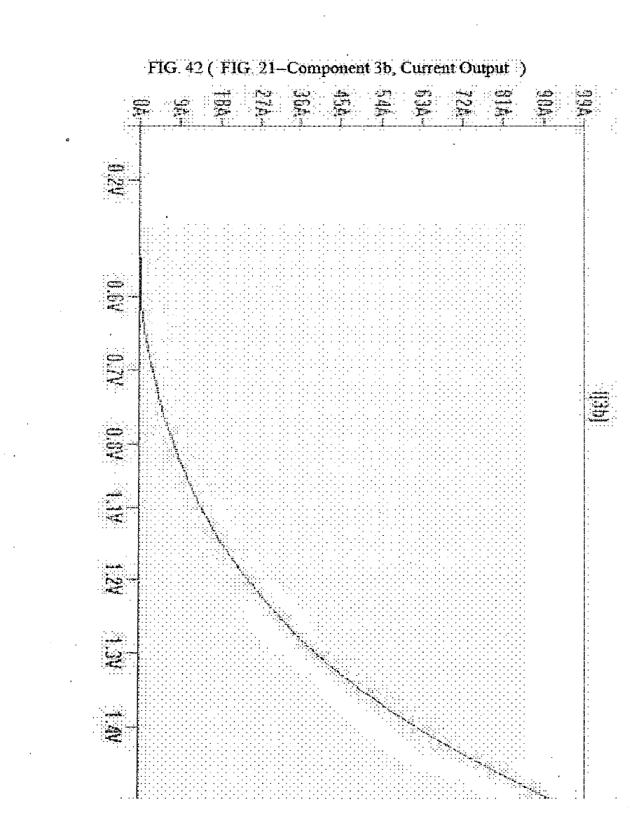

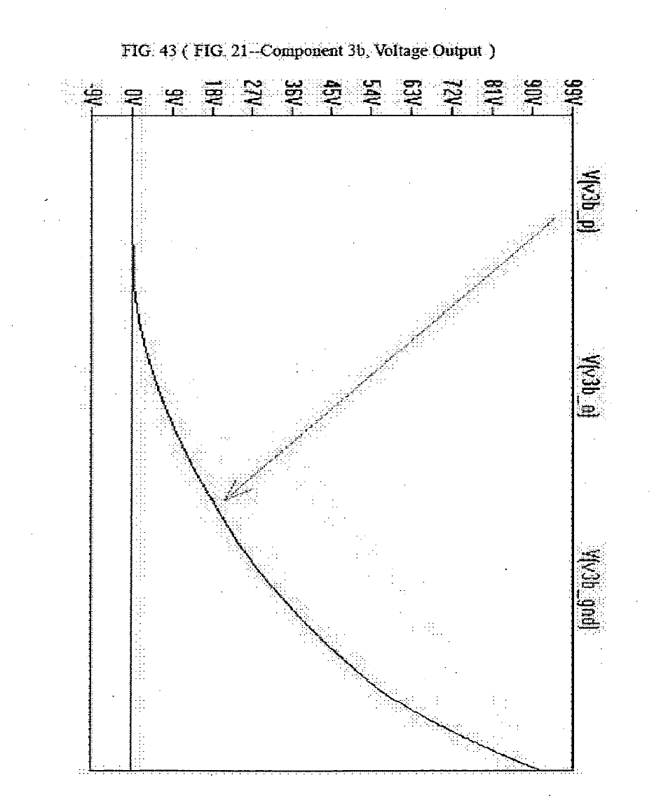

FIG. 40—Represented by the blown up views of FIG. 21B, and FIG. 21D, and partly FIG. 38 diode positions—This figure is a diode chart of FIG. 21.

### DETAILED DESCRIPTION OF THE INVENTION

Turning now descriptively to the drawings, in which similar reference characters denote similar elements throughout the several views, the attached figures illustrate a device, my invention, THE BRAITHWAITE PARTICLE TRAP, a small device that is for or used to generate limitless electrical power, which comprises Batteries, Capacitors, Resistors and Diodes (Optional i.e. the device can be made of simply Batteries, Capacitors, Resistors as Diodes (see FIG. 8 and FIG. 13)—Working resistors I have tested are about 0.1 Million Ohms for FIG. 1 and FIG. 15, and 0.02 Million Ohms for FIG. 8 and FIG. 13—, Wires and a Bread Board or PCB), Wires and a Prototype Board or a PCB (PRINTED CIRCUIT BOARD).

Batteries are a 2 pin device. Capacitors are a 2 pin device. Resistors are a 2 pin device. Diodes are a 2 pin device. Prototype Boards are drilled Copper Clad Breadboards for use with many pin type components at the same time. PCBs are printed circuit boards—used in place of a Drilled Copper Clad Breadboard and wires—.

The wire to use is a string of conducting material, copper or other metals which usually come in circumference units of gage. BATTERY POWER, ALLOWS TIMED-PARTICLES (moving atomic particles that have a frequency) TO EXIST AT ZONES OF THE BPT CIRCUIT see FIG. 16 (THE PARTICLE TENDENCY ZONE and EXTENDED PARTICLE TENDENCY ZONE).

Where the particles end up in THE BPT CIRCUIT is an interesting matter. The particles can exist at any zone of the circuit. They mostly run to the parts of the circuit with the most resistance or highest resistor. The following are examples of enhanced concepts of where the particles run to, called (THE PARTICLE TENDENCY ZONE and EXTENDED PARTICLE TENDENCY ZONE), and this (see FIG. 16) part of THE BPT CIRCUIT MAINTAINS THE DIRECTION OF PARTICLES, and EXIST IN THESE BPT CIRCUIT(s) FIG. 1, FIG. 3, FIG. 4, FIG. 5, FIG. 6, FIG. 7, FIG. 8, FIG. 13, FIG. 14, FIG. 15, FIG. 21, FIG. 22, and FIG. 34.

THE PARTICLE TENDENCY ZONE and EXTENDED PARTICLE TENDENCY ZONE: POTENTIAL ENERGY OR STORAGE OF ARTICLES OCCURS at these zones. Tapping into these zones of THE BPT CIRCUIT and using a CURRENT ARRAY allows current increase in some components in the CURRENT ARRAY (see FIG. 16). ONLY A FEW NODES IN THE BPT CIRCUIT HAS THE POTENTIAL FOR CURRENT INCREASE IN THE OUTPUT ARRAY. FIG. 3, FIG. 4, FIG. 5, FIG. 6, FIG. 7, FIG. 8, FIG. 14, FIG. 15, FIG. 22 and FIG. 34 have THE PARTICLE TENDENCY ZONE and EXTENDED PARTICLE TENDENCY ZONE where POTENTIAL ENERGY exists that causes current increase in an OUTPUT ARRAY.

Current can be a burden at times; in the case of THE BPT CIRCUIT, current can be dangerous; therefore, I decided to work with current limiter zones in THE BPT CIRCUIT (see FIG. 16). The CURRENT LIMITER (CURRENT LIMITER 2) is made up of LOWERED RESISTANCE OR POTENTIOMETERS (POTS), ALLOWING HIGHER CURRENT FLOW IN THE OUTPUT ARRAY.

For CURRENT LIMITER 2, either component 7d or component 3e CAN BE OPEN CIRCUITED. FIG. 3, FIG. 4, FIG. 6 (components 8d and 4e are shorted and THERE IS NO RESISTOR OR INDUCTOR AT THE GROUND between components 9d and 2e; making, THE OUTPUT ARRAY CURRENT AT ITS MAXIMUM AMP.), FIG. 8 and FIG. 34. Also, for the figures mentioned; not both components 7d and 3e CAN BE OPEN- CIRCUITED, that causes current in THE BPT CIRCUIT(s)TO DROP down to zero.

Open components like capacitors can be used to have a desired output such as that of FIG. 1 (see FIG. 17 and FIG. 18); FIG. 15 (see FIG. 19 and FIG. 20) and FIG. 21 (see FIG. 16, CURRENT LIMITER 2 and FIG. 37 The output of some components of FIG. 21).

FIG. 21 is a circuit that oscillates for 10 seconds giving high voltage and current output for a limited time of only 10 seconds.

Another current limiter (CURRENT LIMITER 3) is a RESISTOR CAPACITOR (RC) CURRENT LIMITER. MADE UP OF 2 SMALL (1P FARAD) PARALLEL CAPACITORS SEPARATED BY 2 SMALL (1 OHM) PARALLEL RESISTORS. In this CURRENT LIMITER, HIGHER RESISTORS=LESS CURRENT and LOWER RESISTORS=MORE CURRENT see FIG. 4.

Also, for the OUTPUT ARRAY(s) for example component 8b, this component allows a SAFE MODE for any higher resistors as component 9b see FIG. 3, FIG. 4, FIG. 5, FIG. 6, FIG. 7, FIG. 8, FIG. 13, FIG. 22 and FIG. 34.

The OUTPUT ARRAY functions because of POTENTIAL ENERGY (PARTICLE TENDENCY ZONE and EXTENDED PARTICLE TENDENCY ZONE) from storage of particles; there are two types of OUTPUT ARRAY(s) among the above mentioned OUTPUT ARRAY(s). One is an OPEN OUTPUT ARRAY (component 2b—is a capacitor—of FIG. 6, FIG. 7 and FIG. 34), and the other is a SWITCHING OUTPUT ARRAY (component 2b—is a voltage controlled switch—of FIG. 3, FIG. 4, FIG. 5, FIG. 8, FIG. 22, also FIG. 13 and FIG. 14, which have OUTPUT ARRAY ZONE(s) between components 2o and 2b.

The odd figure FIG. 3 (A repeated demonstration) is simply a demonstration of a particle filter used in the initial process of the more complex figures of THE BPT CIRCUIT. The remaining figures FIG. 1 and FIG. 15 are figures of a slightly more complex version of THE BPT CIRCUIT in comparison to FIG. 2. FIG. 1 and FIG. 15 are simply the first steps in realizing THE PARTICLE TENDENCY ZONE and EXTENDED PARTICLE TENDENCY ZONE.

Batteries are a 2 pin device, they a limited particle linear device that utilizes atomic particles for power to perform work in mechanical devices or conductive materials. Batteries are a small or large structural device that is used to store conduct or accelerate atomic particles. Batteries exist in a vast amount. Capacitors are a 2 pin device. An open separated pole device or a battery like device that uses atomic particles outside of itself that utilizes atomic particles for power to perform work in mechanical devices or conductive materials. Capacitors exist in a vast amount.

CAPACITORS are a two pole fast-discharge-or-slow-discharge-of atomic particle-function-device that is manipulated by frequency and power of atomic particle input. Capacitors can be used to stabilize or distort atomic particles.

RESISTORS are a 2 pin device. It is a device used to oppose current flow. Resistors exist in a vast amount.

DIODES are a 2 pin device. Diodes exist in a vast amount. They are semiconductor devices made of Silicon or Germanium and are made to work by giving the Silicon or Germanium 2 poles one pole fused with an element that is an accepter of electrons and the other pole fused with an element that is a donor of electrons. The fusing of these elements with an insulator is called doping.

PROTOTYPE BOARDS are drilled Copper Clad Breadboards for use with many pin type components at the same time. Prototype Boards exist in a vast amount.

PCBs are printed circuit boards—used in place of a Drilled Copper Clad Breadboard and wires—that can be created by a computer application such as PCB123 and manufactured from the CAD layout of the PCB. PCBs can be made very small. It's possible to fit about 200 surface mount electronic components on one side of a 2 inch by 4 inch PCB, due to small components such as surface mount electronic components and routing techniques of PCBs, a small size high power device can be made as THE BPT CIRCUIT.

The WIRE to use is a string of conducting material, copper or other metals which usually come in circumference units of gage. Wire exists in a vast amount.

### Addressing Combined Zones in The BPT Circuit Figures

See FIG. 1, FIG. 2, FIG. 13, FIG. 16 and FIG. 21 for details

The Open Medium

This is a part (component 2c) of the BPT CIRCUIT(s) that gains a pooling or accumulation of particles. This is a simple version of what an OPEN or SWITCHING OUTPUT ARRAY does. THE OUTPUT ARRAY(s) represent a much greater resistance or spatial value to store particles. THE OPEN MEDIUM represents the maximum resistance or spatial value to store particles that a BPT CIRCUIT has without an OUTPUT ARRAY. THE OPEN MEDIUM can be represented by a floating (connected at one pin only to a circuit node) high value resistance such as 20 Million OHMS shown mainly in FIG. 1, FIG. 5, FIG. 7 and FIG. 15 as component 2c.

The Storage Medium Controller

Component 3c, which is used to act as an extending resistor or spatial value so that THE STORAGE MEDIUM—component 4c—, can recognize a greater OPEN MEDIUM.

The Load

Component 5c, which is used to test Component 4c, component 5c is usually a parallel capacitor to component 4c which draws power from component 4c that it is in parallel with. The drain from component 5c can prove if the value of power of component 4c is static or stable power. If the capacitor component 5c is used in parallel of component 4c and there is zero value voltage between the components, the power of component 4c is static, and if the value of the voltage of component 4c is close to that of the input voltage source 4d then the power value of component 4c is a stable voltage.

The Storage Medium

Component 4c, this is a resistor that is used to store particles. The value of the component is important while storing particles, but not necessary. The OUTPUT ARRAY(s) are what truly determine where particles end up being stored. With An OUTPUT ARRAY used with THE BPT CIRCUIT, component 4c can be a smaller value than 20 Million Ohms, but what component 4c truly represents as a THE STORAGE MEDIUM is somewhat like being a testing source for particles. At 20 Million Ohms component 4c stores a voltage that is equal to voltage source 4d defining the existence of particles between 4c, which only shows component 4c as a testing component for particles.

The Output Array(s)

THE OUTPUT ARRAY FUNCTIONS BECAUSE it is the ultimate OPEN MEDIUM that stores POTENTIAL ENERGY beyond THE PARTICLE TENDENCY ZONE AND EXTENDED PARTICLE TENDENCY ZONE There are two types of OUTPUT ARRAY(s) among the above mentioned OUTPUT ARRAY(s). One is an OPEN OUTPUT ARRAY—OOA—where component 2b is a capacitor—of FIG. 6, FIG. 7 and FIG. 34). The other is a SWITCHING OUTPUT ARRAY (SOA), where component 2b is a voltage controlled switch of FIG. 3, FIG. 4, FIG. 5, FIG. 8 and FIG. 22 also FIG. 13, and FIG. 14, which have OUTPUT ARRAY ZONE(s) (BETWEEN COMPONENTS 2o and 2b) Component 4b (V3) is used to help control the switch/capacitor (2b) at the high voltage (or particle) point where THE BPT OUTPUT ARRAY is located.

Disperse Particles 1

A high resistor (component 7e) is used to slow down particles as they discharge from a capacitor (component 6e). The impedance at this point naturally exists because of the particles that are propelled at this point, but the impedance is only comparable to what was used as a resistor. At the DISPERSE PARTICLES 3 (see FIG. 2) zone wire is used, at this point an actual resistor is used.

Disperse Particles 2

A high resistor (component 7e) is used to slow down particles as they discharge from a capacitor (component 6e). The impedance at this point naturally exists because of the particles that are propelled at this point, but the impedance is only comparable to what was used as a resistor. At the DISPERSE PARTICLES 3 (see FIG. 2) zone wire is used, at this point an actual resistor is used.

Disperse Particles 3

Basically, a wire is used in connection with components to allow dispersal of particles, because of the particles through the wire; the wire ends up with high impedance causing transference of high impedance to the surrounding components.

Particle Drain

Particles run to this point as they disperse from component 6e while being attracted by particles on the opposite side of components 9e (PARTICLE STORAGE 1) and 6f (PARTICLE STORAGE 2).

Discharge Damper 1

Particles are slowed down for the PARTICLE DRAIN.

Discharge Damper 2

Particles are slowed down for the PARTICLE DRAIN.

Particle Storage 1

Particles are stored for the PARTICLE DRAIN

Particle Storage 2

Particles are stored for the PARTICLE DRAIN

Particle Storage 3

This is a fast discharging capacitor, component 6e.

Controller 1

If the components at this point are not a particular value, there is no transmission of particles in THE BPT CIRCUIT, of FIG. 1 and FIG. 15.

Controller 2

If the components at this point are not a particular value, there is no transmission of particles in THE BPT CIRCUIT, of FIG. 1 and FIG. 15.

Controller 3

If the components at this point are not a particular value, there is no transmission of particles in THE BPT CIRCUIT, of FIG. 21

Merge 1

This is like THE DISCHARGE; that comes after a SPLITTER; see, SPLITTER 1 TO SPLITTER 11.

Merge 2

This is like THE DISCHARGE; that comes after a SPLITTER; see, SPLITTER 1 TO SPLITTER 11.

Merge 3

This is like THE DISCHARGE; that comes after a SPLITTER; see, SPLITTER 1 TO SPLITTER 11.

Main Merge

This is the main discharge point in THE BPT CIRCUIT. Without this point being shorted, THE BPT CIRCUIT(s) FIG. 1 and FIG. 15 cease to function.

Splitter 1

Component 1h is used to break voltage down into streaming particles for the MAIN MERGE point in THE BPT CIRCUIT (see FIG. 1 and FIG. 15)

Splitter 2

Component 2h is used to break voltage down into streaming particles for the MAIN MERGE point in THE BPT CIRCUIT (see FIG. 1 and FIG. 15)

Splitter 3 And Splitter 4

FOR FIG. 1 and FIG. 15, the component (3k) with component 4k must be shorted using their value in the figures BOM (FIG. 23 and FIG. 30), if the resistance was higher, the PARTICLE TENDENCY ZONE and THE EXTENDED PARTICLE ZONE would shift and cause particles to allow an output of voltage between component (3k) as well as component 4k shifting the output from component 4c (THE STORAGE MEDIUM). Component 3k as well as 4k will then become the new STORAGE MEDIUM. The BPT CIRCUIT will then stop functioning. When components 3k and 4k change, THE STORAGE MEDIUM can shift to any where in THE BPT CIRCUIT.

Splitter 5

Component 3d and component 6d are used to allow the voltage source (component 4d) to use component 1i's particle output

Splitter 6

This is used to merge particles at component 2c (THE OPEN MEDIUM)

Splitter 7

This is used to merge particles at component 2c (THE OPEN MEDIUM)

Splitter 8 and Splitter 9

These are used to delay THE DISCHARGE

Splitter 10 and Splitter 11

These are used to project particles to component 9e, component 6e, component 7e and component 6f

Blocker 1

These components (6k, 7k, 8k and 9k) force particles opposite of voltage source (component 1i) while having a stream of particles passing through

Blocker 2

This component forces particles opposite of voltage source (component 1i) while having a stream of particles passing through itself.

Blocker 3

This component forces particles opposite of voltage source (component 1i) while having a stream of particles passing through itself.

Blocker 4 and Blocker 5

The DISPERSE PARTICLES 3 impedance functions for components (5L, 6L, 7L and 8L) by allowing them to mimic the impedance (see FIG. 2)

Blocker 6, Blocker 7 and Blocker 8

These components are ground components; they are used to give the circuit a physical reality in comparison with voltage input. In THE BPT CIRCUIT, these components work as repellents forcing particles opposite it and ground (see FIG. 2).

Output 1 and Output 2

These components are used as test components (see FIG. 2)

The Discharge

This is an endpoint that is opposite an input charge and component at one pole of the battery (1i), an output then exists between components at both poles of the battery (1i) and this endpoint.

Forced Particles

This forces particles opposite of the voltage (component 1i) while having a stream of particles passing through itself.

Component 8h

This component disperses particles evenly between the surrounding components

Particle Amplitude/Frequency Control 1

Component 3f and component 4f are used to control the amplitude and frequency of particles

Particle Amplitude/Frequency Control 2

Component 9f and component 1g are used to control the amplitude and frequency of particles

The Particle Filter (FIG. 2);

OUTPUT AT SOME FREQUENCIES (TIMED-PARTICLES) FROM THE BPT MAIN CIRCUIT, allows the PARTICLE FILTER CIRCUIT of this version of THE BPT CIRCUIT to give the entire BPT CIRCUIT less harmonics. THE PARTICLE FILTER basically is a part of THE BPT CIRCUIT of FIG. 2. The filter is a FILTER for PARTICLES THAT HAVE A FREQUENCY (TIMED-PARTICLES). THE PARTICLE FILTER is useful only at the initial stage of making THE BPT CIRCUIT. As the circuit becomes more complex and power increases, the need for a PARTICLE FILTER CIRCUIT decreases.

Current Limiter 1;

Component 2o which is used in FIG. 1, FIG. 5, FIG. 7, FIG. 13, FIG. 14, FIG. 15, FIG. 21, FIG. 22, and FIG. 34 is used to prevent power loss in component 4d (voltage source 1). Component 2o used to be a resistor.

Current Limiter 2;

LOWERED RESISTANCE OR POTENTIOMETERS (POTS), ALLOW HIGHER CURRENT FLOW IN THE OUTPUT ARRAY. Either component 7d or component 3e CAN BE OPEN CIRCUITED. FIG. 3, FIG. 4, FIG. 6 (components 8d and 4e are shorted and THERE IS NO RESISTOR OR INDUCTOR AT THE GROUND between components 9d and 2e; making, THE OUTPUT ARRAY CURRENT AT ITS MAXIMUM AMP.), and FIG. 8. Also, for the figures mentioned, not both components 7d and 3e CAN BE OPEN-CIRCUITED that causes current in THE BPT CIRCUIT(s) TO DROP down to zero. Open components like capacitors can be used to have a desired output such as that of FIG. 1 (see FIG. 17 and FIG. 18); FIG. 15 (see FIG. 19 and FIG. 20) and FIG. 21 (see FIG. 16, CURRENT LIMITER 2 and FIG. 37 The output of some components of FIG. 21). FIG. 21 is a circuit that oscillates for 10 seconds giving high voltage and current output for a limited time of only 10 seconds.

Current Limiter 3;

Another current limiter (CURRENT LIMITER 3) is a RESISTOR CAPACITOR (RC) CURRENT LIMITER. MADE UP OF 2 SMALL (1P FARAD) PARALLEL CAPACITORS SEPARATED BY 2 SMALL (1 OHM) PARALLEL RESISTORS. HIGHER RESISTORS=LESS CURRENT and LOWER RESISTORS=MORE CURRENT see FIG. 4.

The Main BPT Circuit

Component 4d (V1) is used to excite electrons in the circuit (THE MAIN BPT CIRCUIT) see FIG. 1. Component 1i (V2) expels particles to THE PARTICLE TENDENCY ZONE, AND EXTENDED PARTICLE TENDENCY ZONE. THE PARTICLE TENDENCY ZONE and EXTENDED PARTICLE TENDENCY ZONE Where the particles end up in THE BPT CIRCUIT is an interesting matter. The particles can exist at any zone of the circuit. They mostly run to the parts of the circuit with the most resistance or highest resistor. The following are examples of enhanced concepts of where the particles run to, called (THE PARTICLE TENDENCY ZONE and EXTENDED PARTICLE TENDENCY ZONE), and this (see FIG. 16) part of THE BPT CIRCUIT MAINTAINS THE DIRECTION OF PARTICLES, and EXIST IN THESE BPT CIRCUIT(s) FIG. 1, FIG. 3, FIG. 4, FIG. 5, FIG. 6, FIG. 7, FIG. 8, FIG. 13, FIG. 14, FIG. 15, FIG. 21, FIG. 22, and FIG. 34.

The Particle Tendency zone and Extended Particle

TENDENCY ZONE: POTENTIAL ENERGY OR STORAGE OF PARTICLES OCCURS at these zones. Tapping into these zones of THE BPT CIRCUIT and using a CURRENT ARRAY allows current increase in some components in the CURRENT ARRAY (see FIG. 16). ONLY A FEW NODES IN THE BPT CIRCUIT HAS THE POTENTIAL FOR CURRENT INCREASE IN THE OUTPUT ARRAY. FIG. 3, FIG. 4, FIG. 5, FIG. 6, FIG. 7, FIG. 8, FIG. 14, FIG. 15, FIG. 22 and FIG. 34 have THE PARTICLE TENDENCY ZONE and EXTENDED PARTICLE TENDENCY ZONE where POTENTIAL ENERGY exists that causes current increase in an OUTPUT ARRAY.

1. FIG. 1 is used in conjunction with FIG. 2 and FIG. 15 to make FIG. 3, FIG. 4, FIG. 5, FIG. 6, FIG. 7, FIG. 8, FIG. 13, FIG. 14, FIG. 21, FIG. 22 and FIG. 34. What's great about the conversion to FIG. 3, FIG. 4, FIG. 5, FIG. 6, FIG. 7, FIG. 8, FIG. 13, FIG. 14, FIG. 21, FIG. 22 and FIG. 34 from FIG. 1, FIG. 2 and FIG. 15 is that the device can still be controlled and THE BPT CIRCUIT can now produce current or high power from a device that is still simple. High current which gains power from THE PARTICLE TENDENCY ZONE and THE EXTENDED PARTICLE TENDENCY ZONE that FIG. 1, FIG. 2 and FIG. 15 has. These zones allow the accumulation of particles at an open area in the circuit that stores particles.
THE PARTICLE TENDENCY ZONE and THE EXTENDED PARTICLE TENDENCY ZONE allows current to exist at OUTPUT ARRAY(s) in THE BPT CIRCUIT. There are 2 forms of OUTPUT ARRAY(S) used in THE BPT CIRCUIT(s). One is an OPEN OUTPUT ARRAY (component 2b—is a capacitor—of FIG. 6, FIG. 7 and FIG. 34), and the other is a SWITCHING OUTPUT ARRAY (component 2b—is a voltage controlled switch—of FIG. 3, FIG. 4, FIG. 5, FIG. 8 and FIG. 22, also FIG. 13, and FIG. 14, which have OUTPUT ARRAY ZONE(s) (BETWEEN COMPONENTS 2o and 2b). The OPEN OUTPUT ARRAY (component 2b—is a capacitor—of FIG. 6, FIG. 7, and FIG. 34) works as well as THE SWITCHING OUTPUT ARRAY, which remains true for all of the figures with OUTPUT ARRAY(s) even FIG. 13 and FIG. 14.
THE BPT SWITCHING OUTPUT ARRAY, in terms of frequency, as the switch (2b) closes and opens—depending on the switch used in the device—the faster the switch opens and closes the less current flows through the switch to open and close the switch. That does not affect current flow through THE BPT SWITCHING OUTPUT ARRAY (see FIG. 33—SOA output—).—As 2b slows down, the frequency is shown by current passing through the switch, small current means the switch 2b is moving fast (HIGH FREQUENCY), and large current means the switch (2b) is moving slowly (LOW FREQUENCY) or not at all—a simple example of why an OPEN OUTPUT ARRAY (see FIG. 36—OOA output—) works with THE BPT CIRCUIT(s) as well as THE SWITCHING OUTPUT ARRAY—, showing only the natural function of the switch (2b) and the power it expels or dissipates to achieve a significant output in an OUTPUT ARRAY.—Once the switch (2b) closes (POTENTIAL ENERGY) current then flows from the grounds (1a, 2a, 3a, 4a, 9a, 2b, 8b, 9b, and 1c) of THE BPT SWITCHING OUTPUT ARRAY CIRCUIT of FIG. 3, FIG. 4, FIG. 5, FIG. 8, FIG. 22 also FIG. 13 and FIG. 14—which have OUTPUT ARRAY ZONE(s) BETWEEN COMPONENTS 2o and 2b—. Current is extracted at all the ground components of THE SWITCHING OUTPUT ARRAY as high current because the switch (2b) closes. The flow of high current through 2b is due to the fact that voltage in THE SWITCHING OUTPUT ARRAY is higher than that of anything it is in contact with. When the switch (2b) opens, the circuit returns to a real voltage state of the original values of V1 (component 4d) and V3 (component 3b) and a current state proportional to the values of the components in the circuit at ground (1a, 2a, 3a, 4a, 9a, 2b, 8b, 9b, and 1c) see FIG. 3 (see FIG. 36—OOA output—) and FIG. 3, (see FIG. 33—SOA output—).
In terms of frequency, as the switch closes and opens—depending on the switch used in the device—the faster the switch opens and closes the less current flows through the switch to open and close the switch; however, the frequency does not affect the current flowing in THE BPT OUTPUT ARRAY and ground of the circuit at THE PARTICLE TENDENCY ZONE and EXTENDED PARTICLE TENDENCY ZONE for a working BPT OUTPUT ARRAY. Comparably, the frequency of component 2b does not affect how much current flows through any component at ground of THE BPT SWITCHING OUTPUT ARRAY of FIG. 3, FIG. 4, FIG. 5, FIG. 8, and FIG. 22 also FIG. 13 and FIG. 14—which have OUTPUT ARRAY ZONE(s) BETWEEN COMPONENTS 2o and 2b—. The Resistor components at ground of THE BPT OUTPUT ARRAY (OPEN OUTPUT ARRAY AND SWITCHING OUTPUT ARRAY) can be of any value, for example less than 1 Ohm (0.001 Ohm) to a high value resistant like 5,000,000,000 Ohms resistor. These values give the same current output (see FIG. 9); and, the current with a parallel component is as usual, the smaller component gets the most current and proportional to the entire current value of the parallel components; illustrated with components 8b and 9b—see FIG. 3, FIG. 4, FIG. 5, FIG. 8, and FIG. 22—.
The output current of THE BPT OUTPUT ARRAY(s) vary depending on CURRENT LIMITER 2, CURRENT LIMITER 3 (see FIG. 16) and the parallel and series components used in conjunction (see FIG. 3, FIG. 4, FIG. 5, FIG. 6, FIG. 7, FIG. 8, FIG. 22 and FIG. 34.) with THE BPT OUTPUT ARRAY components at ground (2a, 4a, 8b, 9b—resistors which may be less than 1 Ohm (0.001 Ohm) to a high value resistant like 5,000,000,000 Ohms resistor values), (1a, 3a, 5a, 6a, 8a, 9a, 3b, 6b, 7b, 1c—parallel and series capacitors that vary in value), and 2b (a voltage controlled switch or a capacitor that can be of almost any value). With these parameters (see FIG. 23, FIG. 24, FIG. 25, FIG. 26, FIG. 27, FIG. 28, FIG. 29, FIG. 10, FIG. 11, FIG. 12, FIG. 30, FIG. 32, FIG. 31 and FIG. 35) in check, THE BPT CIRCUIT has current of a stable range while having limitless electrical power.
As to a further discussion of the manner of usage and operation of the present invention, the same should be apparent from the above description. Accordingly, no further discussion relating to the manner of usage and operation will be provided.
With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.
Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.
